(19) United States
(12) Patent Application Publication
(10) Pub. No.: US 2009/0274975 A1
(43) Pub. Date: Nov. 5, 2009

(54) POSITIVE PHOTOSENSITIVE COMPOSITION AND METHOD OF FORMING PATTERN THEREWITH

(75) Inventors: Yuko Tada, Haibara-gun (JP); Akinori Shibuya, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/413,314

(22) Filed: Mar. 27, 2009

(30) Foreign Application Priority Data
Mar. 28, 2008 (JP) 2008-088541

(51) Int. Cl. G03F 7/039; G03F 7/20

(52) U.S. Cl. 430/270.1; 430/326

(57) ABSTRACT

A positive photosensitive composition includes (A) a resin having a repeating unit with a lactone structure of 5.0 or below an Onishi parameter and having any of repeating units of Formula (I) that when acted on by an acid, generates a carboxylic acid, and (B) a compound that when exposed to actinic rays or radiation, generates an acid,

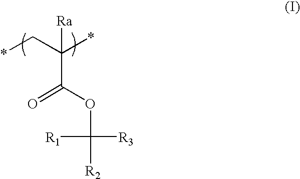

wherein each of R₁, R₂ and R₃ independently represents a substituted or unsubstituted alkyl group or a substituted or unsubstituted cycloalkyl group, provided that R₂ and R₃ may be bonded with each other to thereby form a ring structure, and Ra represents a hydrogen atom, an alkyl group or a group of the formula —CH₂—O—Ra₂ in which Ra₂ represents a hydrogen atom, an alkyl group or an acyl group, the structure of Formula (I) having a van der Waals volume of 306×10⁻³⁰ m³ or less.

### CROSS-REFERENCE TO RELATED APPLICATIONS

This application is based upon and claims the benefit of priority from prior Japanese Patent Application No. 2008-088541, filed Mar. 28, 2008, the entire contents of which are incorporated herein by reference.

### BACKGROUND OF THE INVENTION

1. Field of the Invention

The present invention relates to a positive photosensitive composition for use in a process for producing a semiconductor such as IC, production of a circuit board for e.g., a thermal head and a liquid crystal, and other photofabrication processes.

2. Description of the Related Art

A chemical amplification resist composition is a pattern forming material that is capable of, upon exposure to far ultraviolet or other actinic rays or radiation, generating an acid at the exposed area and, by a reaction catalyzed by the acid, changing the solubility to developer between the area having been exposed to actinic rays or radiation and the nonexposed area to thereby attain pattern formation on a substrate.

In the use of a KrF excimer laser as an exposure light source, a resin whose fundamental skeleton consists of a poly(hydroxystyrene) exhibiting low absorption mainly in the region of 248 nm is employed as a major component. Accordingly, there can be attained high sensitivity, high resolving power and favorable pattern formation. Thus, a system superior to the conventional naphthoquinone diazide/novolak resin system is provided.

On the other hand, in the use of a light source of shorter wavelength, for example, ArF excimer laser (193 nm) as an exposure light source, as the compound having an aromatic group inherently exhibits a sharp absorption in the region of 193 nm, the above-mentioned chemical amplification system has not been satisfactory.

Therefore, resists for an ArF excimer laser containing a resin with an alicyclic hydrocarbon structure have been developed. As acid-decomposable resins being main constituents of the chemical amplification resist compositions, general use is made of, for example, resins having, in their principal chains, structural units derived from (meth)acrylic esters having an alicyclic hydrocarbon structure with multiple rings, such as an adamantane skeleton (see, for example, patent reference (1)) and resins having, in their principal chains, structural units derived from (meth)acrylic esters having an alicyclic hydrocarbon structure with a single ring, such as a cyclohexane skeleton (see, for example, patent reference (2)).

It has already been discovered that performance enhancement can be achieved by introduction of a repeating unit with a lactone structure in the above resins with an alicyclic hydrocarbon structure. For example, the patent references (3) and (4) describe resist compositions containing resins having repeating units with a mevalonic lactone structure or γ-lactone structure. Further, the patent references (5) to (7) describe resist compositions containing resins having repeating units with an alicyclic lactone structure.

However, the current situation is that it is extremely difficult to find an appropriate combination of resin, photo-acid generator, additive, solvent, etc. to be employed, from the viewpoint of overall performance of the resist. Further, in the formation of a fine pattern such as that of 100 nm or less line width, there is a demand for improvement of the line edge roughness performance of a line pattern and improvement on pattern collapse.

[Patent reference 1] JP 2881969

[Patent reference 2] WO 2005/016982

[Patent reference 3] Jpn. Pat. Appln. KOKAI Publication No. (hereinafter referred to as JP-A-) 9-73173

[Patent reference 4] U.S. Pat. No. 6,388,101

[Patent reference 5] JP-A-2000-159758

[Patent reference 6] JP-A-2001-109154

[Patent reference 7] US 2001/26901 A

### BRIEF SUMMARY OF THE INVENTION

It is an object of the present invention to provide a positive photosensitive composition improved with respect to the line edge roughness and pattern collapse and provide a method of forming a pattern therewith.

The inventors have conducted extensive and intensive studies with a view toward solving the above problem, and have arrived at this invention.

The present invention is summarized below.

(1) A positive photosensitive composition comprising:

(A) a resin having a repeating unit with a lactone structure of 5.0 or below an Onishi parameter and having any of repeating units of the following general formula (I) that when acted on by an acid, generates a carboxylic acid, and

(B) a compound that when exposed to actinic rays or radiation, generates an acid,

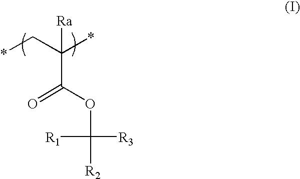

wherein each of R₁, R₂ and R₃ independently represents a substituted or unsubstituted alkyl group or a substituted or unsubstituted cycloalkyl group, provided that R₂ and R₃ may be bonded with each other to thereby form a ring structure, and

Ra represents a hydrogen atom, an alkyl group or a group of the formula —CH₂—O—Ra₂ in which Ra₂ represents a hydrogen atom, an alkyl group or an acyl group,

the structure of the general formula (I) having a van der Waals volume of 306×10⁻³⁰ m³ or less.

(2) The positive photosensitive composition according to item (1), wherein the resin (A) further has any of repeating units of the following general formula (II):

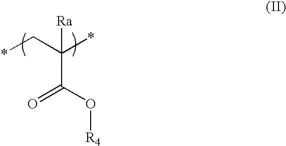

wherein R₄ represents an alicyclic hydrocarbon structure having a cyano group or a hydroxyl group, and

Ra represents a hydrogen atom, an alkyl group or a group of the formula —CH₂—O—Ra₂ in which Ra₂ represents a hydrogen atom, an alkyl group or an acyl group.

(3) The positive photosensitive composition according to item (1) or (2), wherein the resin (A) further has any of repeating units of the following general formula (III):

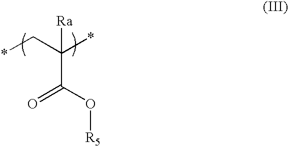

wherein R₅ represents a hydrocarbon group having at least one cyclic structure in which neither a hydroxyl group nor a cyano group is contained, and

Ra represents a hydrogen atom, an alkyl group or a group of the formula —CH₂—O—Ra₂ in which Ra₂ represents a hydrogen atom, an alkyl group or an acyl group.

(4) A method of forming a pattern, comprising the steps of shaping the positive photosensitive composition according to any of items (1) to (3) into a film and subjecting the film to exposure to light and development.

The positive photosensitive composition of the present invention realizes the formation of a pattern being free from pattern collapse and excelling in line edge roughness.

### DETAILED DESCRIPTION OF THE INVENTION

Now, the present invention will be described in detail.

With respect to the expression of a group (atomic group) used in this specification, the expression even when there is no mention of “substituted and unsubstituted” encompasses groups not only having no substituent but also having substituents. For example, the “alkyl groups” encompasses not only alkyls having no substituent (unsubstituted alkyls) but also alkyls having substituents (substituted alkyls).

[1] Resin Having a Repeating Unit with Lactone Structure and a Repeating Unit that when Acted on by an Acid, Generates a Carboxylic Acid (Component (A)):

The positive photosensitive composition of the present invention contains a resin having a repeating unit with a lactone structure of 5.0 or below the Onishi parameter and having any of repeating units of the following general formula (I) that when acted on by an acid, generates a carboxylic acid (hereinafter, often referred to as “resin (A)” or the like).

First, the repeating unit with a lactone structure of 5.0 or below the Onishi parameter will be described.

The repeating unit with a lactone structure contained in the resin (A) has an Onishi parameter of 5.0 or below, preferably 4.5 or below and still preferably 4.0 or below. Preferably, the Onishi parameter is 3.45 or above. The Onishi parameter is an index for dry etching resistance and is determined by the formula (number of C atoms+number of H atoms+number of O atoms)/(number of C atoms−number of O atoms). In the calculation of the Onishi parameter of a lactone structure, the structure up to the repeating unit is involved, and substituents on the lactone structure are also involved. When nitrogen is contained, the Onishi parameter has been determined as a value excluding nitrogen. The numeric value of the Onishi parameter determined in this way is in correlation with the etching resistance.

In the present invention, the repeating unit having the lactone structure would be appropriate as long as its Onishi parameter is 5.0 or below, and is not limited to specified lactone structures. However, lactone structures of a 5 to 7-membered ring are preferred, and in particular, those resulting from condensation of lactone structures of 5 to 7-membered rings with other cyclic structures effected in a fashion to form a bicyclo structure or spiro structure are preferred. The possession of the repeating unit having the lactone structure represented by any of the following general formulae (LC1-1) to (LC1-16) is more preferred. The lactone structures may be directly bonded to the principal chain. Preferred lactone structures are those with the skeletons of the formulae (LC1-1), (LC1-4) and (LC1-15). An especially preferred lactone structure is one with a skeleton of the formula (LC1-4). The use of these specified lactone structures would ensure improvement in line edge roughness and development defect.

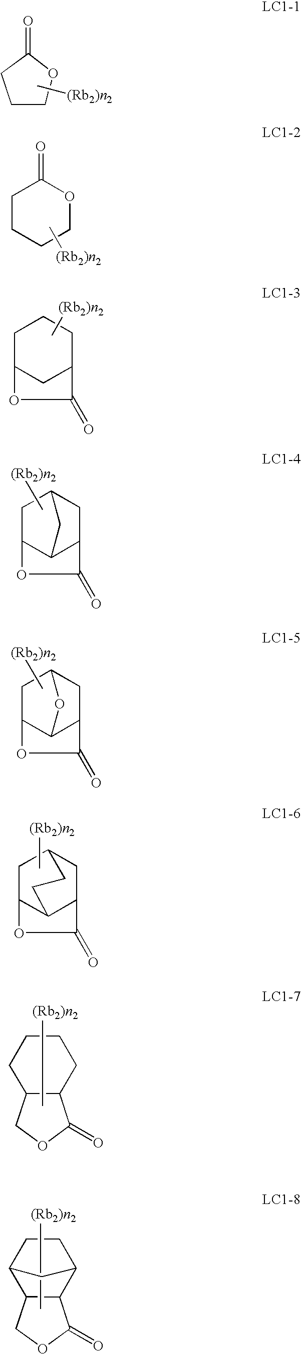

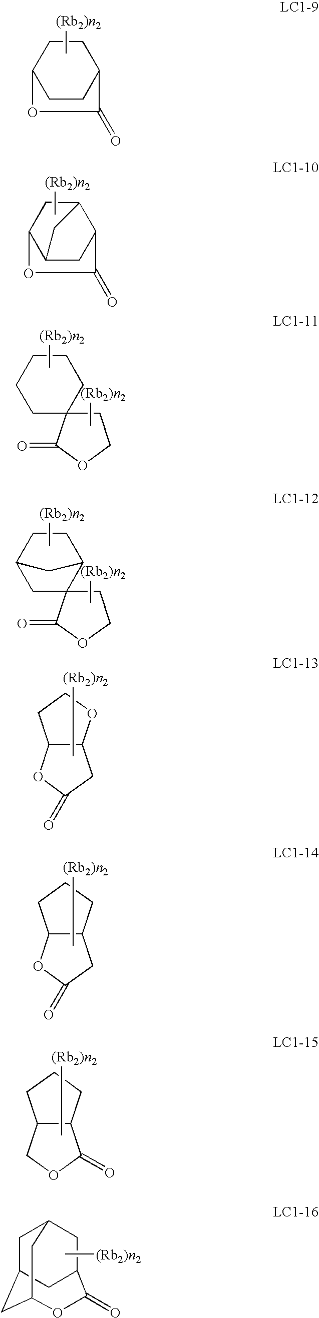

The possession of substituent (Rb₂) on the portion of the lactone structure is optional. As preferred substituent (Rb₂), there can be mentioned, for example, an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group or an acid-decomposable group. Of these, an alkyl group having 1 to 4 carbon atoms, a cyano group and an acid-decomposable group are more preferred. In the formulae, n2 is an integer of 0 to 4. When n2 is 2 or greater, the plurality of present substituents (Rb₂) may be identical with or different from each other. Further, the plurality of present substituents (Rb₂) may be bonded with each other to thereby form a ring.

As the repeating unit with a lactone structure, there can be mentioned the repeating units represented by the following general formula (AI).

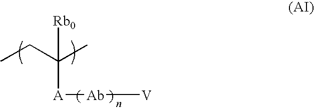

In the general formula (AI),

Rb₀ represents a hydrogen atom, a halogen atom or an alkyl group. A preferred alkyl group represented by Rb₀ is an alkyl group having 1 to 4 carbon atoms and may have a substituent. As a preferred substituent optionally possessed by the alkyl group represented by Rb₀, there can be mentioned a hydroxyl group or a halogen atom, etc. As the halogen atom represented by Rb₀, there can be mentioned a fluorine atom, a chlorine atom, a bromine atom or an iodine atom. The Rb₀ is preferably a hydrogen atom, a methyl group, trifluoromethyl group or a hydroxymethyl group.

A represents an ester bond (—COO—) or an amido bond (—CONH—).

Ab represents a single bond, an alkylene group, a bivalent linkage group with alicyclic hydrocarbon structure of a single ring or multiple rings, an ether bond, an ester bond, a carbonyl bond, an amido bond, a urethane bond, a urea bond, or a bivalent linkage group resulting from a combination thereof. A single bond and a bivalent linkage group of the formula -Ab₁-CO₂— are preferred. Ab₁ is a linear or branched alkylene group or a cycloalkylene group of a single ring or multiple rings, being preferably a methylene group, an ethylene group, a cyclohexylene group, an adamantylene group or a norbornylene group.

V represents a monovalent organic group with a lactone structure, and there can be mentioned, for example, a group with a structure represented by any of the general formulae (LC1-1) to (LC1-16).

n is an integer of 1 to 5, preferably 1.

General formula (AI) is preferably the repeating units with a lactone structure represented by the following general formula (2).

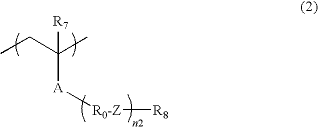

In the general formula (2),

A represents an ester bond (—COO—) or an amido bond (—CONH—). R₀ represents an alkylene group or a cycloalkylene group, provided that when n2 is 2 or greater, the plurality of present R₀s may be identical with or different from each other. Z represents a carbonyl group, an ether bond, an ester bond, an amido bond, a urethane bond or a urea bond, provided that when n2 is 2 or greater, the plurality of present Zs may be identical with or different from each other. R₈ represents a monovalent organic group with a lactone structure. n₂ is an integer of 1 to 5, and preferably 1. R₇ represents a hydrogen atom, a halogen atom or an alkyl group.

An alkylene group and a cycloalkylene group represented by R₀ may have substituents.

Z is preferably an ether bond or an ester bond, more preferably an ester bond.

An alkyl group represented by R₇ is preferably an alkyl group having 1 to 4 carbon atoms, more preferably a methyl group or an ethyl group, and especially preferably a methyl group. An alkyl group represented by R₇ may have substituents. As the substituent of the alkyl group, there can be mentioned, for example, a halogen atom (fluorine atom, chlorine atom or bromine atom, etc), a mercapto group, a hydroxyl group, an alkoxy group (a methoxy group, an ethoxy group, an isopropoxy group, a t-butoxy group or a benzyloxy group, etc.), an acyl group (an acetyl group or a propionyl group, etc.), acetoxy group or the like. R₇ is preferably a hydrogen atom, a methyl group, a trifluoromethyl group or a hydroxymethyl group.

As preferred alkylene groups represented by R₀, there can be mentioned a linear or branched alkylene group having 1 to 10 carbon atoms, more preferably 1 to 5 carbon atoms (for example, a methylene group, ethylene group or propylene group). As preferred cycloalkylene groups represented by R₀, there can be mentioned a cycloalkylene group having 3 to 20 carbon atoms (for example, a cyclohexylene group, a cyclopentylene group, a norbornylene group or an adamantylene group). From the viewpoint of exerting of the effects of the present invention, R₀ is more preferably an alkylene group, especially preferably a methylene group.

Although the monovalent organic group with a lactone structure represented by R₈ is not limited as long as the monovalent organic group has a lactone structure, there can be mentioned lactone structures represented by any of the aforementioned general formulae (LC1-1) to (LC1-16), among which the lactone structure represented by general formula (LC1-4) is especially preferred. In addition, the structures represented by the general formulae (LC1-1) to (LC1-16) wherein n₂ is 2 or less are preferred.

R₈ is more preferably a monovalent organic group with a lactone structure having a cyano group as a substituent (cyano lactone).

Specific examples of repeating units having a lactone structure represented by the general formula (2) will be shown below, which however in no way limit the scope of the invention. In the specific examples, R represents a hydrogen atom, a methyl group, a hydroxymethyl group or acetoxymethyl group.

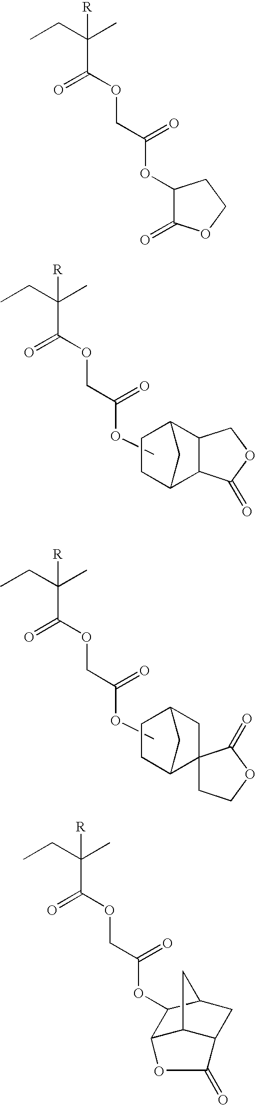

The repeating units represented by the following general formula (2-1) is more preferred as the repeating unit with a lactone structure.

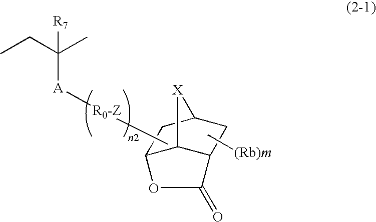

In the general formula (2-1),

R₇, A, R₀, Z and n₂ have the same meaning as R₇, A, R₀, Z and n₂ in the general formula (2).

Rb represents an alkyl group, a cycloalkyl group, an alkoxycarbonyl group, a cyano group, a hydroxyl group or an alkoxy group, provided that when m is 2 or greater, the plurality of present Rbs may be identical with or different from each other. Further, two of the plurality of present Rbs may be bonded with each other to thereby form a ring.

X represents an alkylene group, an oxygen atom or a sulfur atom.

m represents the number of substituents and is an integer of 0 to 5, preferably 0 or 1.

An alkyl group represented by Rb is preferably an alkyl group having 1 to 4 carbon atoms, more preferably a methyl group or an ethyl group, and especially preferably a methyl group. As a cycloalkyl group, there can be mentioned monocyclic groups having 3 to 6 carbon atoms. As an alkoxycarbonyl group, there can be mentioned a methoxycarbonyl group, an ethoxycarbonyl group, n-butoxycarbonyl group, t-butoxycarbonyl group or the like. As an alkoxy group, there can be mentioned a methoxy group, an ethoxy group, n-butoxy group, t-butoxy group or the like. An alkyl group, a cycloalkyl group, an alkoxycarbonyl group and an alkoxy group represented by Rb may have a substituent. As the substituent, there can be mentioned, for example, a hydroxyl group, an alkoxy group (a methoxy group, an ethoxy group, etc.), a cyano group, a halogen atom (fluorine atom, etc.) or the like.

Rb is more preferably a methyl group, a cyano group or an alkoxycarbonyl group and further preferably a cyano group.

As an alkylene group represented by X, there can be mentioned a methylene group, an ethylene group or the like. X is preferably an oxygen atom or a methylene group and more preferably a methylene group. When m is 1, it is preferred that the lactone is substituted at its α-position or β-position of carbonyl group with Rb, more preferably at its α-position.

Specific examples of the repeating units having a group with a lactone structure will be shown below, which however in no way limit the scope of the present invention.

In the specific examples, R represents a hydrogen atom, a substituted or unsubstituted alkyl group or a halogen atom, more preferably a hydrogen atom, a methyl group, a hydroxymethyl group or an acetoxymethyl group.

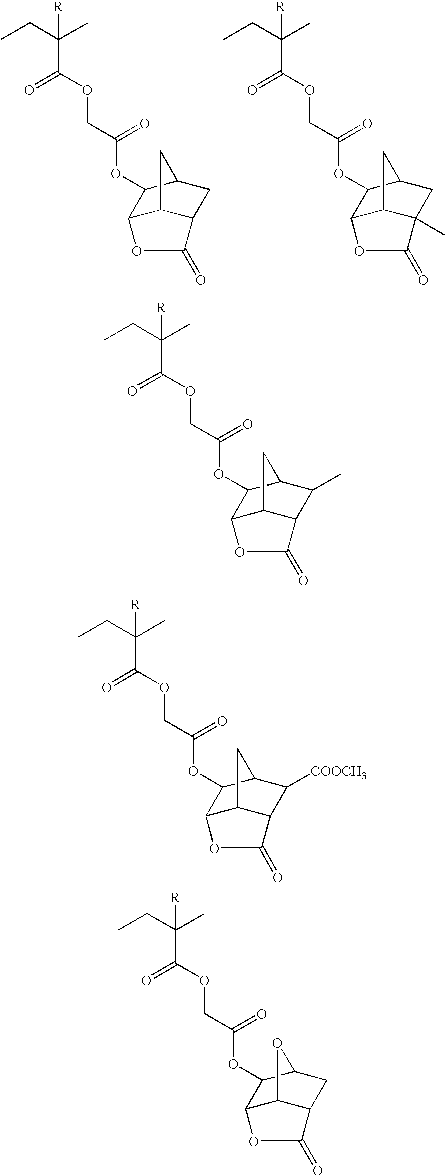

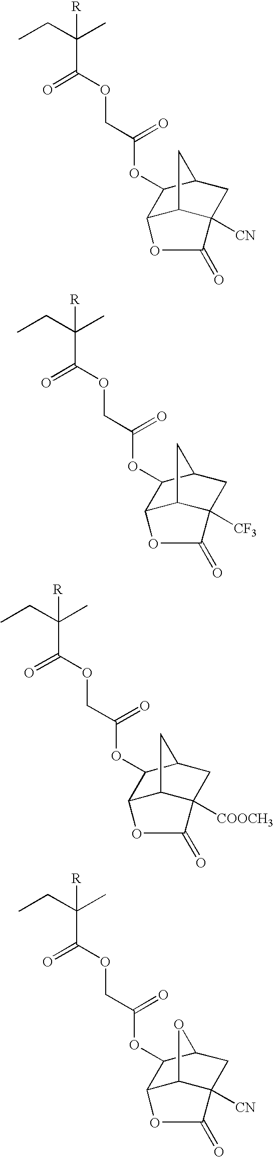

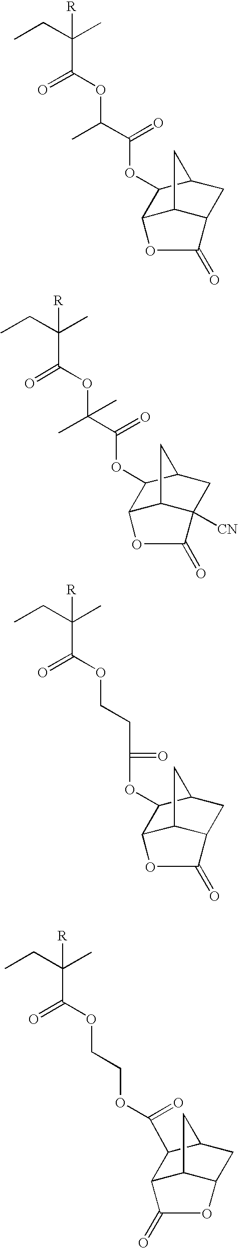

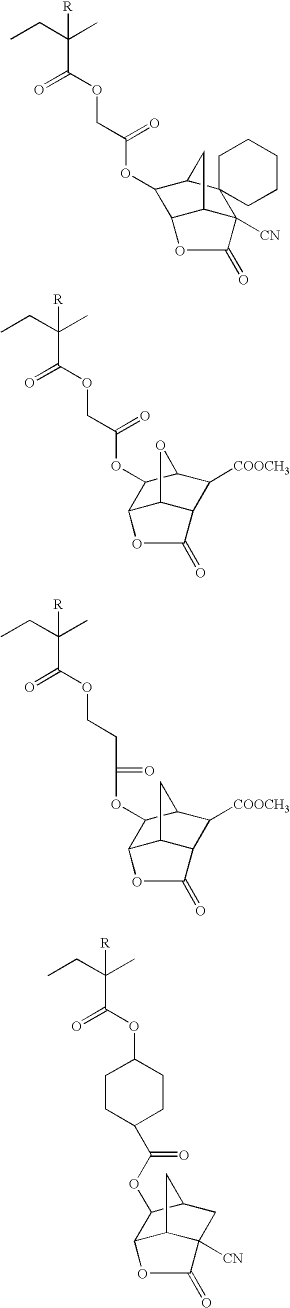

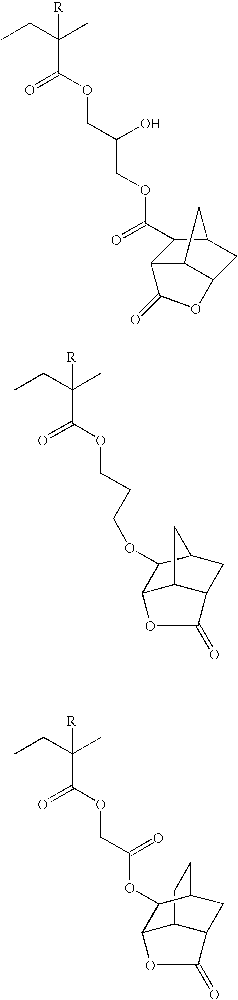

From the viewpoint of exerting of the effects of the present invention, a combination of two or more repeating units with a lactone structure selected from the general formula (AI) may be used.

The repeating unit having a lactone group is generally present in the form of optical isomers. Any optical isomer may be used. It is both appropriate to use a single type of optical isomer alone and to use a plurality of optical isomers in the form of a mixture. When a single type of optical isomer is mainly used, the optical purity (ee) thereof is preferably 90 or higher, more preferably 95 or higher.

The content of the repeating unit having a lactone group based on all the repeating units of the resin (A) is preferably in the range of 15 to 70 mol %, more preferably 20 to 60 mol % and still more preferably 30 to 50 mol %.

Examples of the repeating units having a lactone group will now be shown, which however in no way limit the scope of the present invention. The Onishi parameters of the examples (1) to (25) are indicated in Table 1.

TABLE 1

| 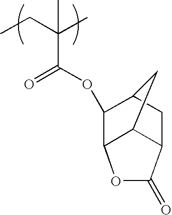 | 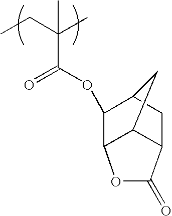 |
|---|---|
| (1) | (2) |
| 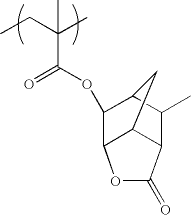 | 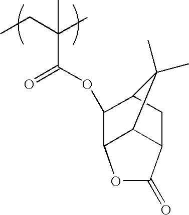 |
| (3) | (4) |
| 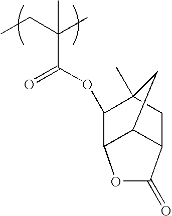 | 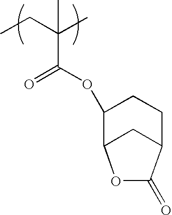 |
| (5) | (6) |
| 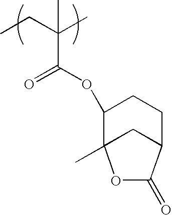 | 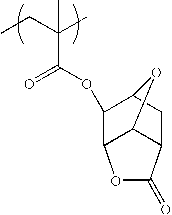 |
| (7) | (8) |
| 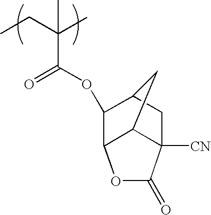 | 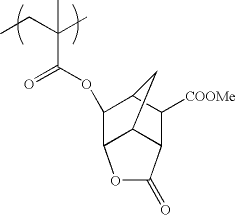 |
| (9) | (10) |
| 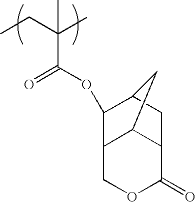 | 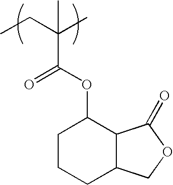 |
| (11) | (12) |
| 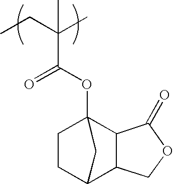 | 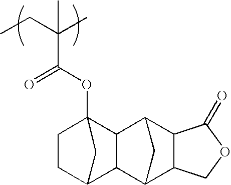 |
| (13) | (14) |
| 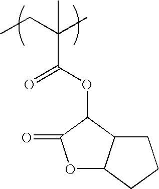 | 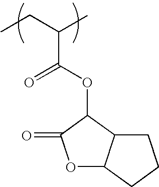 |
| (15) | (16) |
| 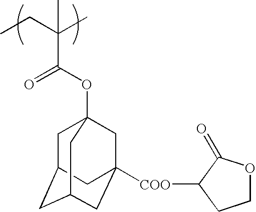 | 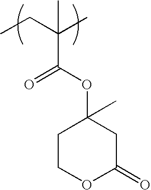 |
| (17) | (18) |
| 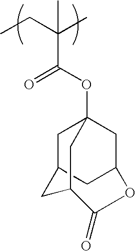 | 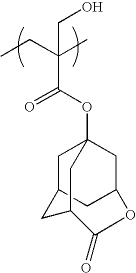 |
| (19) | (20) |
| 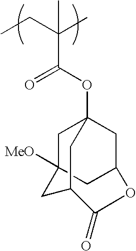 | 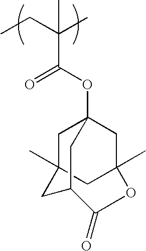 |
| (21) | (22) |
| 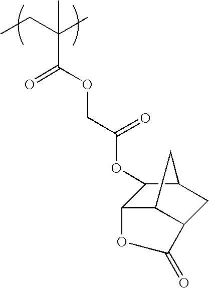 | 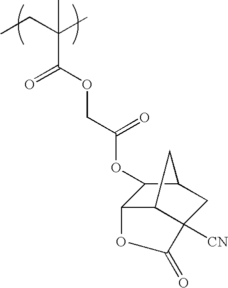 |
| (23) | (24) |

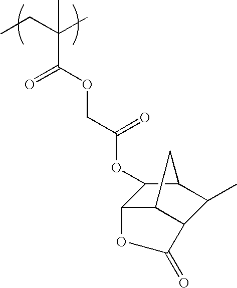

(25)

| Specific example | Onishi parameter |
|---|---|
| (1) | 3.80 |
| (2) | 3.89 |
| (3) | 3.73 |
| (4) | 3.67 |
| (5) | 3.73 |
| (6) | 4.11 |
| (7) | 4.00 |
| (8) | 4.50 |
| (9) | 3.45 |
| (10) | 4.40 |
| (11) | 3.73 |
| (12) | 4.00 |
| (13) | 3.73 |
| (14) | 3.25 |
| (15) | 4.11 |
| (16) | 4.25 |
| (17) | 3.80 |
| (18) | 4.50 |
| (19) | 3.67 |
| (20) | 4.09 |
| (21) | 4.00 |
| (22) | 3.57 |
| (23) | 4.50 |
| (24) | 4.29 |
| (25) | 4.33 |

The repeating units of the general formula (I) that when acted on by an acid, generate a carboxylic acid will now be described.

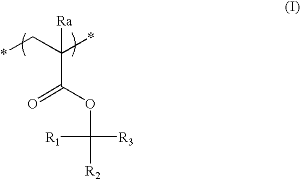

In the general formula (I), each of R₁, R₂ and R₃ independently represents a substituted or unsubstituted alkyl group or a substituted or unsubstituted cycloalkyl group, provided that R₂ and R₃ may be bonded with each other to thereby form a ring structure. The structure of the general formula (I) has a van der Waals volume of 306×10⁻³⁰ m³ or less.

Ra represents a hydrogen atom, an alkyl group or a group of the formula —CH₂—O—Ra₂ in which Ra₂ represents a hydrogen atom, an alkyl group or an acyl group.

The general formula (I) will be described in detail.

R₁ is an optionally substituted alkyl group or an optionally substituted cycloalkyl group. The alkyl group represented by R₁ may be in the form of a linear chain or branched chain, being preferably one having 1 to 10 carbon atoms, especially 1 to 5 carbon atoms. The cycloalkyl group represented by R₁ is preferably a cycloalkyl group having 3 to 10 carbon atoms. For example, there can be mentioned a methyl group, an ethyl group, an isopropyl group, a cyclopentyl group, a cyclohexyl group and the like, among which a methyl group, an ethyl group and an isopropyl group are especially preferred.

Each of R₂ and R₃ is an optionally substituted alkyl group or an optionally substituted cycloalkyl group. The alkyl group represented by R₂ or R₃ may be in the form of a linear chain or branched chain, being preferably one having 1 to 10 carbon atoms. The alkyl chain may contain an oxygen atom, a sulfur atom or a nitrogen atom. For example, there can be mentioned a linear alkyl group, such as a methyl group, an ethyl group, an n-propyl group, an n-butyl group, an n-pentyl group, an n-hexyl group, an n-octyl group, an n-dodecyl group, an n-tetradecyl group or an n-octadecyl group, and a branched alkyl group, such as an isopropyl group, an isobutyl group, a t-butyl group, a neopentyl group or a 2-ethylhexyl group.

The cycloalkyl group represented by R₂ or R₃ is preferably a cycloalkyl group having 3 to 10 carbon atoms, which may be polycyclic and may have an oxygen atom in its ring. For example, there can be mentioned a cyclopropyl group, a cyclopentyl group, a cyclohexyl group, a cycloheptyl group or the like.

The R₂ and R₃ may be identical with or different from each other, and may be bonded with each other to thereby form a ring structure. The ring structure resulting from mutual bonding is preferred. As a preferred ring structure, there can be mentioned any of a cyclopropyl group, a cyclopentyl group, a cyclohexyl group and a cycloheptyl group, among which a cyclopentyl group and a cyclohexyl group are more preferred.

As a substituent that may be possessed by each of the R₁ to R₃ groups, there can be mentioned, for example, a halogen atom, a hydroxyl group, a nitro group, a cyano group, a carboxyl group, a carbonyl group, a cycloalkyl group (preferably 3 to 10 carbon atoms), an aryl group (preferably 6 to 14 carbon atoms), an alkoxy group (preferably 1 to 10 carbon atoms), an acyl group (preferably 2 to 20 carbon atoms), an acyloxy group (preferably 2 to 10 carbon atoms), an alkoxycarbonyl group (preferably 2 to 20 carbon atoms), an aminoacyl group (preferably 2 to 10 carbon atoms) or the like. As a substituent of the ring structure of the aryl group, cycloalkyl group or the like, there can be mentioned an alkyl group (preferably 1 to 10 carbon atoms). As a substituent of the aminoacyl group, there can be mentioned one or two alkyl groups (preferably 1 to 10 carbon atoms).

Ra represents a hydrogen atom, an alkyl group (preferably 1 to 4 carbon atoms) or a group of the formula —CH₂—O—Ra₂ in which Ra₂ represents a hydrogen atom, an alkyl group or an acyl group. Preferably, Ra is a hydrogen atom, a methyl group or —CH₂—OH.

The van der Waals volume of the structure of the general formula (I) can be determined by means known in the art to which the present invention pertains. For example, the volume may be calculated with the use of the standard procedure of CAChe Version 7.5.0.85 manufactured by Fujitsu Limited. In the present invention, the van der Waals volume of the repeating units of the general formula (I) determined by this measuring method is 306×10⁻³⁰ m³ or less, preferably 300×10⁻³⁰ m³ or less and still preferably in the range of 240×10⁻³⁰ to 285×10⁻³⁰ m³.

Specific examples of preferred repeating units having an acid-decomposable group will be shown below, which however in no way limit the scope of the invention. The van der Waals volumes (hereinafter also referred to as “volumes”) of examples (1) to (24) are indicated in Table 2.

TABLE 2

| 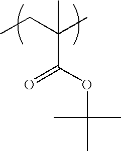 | 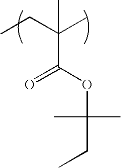 |
|---|---|
| (1) | (2) |
| 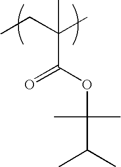 | 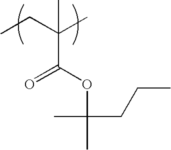 |
| (3) | (4) |
| 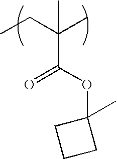 | 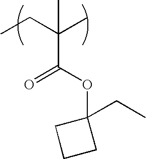 |
| (5) | (6) |
| 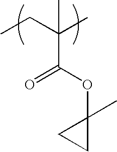 | 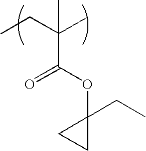 |
| (7) | (8) |
| 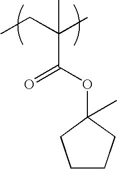 | 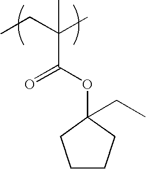 |
| (9) | (10) |
| 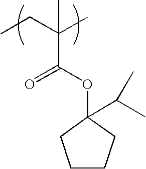 | 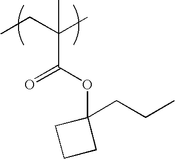 |
| (11) | (12) |
| 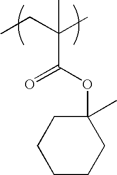 | 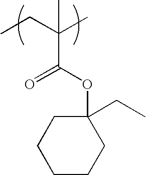 |
| (13) | (14) |
| 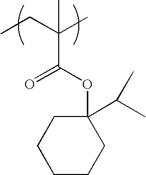 | 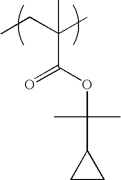 |
| (15) | (16) |
| 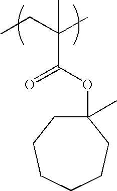 | 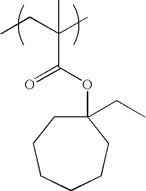 |
| (17) | (18) |
| 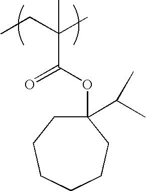 | 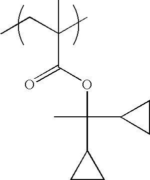 |
| (19) | (20) |
| 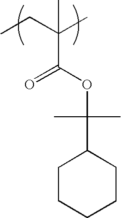 | 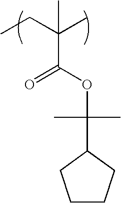 |
| (21) | (22) |
| 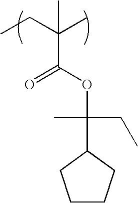 | 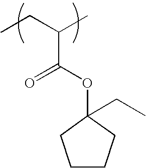 |
| (23) | (24) |

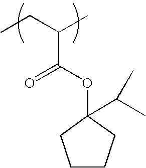

(25)

| | Volume |
|---|---|
| Specific example | (× 10⁻³⁰ m³) |
| (1) | 218.59 |
| (2) | 236.76 |
| (3) | 257.14 |
| (4) | 257.09 |
| (5) | 226.93 |
| (6) | 247.29 |
| (7) | 201.49 |
| (8) | 228.3 |
| (9) | 245.69 |
| (10) | 264.84 |
| (11) | 283.4 |
| (12) | 267.24 |
| (13) | 263.11 |
| (14) | 282.77 |
| (15) | 301.94 |
| (16) | 246.3 |
| (17) | 284.07 |
| (18) | 302.78 |
| (19) | 320.87 |
| (20) | 276.49 |
| (21) | 302.58 |
| (22) | 282.7 |
| (23) | 305.22 |
| (24) | 245.75 |
| (25) | 263.71 |

The content of any of repeating units of the general formula (I) that when acted on by an acid, generate a carboxylic acid, based on all the repeating units of the resin (A), is preferably in the range of 20 to 90 mol %, more preferably 30 to 50 mol %. It is preferred that the mixing ratio between any of the repeating units of the general formula (I) and a lactone-containing repeating unit falls within ±10 mol %.

Preferably, the resin (A) of the present invention further contains any of the repeating units of the general formula (II) having a hydroxyl group or cyano group. Accordingly, the adhesion to substrate and developer affinity would be enhanced. It is preferred for the repeating units of the general formula (II) to have no acid-decomposable group.

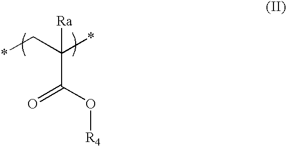

In the general formula (II), R₄ represents an alicyclic hydrocarbon structure having a cyano group or a hydroxyl group.

Ra represents a hydrogen atom, an alkyl group or a group of the formula —CH₂—O—Ra₂ in which Ra₂ represents a hydrogen atom, an alkyl group or an acyl group. The particular description made with respect to the Ra of the general formula (I) applies to this Ra.

With respect to the R₄ representing an alicyclic hydrocarbon structure having a cyano group or a hydroxyl group, the alicyclic hydrocarbon structure preferably consists of an adamantyl group, a diadamantyl group or a norbornane group. As preferred alicyclic hydrocarbon structures (R₄) substituted with a cyano group or a hydroxyl group, there can be mentioned partial structures of the following general formulae (VIIa) to (VIId).

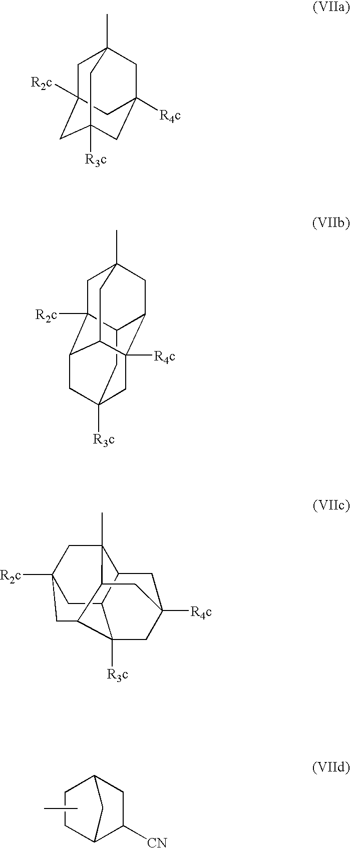

In the general formulae (VIIa) to (VIIc),

each of R₂c to R₄c independently represents a hydrogen atom, a hydroxyl group or a cyano group, provided that at least one of the R₂c to R₄c represents a hydroxyl group or a cyano group. Preferably, one or two of the R₂c to R₄c are hydroxyl groups and the remainder is a hydrogen atom. In the general formula (VIIa), more preferably, two of the R₂c to R₄c are hydroxyl groups and the remainder is a hydrogen atom.

As repeating units of the general formula (II) having any of the partial structures of the general formulae (VIIa) to (VIId) as R₄, there can be mentioned those of the following general formulae (AIIa) to (AIId).

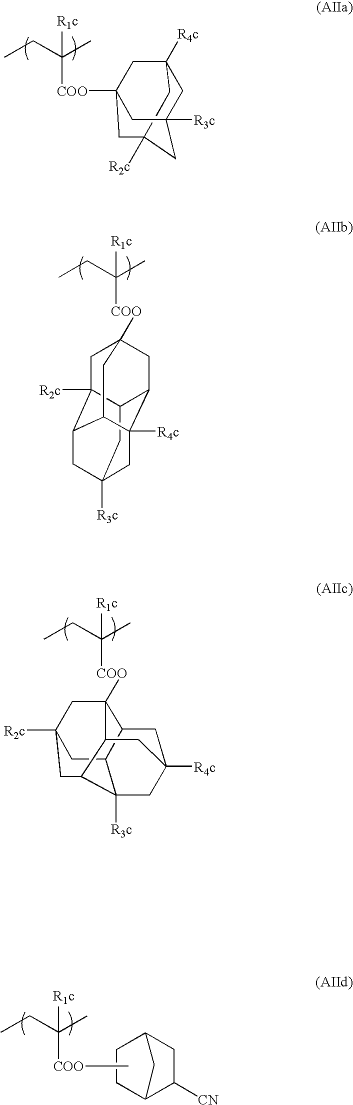

In the general formulae (AIIa) to (AIId), R₁c represents a hydrogen atom, a methyl group, a trifluoromethyl group or a hydroxymethyl group. R₂c to R₄c have the same meaning as in the general formulae (VIIa) to (VIIc).

The content of any of the repeating units of the general formula (II) having an alicyclic hydrocarbon structure substituted with a cyano group or a hydroxyl group, based on all the repeating units of the resin (A), is preferably in the range of 5 to 40 mol %, more preferably 5 to 30 mol % and still more preferably 10 to 25 mol %.

Specific examples of the repeating units having a cyano group or a hydroxyl group will be shown below, which however in no way limit the scope of the present invention.

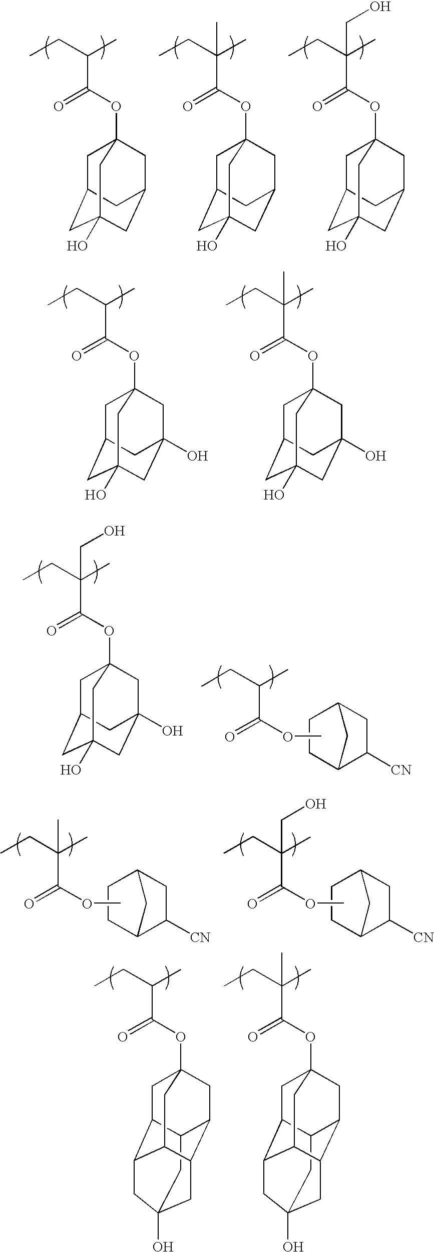

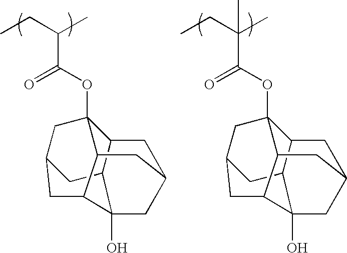

The resin (A) of the present invention preferably further contains any of the repeating units of the following general formula (III) having neither a hydroxyl group nor a cyano group.

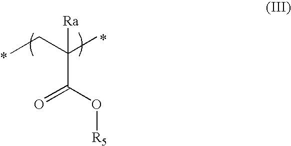

In the general formula (III), R₅ represents a hydrocarbon group having at least one cyclic structure in which neither a hydroxyl group nor a cyano group is contained.

Ra represents a hydrogen atom, an alkyl group or a group of the formula —CH₂—O—Ra₂ in which Ra₂ represents a hydrogen atom, an alkyl group or an acyl group. The particular description made with respect to the Ra of the general formula (I) applies to this Ra.

The cyclic structures of R₅ include a monocyclic hydrocarbon group and a polycyclic hydrocarbon group. As the monocyclic hydrocarbon group, there can be mentioned, for example, a cycloalkyl group having 3 to 12 carbon atoms, such as a cyclopentyl group, a cyclohexyl group, a cycloheptyl group or a cyclooctyl group, or a cycloalkenyl group having 3 to 12 carbon atoms, such as a cyclohexenyl group. Preferably, the monocyclic hydrocarbon group is a monocyclic hydrocarbon group having 3 to 7 carbon atoms. A cyclopentyl group and a cyclohexyl group are more preferred.

The polycyclic hydrocarbon groups include ring-assembly hydrocarbon groups and crosslinked-ring hydrocarbon groups. Examples of the ring-assembly hydrocarbon groups include a bicyclohexyl group, a perhydronaphthalene group and the like. As crosslinked-ring hydrocarbon rings, there can be mentioned, for example, bicyclic hydrocarbon rings, such as pinane, bornane, norpinane, norbornane and bicyclooctane rings (e.g., bicyclo[2.2.2]octane ring or bicyclo[3.2.1]octane ring); tricyclic hydrocarbon rings, such as homobledane, adamantane, tricyclo[5.2.1.0^{2.6}]decane and tricyclo[4.3.1.1^{2.5}]undecane rings; and tetracyclic hydrocarbon rings, such as tetracyclo[4.4.0.1^{2.5}.1^{7.10}]dodecane and perhydro-1,4-methano-5,8-methanonaphthalene rings. Further, the crosslinked-ring hydrocarbon rings include condensed-ring hydrocarbon rings, for example, condensed rings resulting from condensation of multiple 5- to 8-membered cycloalkanes, such as perhydronaphthalene (decalin), perhydroanthracene, perhydrophenanthrene, perhydroacenaphthene, perhydrofluorene, perhydroindene and perhydrophenarene rings.

As preferred crosslinked-ring hydrocarbon rings, there can be mentioned, for example, a norbornyl group, an adamantyl group, a bicyclooctanyl group and a tricyclo[5.2.1.0^{2.6}]decanyl group. As more preferred crosslinked-ring hydrocarbon rings, there can be mentioned a norbornyl group and an adamantyl group.

These alicyclic hydrocarbon groups may have substituents. As preferred substituents, there can be mentioned, for example, a halogen atom, an alkyl group, a hydroxyl group protected by a protective group and an amino group protected by a protective group. The halogen atom is preferably a bromine, chlorine or fluorine atom, and the alkyl group is preferably a methyl, ethyl, butyl or t-butyl group. The alkyl group may further have a substituent. As the optional substituent, there can be mentioned a halogen atom, an alkyl group, a hydroxyl group protected by a protective group and an amino group protected by a protective group.

As the protective group, there can be mentioned, for example, an alkyl group, a cycloalkyl group, an aralkyl group, a substituted methyl group, a substituted ethyl group, an alkoxycarbonyl group or an aralkyloxycarbonyl group. Preferred alkyl groups include alkyl groups having 1 to 4 carbon atoms. Preferred substituted methyl groups include methoxymethyl, methoxythiomethyl, benzyloxymethyl, t-butoxymethyl and 2-methoxyethoxymethyl groups. Preferred substituted ethyl groups include 1-ethoxyethyl and 1-methyl-1-methoxyethyl groups. Preferred acyl groups include aliphatic acyl groups having 1 to 6 carbon atoms, such as formyl, acetyl, propionyl, butyryl, isobutyryl, valeryl and pivaloyl groups. Preferred alkoxycarbonyl groups include alkoxycarbonyl groups having 1 to 4 carbon atoms.

The content of any of repeating units of the general formula (III) having neither a hydroxyl group nor a cyano group, based on all the repeating units of the resin (A), is preferably in the range of 0 to 40 mol %, more preferably 0 to 20 mol %.

Specific examples of the repeating units of the general formula (III) will now be shown, which however in no way limit the scope of the present invention.

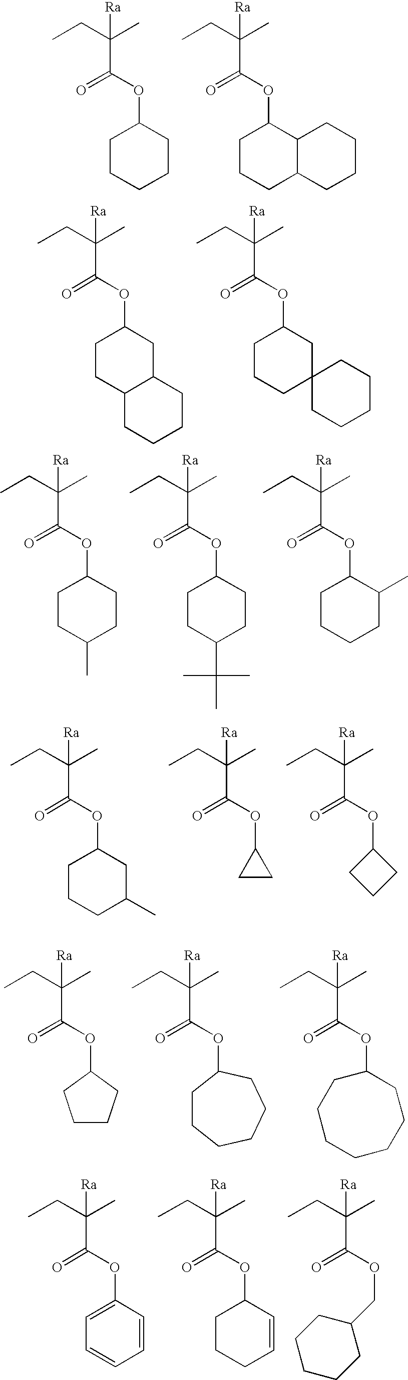

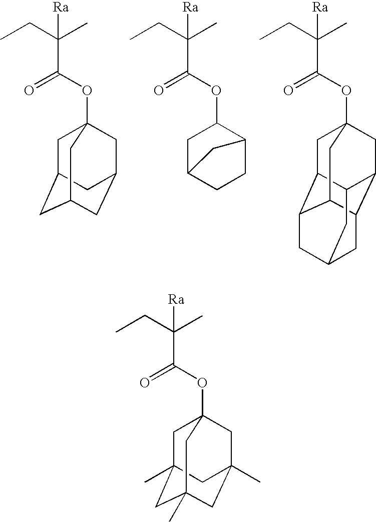

In the formulae, Ra represents H, CH₃, CH₂OH or CF₃.

It is also preferred for the resin (A) of the present invention to have a repeating unit having an alkali-soluble group. As the alkali-soluble group, there can be mentioned a carboxyl group, a sulfonamido group, a sulfonylimido group, a bisulfonylimido group or an aliphatic alcohol substituted at its α-position with an electron-withdrawing group (for example, a hexafluoroisopropanol group). The possession of a repeating unit having a carboxyl group is more preferred. The incorporation of the repeating unit having an alkali-soluble group would increase the resolving power in contact hole usage. The repeating unit having an alkali-soluble group is preferably any of a repeating unit wherein the alkali-soluble group is directly bonded to a principal chain of a resin such as repeating units of acrylic acid or methacrylic acid, a repeating unit wherein the alkali-soluble group is bonded via a linkage group to the principal chain of resin and a repeating unit wherein the alkali-soluble group is introduced in a terminal of polymer chain by the use of a chain transfer agent or polymerization initiator having the alkali-soluble group in the stage of polymerization. The linkage group may have a cyclohydrocarbon structure of a single ring or multiple rings. The use of a repeating unit of acrylic acid or methacrylic acid is especially preferred.

The content of the repeating unit having an alkali-soluble group based on all the repeating units of the resin (A) is preferably in the range of 1 to 20 mol %, more preferably 3 to 15 mol % and still more preferably 5 to 10 mol %.

Specific examples of the repeating units having the alkali-soluble group will now be shown, which however in no way limit the scope of the present invention.

In the formulae, Rx represents H, CH₃, CF₃ or CH₂OH.

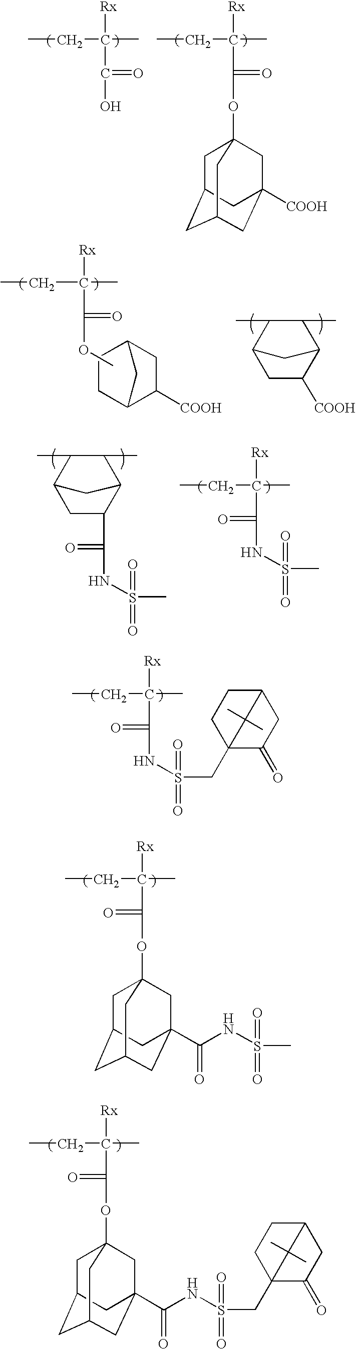

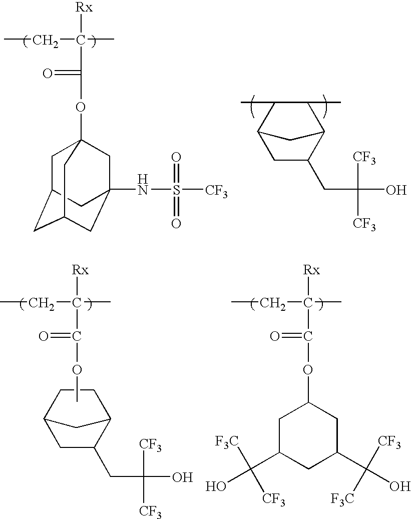

The resin (A) of the present invention may have, in addition to the foregoing repeating structural units, various repeating structural units for the purpose of regulating the dry etching resistance, standard developer adaptability, substrate adhesion, resist profile and generally required properties of the resist such as resolving power, heat resistance and sensitivity.

As such repeating structural units, there can be mentioned those corresponding to the following monomers, which however are nonlimiting.

Such repeating structural units would permit fine regulation of the properties required of the resin (A), especially:

(1) solubility in applied solvents,

(2) film forming easiness (glass transition temperature),

(3) alkali developability,

(4) film thinning (selections of hydrophilicity/hydrophobicity and alkali-soluble group),

(5) adhesion of unexposed area to substrate,

(6) dry etching resistance, etc.

As appropriate monomers, there can be mentioned, for example, a compound having an unsaturated bond capable of addition polymerization, selected from among acrylic esters, methacrylic esters, acrylamides, methacrylamides, allyl compounds, vinyl ethers, vinyl esters and the like.

In addition, copolymerization may be carried out with an unsaturated compound capable of addition polymerization as long as it is copolymerizable with any of the monomers corresponding to the above various repeating structural units.

The molar ratios of individual repeating structural units contained in the resin (A) are appropriately determined from the viewpoint of regulation of not only resist dry etching resistance but also standard developer adaptability, substrate adhesion, resist profile and generally required properties of a resist such as resolving power, heat resistance and sensitivity.

When the positive photosensitive composition of the present invention is one for ArF exposure, it is preferred for the resin as the component (A) to have no aromatic group from the viewpoint of transparency to ArF beams.

From the viewpoint of compatibility with the after-mentioned hydrophobic resin (HR), it is preferred for resin (A) to have neither a hydroxyl group nor a cyano group.

In the resin (A) for use in the present invention, preferably, all the repeating units consist of (meth)acrylate repeating units. In that instance, use can be made of any of a resin wherein all the repeating units consist of methacrylate repeating units, a resin wherein all the repeating units consist of acrylate repeating units and a resin wherein all the repeating units consist of methacrylate repeating units and acrylate repeating units. However, it is preferred that acrylate repeating units account for 50 mol % or less of all the repeating units. It is more preferred to employ a copolymer containing 20 to 50 mol % of (meth)acrylate repeating units having an acid-decomposable group represented by the general formula (I), 20 to 50 mol % of (meth)acrylate repeating units having a lactone group, 5 to 30 mol % of (meth)acrylate repeating units having an alicyclic hydrocarbon structure substituted with a cyano group or a hydroxyl group, 0 to 20 mol % of any of the repeating units of the general formula (III) and 0 to 20 mol % of other (meth)acrylate repeating units.

In the event of exposure of the positive photosensitive composition of the present invention to KrF excimer laser beams, electron beams, X-rays or high-energy light rays of 50 nm or less wavelength (EUV, etc.), it is preferred for the resin (A) to have not only the repeating units of the general formula (I) but also hydroxystyrene repeating units. More preferably, the resin (A) has hydroxystyrene repeating units, hydroxystyrene repeating units protected by an acid-decomposable group and acid-decomposable repeating units of a (meth)acrylic acid tertiary alkyl ester, etc.

As preferred repeating units having an acid-decomposable group, there can be mentioned, for example, repeating units derived from t-butoxycarbonyloxystyrene, a 1-alkoxyethoxystyrene and a (meth)acrylic acid tertiary alkyl ester. Repeating units derived from a 2-alkyl-2-adamantyl (meth)acrylate and a dialkyl(1-adamantyl)methyl (meth)acrylate are more preferred.

The resin (A) can be synthesized by conventional techniques (for example, radical polymerization). As conventional synthetic methods, there can be mentioned, for example, a batch polymerization method in which a monomer species and an initiator are dissolved in a solvent and heated so as to accomplish polymerization, and a dropping polymerization method in which a solution of monomer species and initiator is added by dropping to a heated solvent over a period of 1 to 10 hours. The dropping polymerization method is preferred. As a reaction solvent, there can be mentioned, for example, an ether, such as tetrahydrofuran, 1,4-dioxane or diisopropyl ether; a ketone, such as methyl ethyl ketone or methyl isobutyl ketone; an ester solvent, such as ethyl acetate; an amide solvent, such as dimethylformamide or dimethylacetamide; or a later described solvent capable of dissolving the composition of the present invention, such as propylene glycol monomethyl ether acetate, propylene glycol monomethyl ether or cyclohexanone. It is preferred that the polymerization be performed with the use of the same solvent as employed in the positive photosensitive composition of the present invention. This would inhibit any particle generation during storage.

The polymerization reaction is preferably carried out in an atmosphere of an inert gas, such as nitrogen or argon. With respect to the polymerization initiator, the polymerization is initiated by the use of a commercially available radical initiator (azo initiator, peroxide, etc.) as a polymerization initiator. Among radical initiators, an azo initiator is preferred. An azo initiator having an ester group, a cyano group or a carboxyl group is especially preferred. As preferred initiators, there can be mentioned azobisisobutyronitrile, azobisdimethylvaleronitrile, dimethyl 2,2′-azobis(2-methylpropionate) and the like. According to necessity, supplementation of an initiator or divided addition thereof may be effected. After the completion of reaction, the reaction mixture is poured into a solvent. The desired polymer is recovered according to a method for powder or solid recovery, etc. The concentration during the reaction is in the range of 5 to 50 mass %, preferably 10 to 30 mass %. The reaction temperature is generally in the range of 10° to 150° C., preferably 30° to 120° C. and still preferably 60° to 100° C.

The weight average molecular weight of the resin (A) in terms of polystyrene molecular weight as measured by GPC is preferably in the range of 1000 to 200,000, more preferably 2000 to 20,000, still more preferably 3000 to 15,000 and especially preferably 5000 to 12,000. The regulation of the weight average molecular weight to 1000 to 200,000 would prevent deterioration of heat resistance and dry etching resistance and also prevent deterioration of developability and increase of viscosity leading to poor film forming property.

Use is made of the resin whose degree of dispersal (molecular weight distribution) is generally in the range of 1 to 3, preferably 1 to 2 and still further preferably 1.4 to 1.7. The smaller the molecular weight distribution, the more excellent the resolving power and resist profile and the smoother the side wall of the resist pattern to thereby attain excellence in roughness.

The content of resin (A) in the positive photosensitive composition based on the total solid content of the positive photosensitive composition is preferably in the range of 50 to 99 mass %, more preferably 60 to 95 mass %.

[2] Compound that when Exposed to Actinic Rays or Radiation, Generates an Acid (Component (B))

The positive photosensitive composition of the present invention contains a compound that when exposed to actinic rays or radiation, generates an acid (hereinafter also referred to as “acid generator”).

As the acid generator, use can be made of a member appropriately selected from among a photoinitiator for photocationic polymerization, a photoinitiator for photoradical polymerization, a photo-achromatic agent and photo-discoloring agent for dyes, any of publicly known compounds that when exposed to actinic rays or radiation, generate an acid, employed in microresist, etc., and mixtures thereof.

For example, as the acid generator, there can be mentioned a diazonium salt, a phosphonium salt, a sulfonium salt, an iodonium salt, an imide sulfonate, an oxime sulfonate, diazosulfone, disulfone, o-nitrobenzyl sulfonate or the like.

Further, use can be made of compounds obtained by introducing any of the above groups or compounds that when exposed to actinic rays or radiation, generate an acid in a polymer principal chain or side chain, for example, compounds described in U.S. Pat. No. 3,849,137, DE 3914407, JP-A's-63-26653, 55-164824, 62-69263, 63-146038, 63-163452, 62-153853, 63-146029, etc.

Furthermore, use can be made of compounds that when exposed to light, generate an acid described in U.S. Pat. No. 3,779,778 and EP 126,712.

As preferred compounds among the acid generators, there can be mentioned those of the following general formulae (ZI), (ZII) and (ZIII).

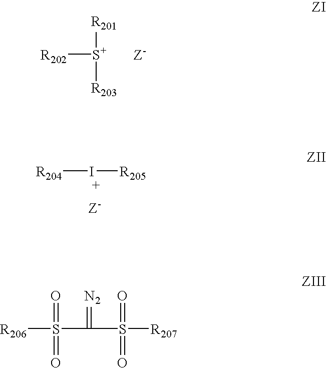

In the above general formula (ZI),

each of R₂₀₁, R₂₀₂ and R₂₀₃ independently represents an organic group.

The number of carbon atoms of the organic group represented by R₂₀₁, R₂₀₂ and R₂₀₃ is generally in the range of 1 to 30, preferably 1 to 20.

Two of R₂₀₁ to R₂₀₃ may be bonded with each other to thereby form a ring structure, and the ring within the same may contain an oxygen atom, a sulfur atom, an ester bond, an amido bond or a carbonyl group. As a group formed by bonding of two of R₂₀₁ to R₂₀₃, there can be mentioned an alkylene group (for example, a butylene group or a pentylene group).

Z⁻ represents a nonnucleophilic anion.

As the nonnucleophilic anion represented by Z⁻, there can be mentioned, for example, a sulfonate anion, a carboxylate anion, a sulfonylimido anion, a bis(alkylsulfonyl)imido anion, a tris(alkylsulfonyl)methyl anion or the like.

The nonnucleophilic anion means an anion whose capability of inducing a nucleophilic reaction is extremely low and is an anion capable of inhibiting any temporal decomposition by intramolecular nucleophilic reaction. This would realize an enhancement of the temporal stability of the resist.

As the sulfonate anion, there can be mentioned, for example, an aliphatic sulfonate anion, an aromatic sulfonate anion, a camphor sulfonate anion or the like.

As the carboxylate anion, there can be mentioned, for example, an aliphatic carboxylate anion, an aromatic carboxylate anion, an aralkyl carboxylate anion or the like.

The aliphatic moiety of the aliphatic sulfonate anion may be an alkyl group or a cycloalkyl group, preferably an alkyl group having 1 to 30 carbon atoms or a cycloalkyl group having 3 to 30 carbon atoms. As such, there can be mentioned, for example, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a boronyl group or the like.

As a preferred aromatic group of the aromatic sulfonate anion, there can be mentioned an aryl group having 6 to 14 carbon atoms, for example, a phenyl group, a tolyl group, a naphthyl group or the like.

The alkyl group, cycloalkyl group and aryl group of the aliphatic sulfonate anion and aromatic sulfonate anion may have a substituent. As the substituent of the alkyl group, cycloalkyl group and aryl group of the aliphatic sulfonate anion and aromatic sulfonate anion, there can be mentioned, for example, a nitro group, a halogen atom (fluorine atom, chlorine atom, bromine atom or iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), a cycloalkylalkyloxyalkyloxy group (preferably having 8 to 20 carbon atoms) or the like. The aryl group and ring structure of these groups may further have an alkyl group (preferably having 1 to 15 carbon atoms) as its substituent.

As the aliphatic moiety of the aliphatic carboxylate anion, there can be mentioned the same alkyl groups and cycloalkyl groups as mentioned with respect to the aliphatic sulfonate anion.

As the aromatic group of the aromatic carboxylate anion, there can be mentioned the same aryl groups as mentioned with respect to the aromatic sulfonate anion.

As a preferred aralkyl group of the aralkyl carboxylate anion, there can be mentioned an aralkyl group having 6 to 12 carbon atoms, for example, a benzyl group, a phenethyl group, a naphthylmethyl group, a naphthylethyl group or the like.

The alkyl group, cycloalkyl group, aryl group and aralkyl group of the aliphatic carboxylate anion, aromatic carboxylate anion and aralkyl carboxylate anion may have a substituent. As the substituent of the alkyl group, cycloalkyl group, aryl group and aralkyl group of the aliphatic carboxylate anion, aromatic carboxylate anion and aralkyl carboxylate anion, there can be mentioned, for example, the same halogen atom, alkyl group, cycloalkyl group, alkoxy group, alkylthio group, etc. as mentioned with respect to the aromatic sulfonate anion.

As the sulfonylimido anion, there can be mentioned, for example, a saccharin anion.

The alkyl group of the bis(alkylsulfonyl)imido anion and tris(alkylsulfonyl)methyl anion is preferably an alkyl group having 1 to 5 carbon atoms. As such, there can be mentioned, for example, a methyl group, an ethyl group, a propyl group, an isopropyl group, an n-butyl group, an isobutyl group, a sec-butyl group, a pentyl group, a neopentyl group or the like. As a substituent of these alkyl groups, there can be mentioned a halogen atom, an alkyl group substituted with a halogen atom, an alkoxy group, an alkylthio group, an alkyloxysulfonyl group, an aryloxysulfonyl group, a cycloalkylaryloxysulfonyl group or the like. An alkyl group substituted with a fluorine atom is preferred.

As the other nonnucleophilic anions, there can be mentioned, for example, phosphorus fluoride, boron fluoride, antimony fluoride and the like.

The nonnucleophilic anion represented by Z⁻ is preferably selected from among an aliphatic sulfonate anion substituted at its α-position of sulfonic acid with a fluorine atom, an aromatic sulfonate anion substituted with a fluorine atom or a group having a fluorine atom, a bis(alkylsulfonyl)imido anion whose alkyl group is substituted with a fluorine atom and a tris(alkylsulfonyl)methide anion whose alkyl group is substituted with a fluorine atom. More preferably, the nonnucleophilic anion is a perfluorinated aliphatic sulfonate anion having 4 to 8 carbon atoms or a benzene sulfonate anion having a fluorine atom. Still more preferably, the nonnucleophilic anion is a nonafluorobutane sulfonate anion, a perfluorooctane sulfonate anion, a pentafluorobenzene sulfonate anion or a 3,5-bis(trifluoromethyl)benzene sulfonate anion.

As the organic groups represented by R₂₀₁, R₂₀₂ and R₂₀₃, there can be mentioned, for example, groups corresponding to the later-described compounds of the general formulae (ZI-1), (ZI-2) and (ZI-3).

The organic groups may be those of compounds with two or more of the structures of the general formula (ZI). For example, the compounds may be those of a structure wherein at least one of R₂₀₁ to R₂₀₃ of a compound of the general formula (ZI) is bonded with at least one of R₂₀₁ to R₂₀₃ of another compound of the general formula (ZI).

As preferred components represented by the formula (ZI), there can be mentioned the below-described compounds of the formulae (ZI-1), (ZI-2) and (ZI-3).

The compounds (ZI-1) are arylsulfonium compounds of the general formula (ZI) wherein at least one of R₂₀₁ to R₂₀₃ is an aryl group, namely, compounds containing an arylsulfonium as a cation.

In the arylsulfonium compounds, all of the R₂₀₁ to R₂₀₃ may be aryl groups. It is also appropriate that the R₂₀₁ to R₂₀₃ are partially an aryl group and the remainder is an alkyl group or a cycloalkyl group.

As the arylsulfonium compounds, there can be mentioned, for example, a triarylsulfonium compound, a diarylalkylsulfonium compound, an aryldialkylsulfonium compound, a diarylcycloalkylsulfonium compound or an aryldicycloalkylsulfonium compound.

The aryl group of the arylsulfonium compounds is preferably a phenyl group or a naphthyl group, more preferably a phenyl group. The aryl group may be one having a heterocyclic structure containing an oxygen atom, nitrogen atom, sulfur atom or the like. As the aryl group having a heterocyclic structure, there can be mentioned, for example, a pyrrole residue (group formed by loss of one hydrogen atom from pyrrole), a furan residue (group formed by loss of one hydrogen atom from furan), a thiophene residue (group formed by loss of one hydrogen atom from thiophene), an indole residue (group formed by loss of one hydrogen atom from indole), a benzofuran residue (group formed by loss of one hydrogen atom from benzofuran), a benzothiophene residue (group formed by loss of one hydrogen atom from benzothiophene) or the like. When the arylsulfonium compound has two or more aryl groups, the two or more aryl groups may be identical to or different from each other.

The alkyl group or cycloalkyl group of the arylsulfonium compound according to necessity is preferably a linear or branched alkyl group having 1 to 15 carbon atoms or a cycloalkyl group having 3 to 15 carbon atoms. As such, there can be mentioned, for example, a methyl group, an ethyl group, a propyl group, an n-butyl group, a sec-butyl group, a t-butyl group, a cyclopropyl group, a cyclobutyl group, a cyclohexyl group or the like.

The aryl group, alkyl group or cycloalkyl group represented by R₂₀₁ to R₂₀₃ may have as a substituent an alkyl group (for example, 1 to 15 carbon atoms), a cycloalkyl group (for example, 3 to 15 carbon atoms), an aryl group (for example, 6 to 14 carbon atoms), an alkoxy group (for example, 1 to 15 carbon atoms), a halogen atom, a hydroxyl group or a phenylthio group. Preferred substituents are a linear or branched alkyl group having 1 to 12 carbon atoms, a cycloalkyl group having 3 to 12 carbon atoms and a linear, branched or cyclic alkoxy group having 1 to 12 carbon atoms. More preferred substituents are an alkyl group having 1 to 4 carbon atoms and an alkoxy group having 1 to 4 carbon atoms. The substituents may be contained by any one of the three R₂₀₁ to R₂₀₃, or alternatively may be contained by all of the three R₂₀₁ to R₂₀₃. When R₂₀₁ to R₂₀₃ represent an aryl group, the substituent preferably lies at the p-position of the aryl group.

Now, the compounds of the formula (ZI-2) will be described.

The compounds of the formula (ZI-2) are compounds of the formula (ZI) wherein each of R₂₀₁ to R₂₀₃ independently represents an organic group having no aromatic ring. The aromatic rings include an aromatic ring having a heteroatom.

The organic group having no aromatic ring represented by R₂₀₁ to R₂₀₃ generally has 1 to 30 carbon atoms, preferably 1 to 20 carbon atoms.

Preferably, each of R₂₀₁ to R₂₀₃ independently represents an alkyl group, a cycloalkyl group, an allyl group or a vinyl group. More preferred groups are a linear or branched 2-oxoalkyl group, a 2-oxocycloalkyl group and an alkoxycarbonylmethyl group. Especially preferred is a linear or branched 2-oxoalkyl group.

As preferred alkyl groups and cycloalkyl groups represented by R₂₀₁ to R₂₀₃, there can be mentioned a linear or branched alkyl group having 1 to 10 carbon atoms (for example, a methyl group, an ethyl group, a propyl group, a butyl group or a pentyl group) and a cycloalkyl group having 3 to 10 carbon atoms (a cyclopentyl group, a cyclohexyl group or a norbornyl group). As more preferred alkyl groups, there can be mentioned a 2-oxoalkyl group and an alkoxycarbonylmethyl group. As more preferred cycloalkyl group, there can be mentioned a 2-oxocycloalkyl group.

The 2-oxoalkyl group may be linear or branched. A preferred group is one having >C═O at the 2-position of the alkyl group.

A preferred 2-oxocycloalkyl group is one having >C═O at the 2-position of the cycloalkyl group.

As preferred alkoxy groups of the alkoxycarbonylmethyl group, there can be mentioned alkoxy groups having 1 to 5 carbon atoms (a methoxy group, an ethoxy group, a propoxy group, a butoxy group and a pentoxy group).

The R₂₀₁ to R₂₀₃ may be further substituted with a halogen atom, an alkoxy group (for example, 1 to 5 carbon atoms), a hydroxyl group, a cyano group or a nitro group.

Now, the compounds (ZI-3) will be described.

The compounds (ZI-3) are those represented by the following general formula (ZI-3) which have a phenacylsulfonium salt structure.

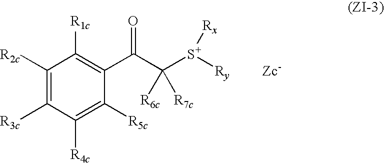

In the general formula (ZI-3),

each of R_{1c} to R_{5c} independently represents a hydrogen atom, an alkyl group, a cycloalkyl group, an alkoxy group or a halogen atom.

Each of R_{6c} and R_{7c} independently represents a hydrogen atom, an alkyl group or a cycloalkyl group.

Each of Rₓ and R_{y} independently represents an alkyl group, a cycloalkyl group, an allyl group or a vinyl group.

Any two or more of R_{1c} to R_{5c}, and R_{6c} and R_{7c}, and Rₓ and R_{y} may be bonded with each other to thereby form a ring structure. This ring structure may contain an oxygen atom, a sulfur atom, an ester bond or an amido bond. As the group formed by bonding of any two or more of R_{1c} to R_{5c}, and R_{6c} and R_{7c}, and Rₓ and R_{y}, there can be mentioned a butylene group, a pentylene group or the like.

Zc⁻ represents a nonnucleophilic anion. There can be mentioned the same nonnucleophilic anions as mentioned with respect to the Z⁻ of the general formula (ZI).

The alkyl group represented by R_{1c} to R_{7c} may be linear or branched. As such, there can be mentioned, for example, an alkyl group having 1 to 20 carbon atoms, preferably a linear or branched alkyl group having 1 to 12 carbon atoms (for example, a methyl group, an ethyl group, a linear or branched propyl group, a linear or branched butyl group or a linear or branched pentyl group). As the cycloalkyl group, there can be mentioned, for example, a cycloalkyl group having 3 to 10 carbon atoms (for example, a cyclopentyl group or a cyclohexyl group).

The alkoxy group represented by R_{1c} to R_{5c} may be linear, or branched, or cyclic. As such, there can be mentioned, for example, an alkoxy group having 1 to 10 carbon atoms, preferably a linear or branched alkoxy group having 1 to 5 carbon atoms (for example, a methoxy group, an ethoxy group, a linear or branched propoxy group, a linear or branched butoxy group or a linear or branched pentoxy group) and a cycloalkoxy group having 3 to 8 carbon atoms (for example, a cyclopentyloxy group or a cyclohexyloxy group).

Preferably, any one of R_{1c} to R_{5c} is a linear or branched alkyl group, a cycloalkyl group or a linear, branched or cyclic alkoxy group. More preferably, the sum of carbon atoms of R_{1c} to R_{5c} is in the range of 2 to 15. Accordingly, there can be attained an enhancement of solvent solubility and inhibition of particle generation during storage.

As the alkyl groups and cycloalkyl groups represented by Rₓ and R_{y}, there can be mentioned the same alkyl groups and cycloalkyl groups as mentioned with respect to R_{1c} to R_{7c}. Among them, a 2-oxoalkyl group, a 2-oxocycloalkyl group and an alkoxycarbonylmethyl group are preferred.

As the 2-oxoalkyl group and 2-oxocycloalkyl group, there can be mentioned groups having >C═O at the 2-position of the alkyl group and cycloalkyl group represented by R_{1c} to R_{7c}.

Regarding the alkoxy group of the alkoxycarbonylmethyl group, there can be mentioned the same alkoxy groups as mentioned with respect to R_{1c} to R_{5c}.

Each of Rₓ and R_{y} represents an alkyl group or cycloalkyl group having preferably 4 or more carbon atoms, more preferably 6 or more carbon atoms and still more preferably 8 or more carbon atoms.

Now, the general formulae (ZII) and (ZIII) will be described.

In the general formulae (ZII) and (ZIII),

each of R₂₀₄ to R₂₀₇ independently represents an aryl group, an alkyl group or a cycloalkyl group,

The aryl group represented by R₂₀₄ to R₂₀₇ is preferably a phenyl group or a naphthyl group, more preferably a phenyl group. The aryl group represented by R₂₀₄ to R₂₀₇ may be one having a heterocyclic structure containing an oxygen atom, nitrogen atom, sulfur atom or the like. As the aryl group having a heterocyclic structure, there can be mentioned, for example, a pyrrole residue (group formed by loss of one hydrogen atom from pyrrole), a furan residue (group formed by loss of one hydrogen atom from furan), a thiophene residue (group formed by loss of one hydrogen atom from thiophene), an indole residue (group formed by loss of one hydrogen atom from indole), a benzofuran residue (group formed by loss of one hydrogen atom from benzofuran), a benzothiophene residue (group formed by loss of one hydrogen atom from benzothiophene) or the like.

As preferred alkyl groups and cycloalkyl groups represented by R₂₀₄ to R₂₀₇, there can be mentioned a linear or branched alkyl group having 1 to 10 carbon atoms (for example, a methyl group, an ethyl group, a propyl group, a butyl group or a pentyl group) and a cycloalkyl group having 3 to 10 carbon atoms (a cyclopentyl group, a cyclohexyl group or a norbornyl group).

The aryl group, alkyl group and cycloalkyl group represented by R₂₀₄ to R₂₀₇ may have a substituent. As a possible substituent in the aryl group, alkyl group and cycloalkyl group represented by R₂₀₄ to R₂₀₇, there can be mentioned, for example, an alkyl group (for example, 1 to 15 carbon atoms), a cycloalkyl group (for example, 3 to 15 carbon atoms), an aryl group (for example, 6 to 15 carbon atoms), an alkoxy group (for example, 1 to 15 carbon atoms), a halogen atom, a hydroxyl group, a phenylthio group or the like.

Z⁻ represents a nonnucleophilic anion. As such, there can be mentioned the same nonnucleophilic anions as mentioned with respect to the Z⁻ of the general formula (ZI).

As the acid generators, there can be further mentioned the compounds of the following general formulae (ZIV), (ZV) and (ZVI).

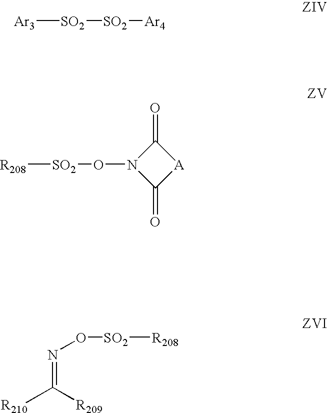

In the general formulae (ZIV) to (ZVI),

each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Among the acid generators, the compounds of the general formulae (ZI) to (ZIII) are more preferred.

As a preferred acid generator, there can be mentioned a compound that generates an acid having one sulfonate group or imido group. As a more preferred acid generator, there can be mentioned a compound that generates a monovalent perfluoroalkanesulfonic acid, a compound that generates a monovalent aromatic sulfonic acid substituted with a fluorine atom or fluorine-atom-containing group, or a compound that generates a monovalent imidic acid substituted with a fluorine atom or fluorine-atom-containing group. As a still more preferred acid generator, there can be mentioned any of sulfonium salts of fluorinated alkanesulfonic acid, fluorinated benzenesulfonic acid, fluorinated imidic acid and fluorinated methide acid. With respect to practicable acid generators, it is especially preferred that the generated acid be a fluorinated alkanesulfonic acid, fluorinated benzenesulfonic acid or fluorinated imidic acid of −1 or below pKa. In the use thereof, an enhancement of sensitivity is attained.

Especially preferred examples of the acid generators are as follows.

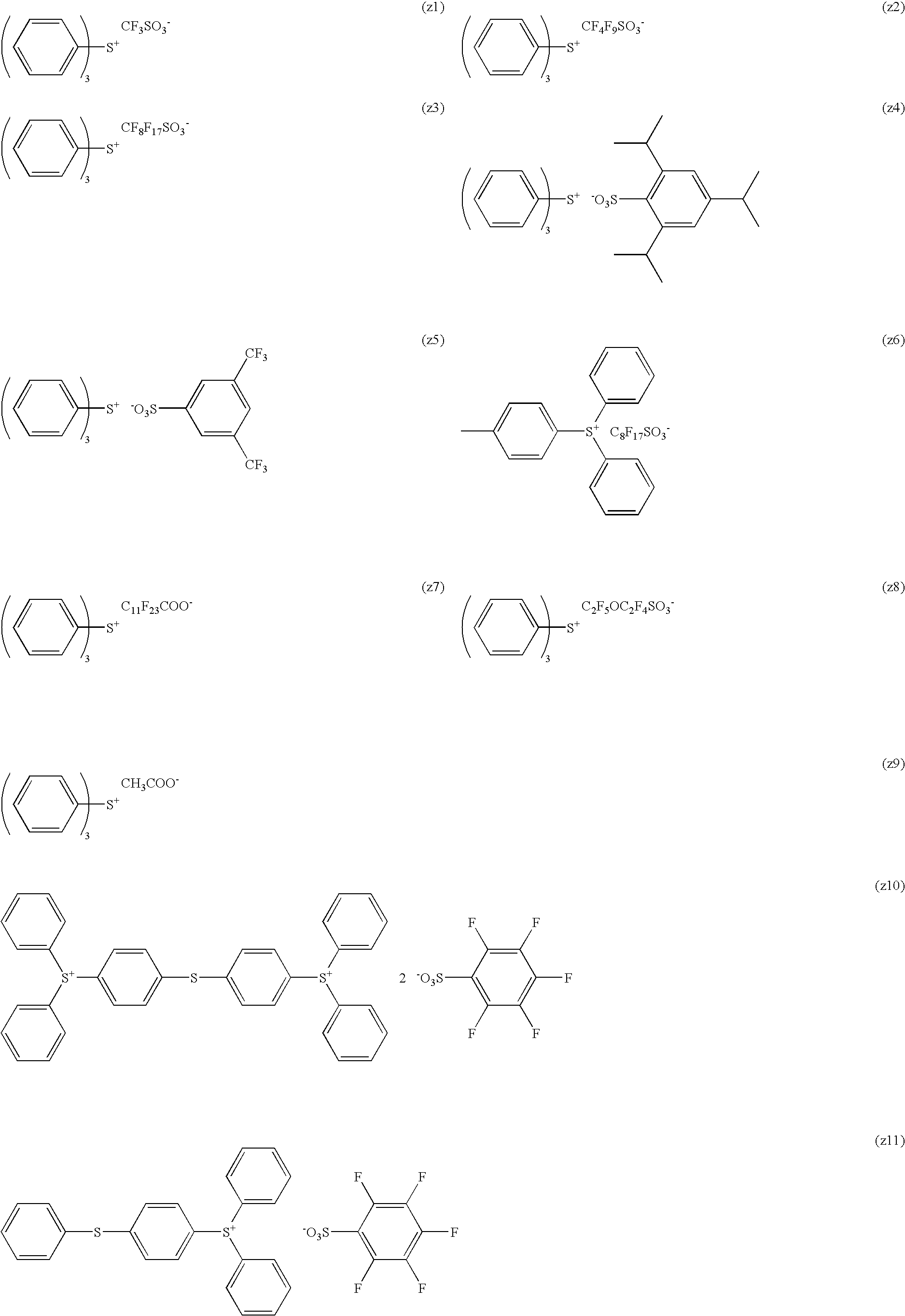

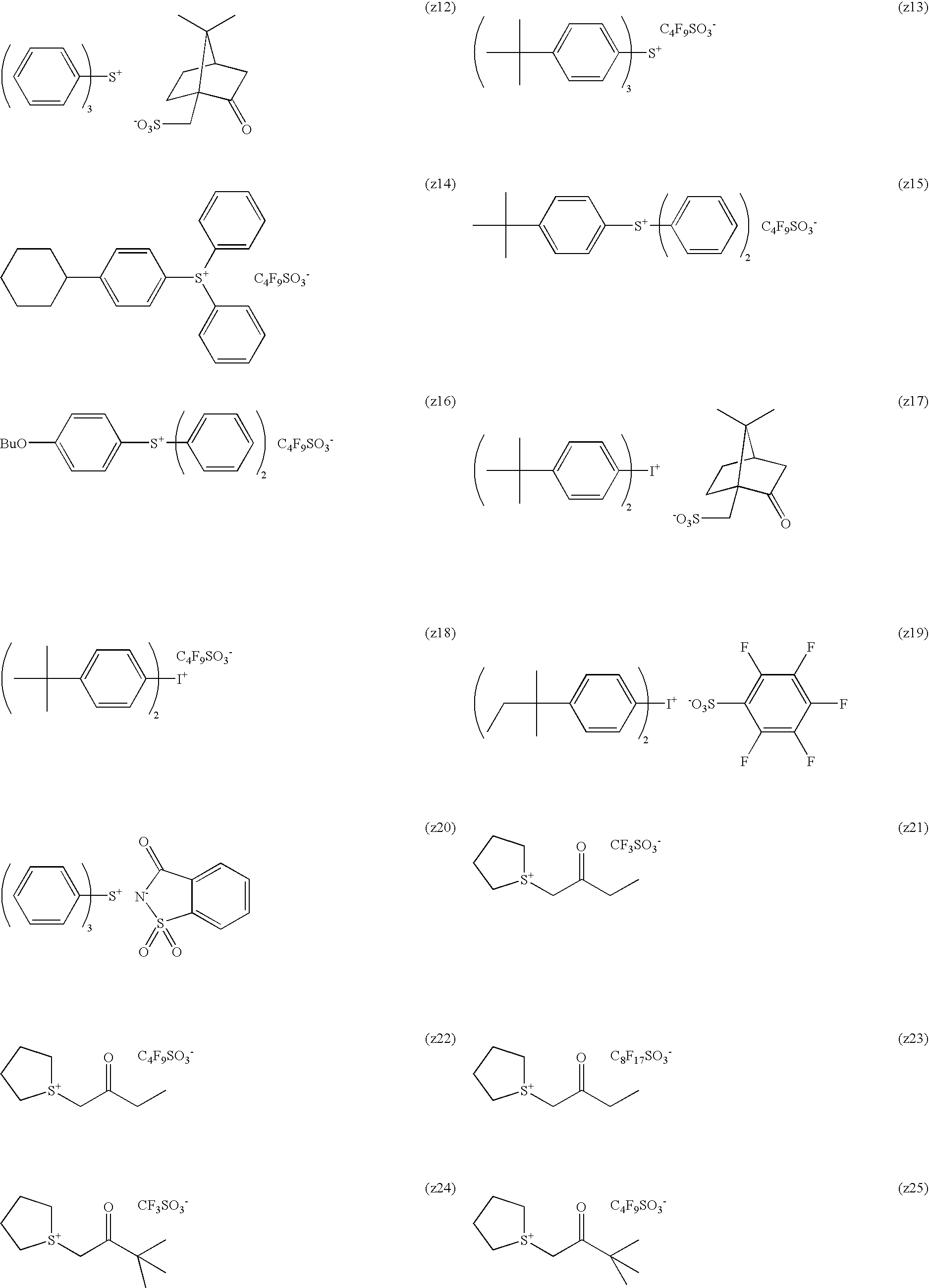

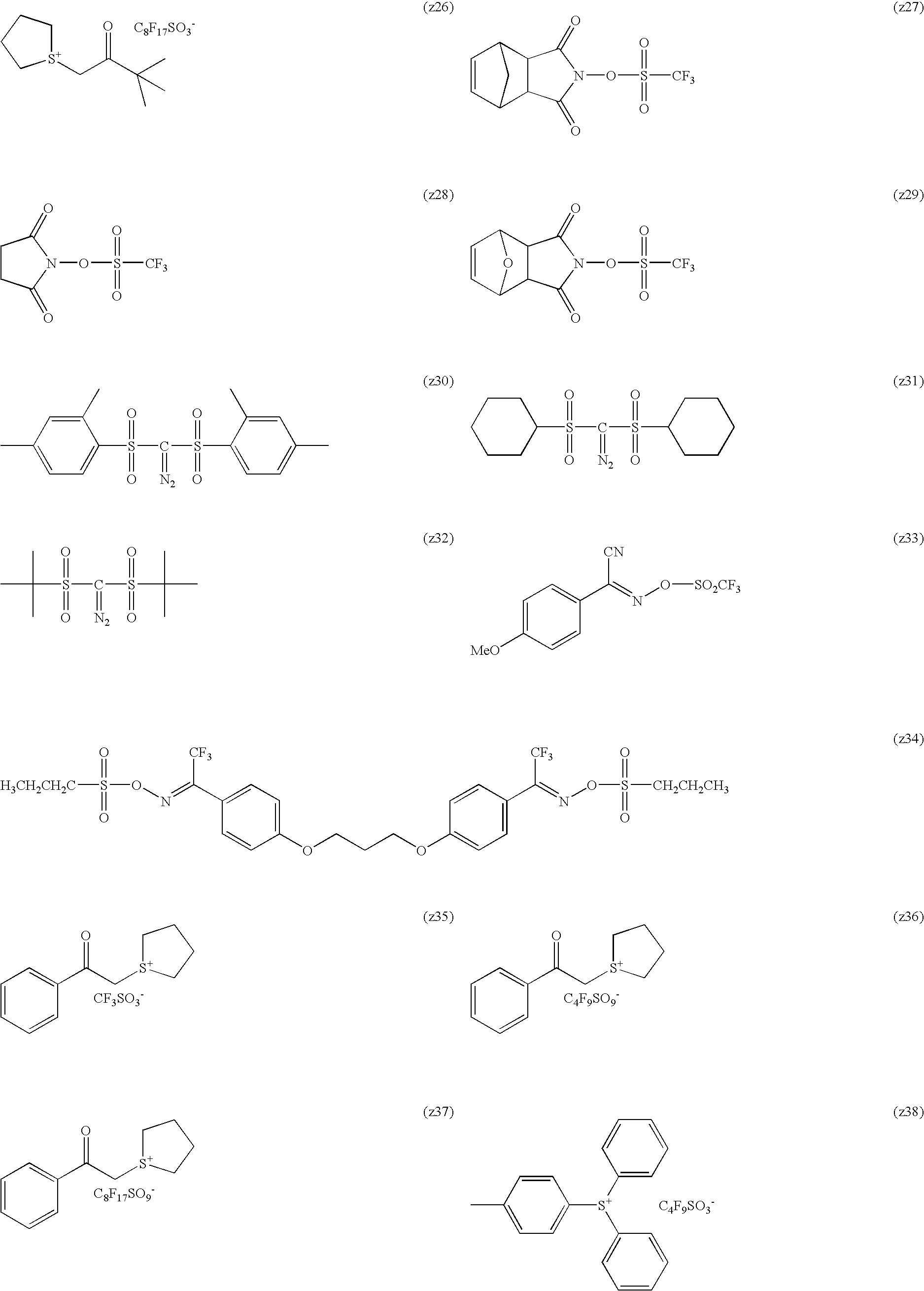

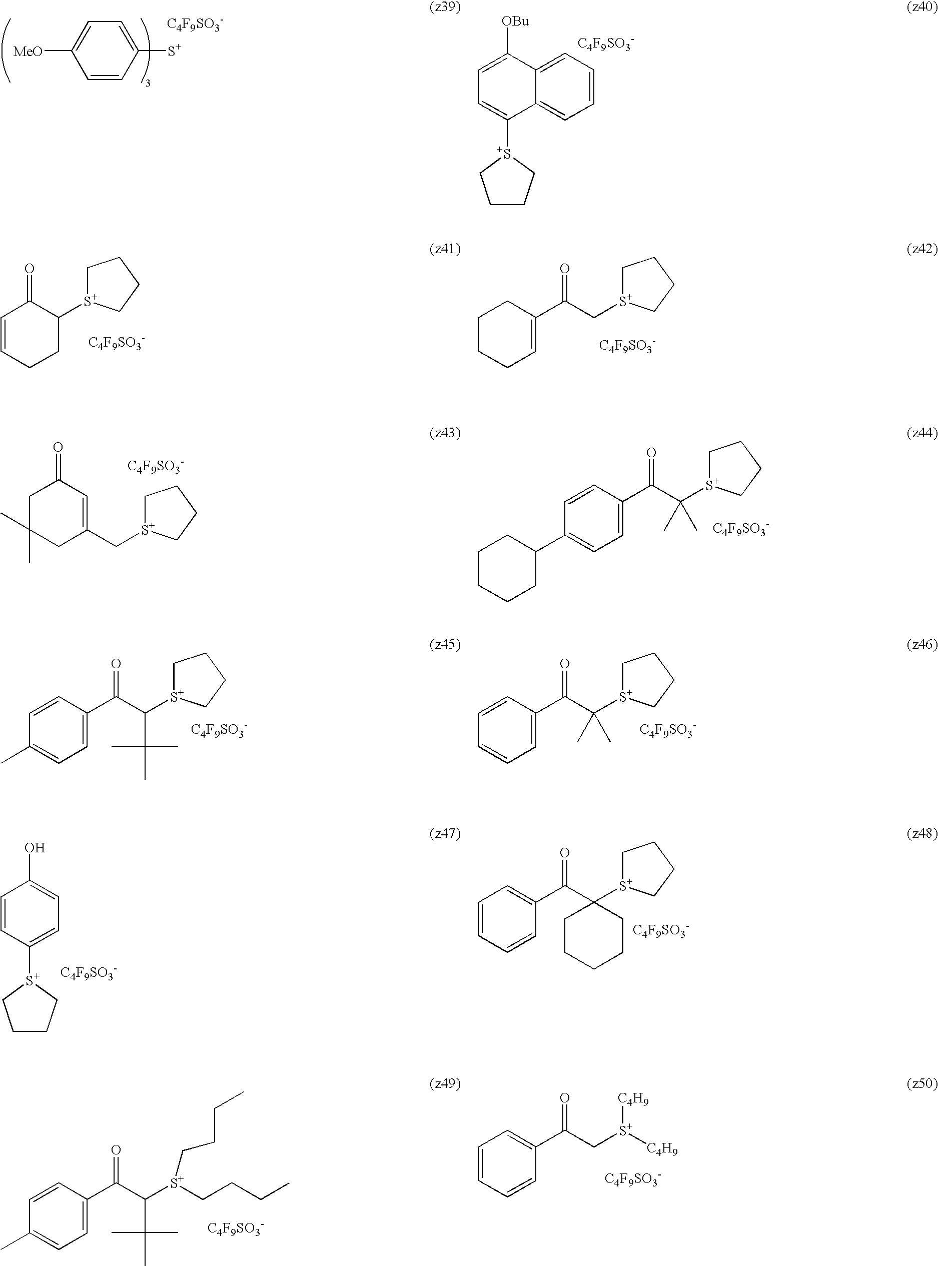

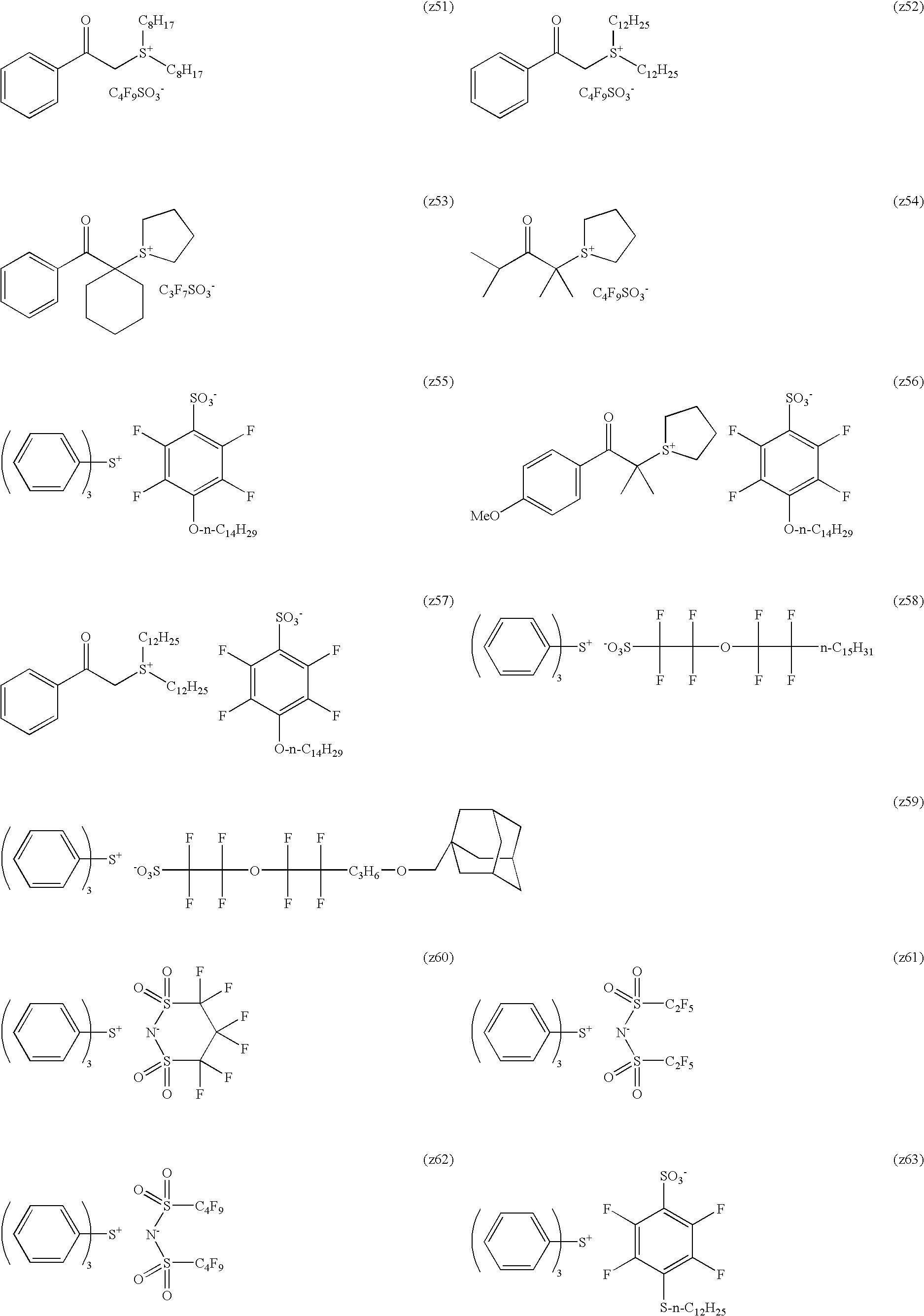

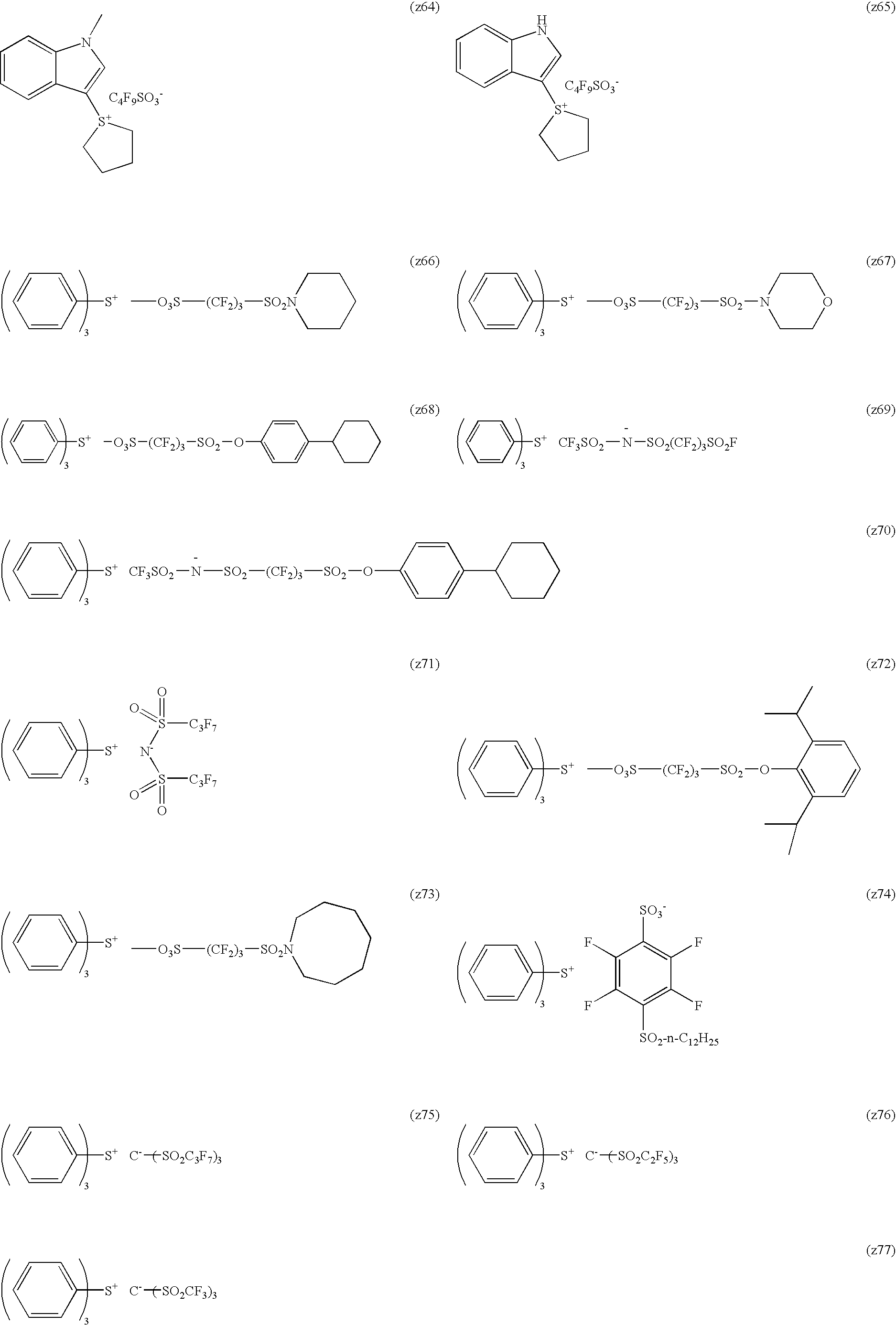

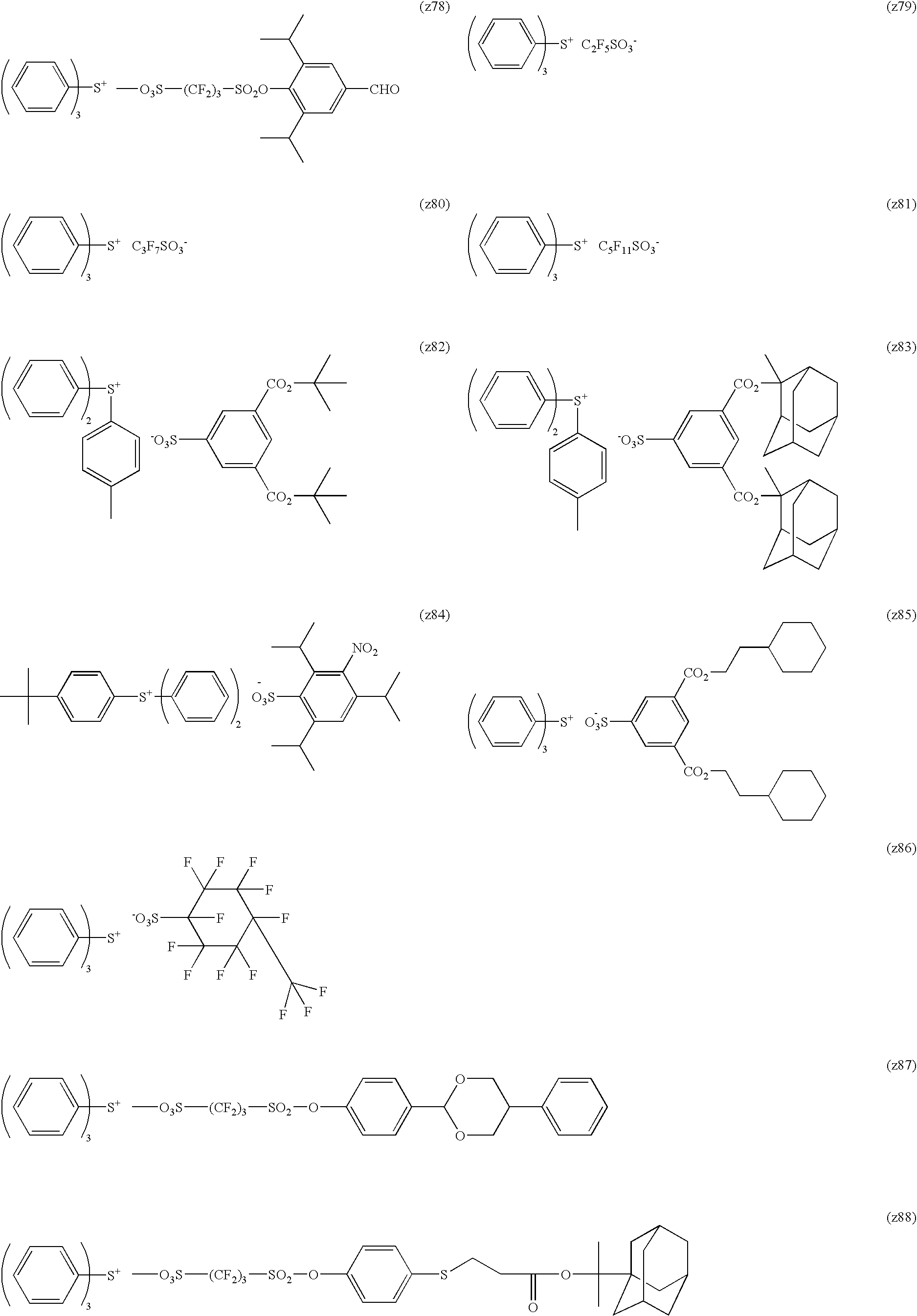

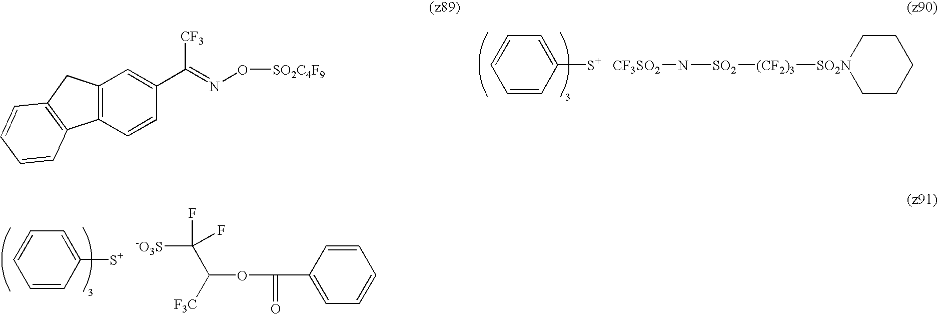

The acid generators can be used either individually or in combination.

The content of the acid generator in the positive photosensitive composition is preferably in the range of 0.1 to 20 mass %, more preferably 0.5 to 10 mass % and still more preferably 1 to 7 mass % based on the total solid of the positive photosensitive composition.

[3] Basic Compound (Component (C))

The positive photosensitive composition of the present invention preferably contains a basic compound so as to decrease any performance alteration over time from exposure to heating.

As preferred basic compounds, there can be mentioned the compounds having the structures of the following formulae (A) to (E).

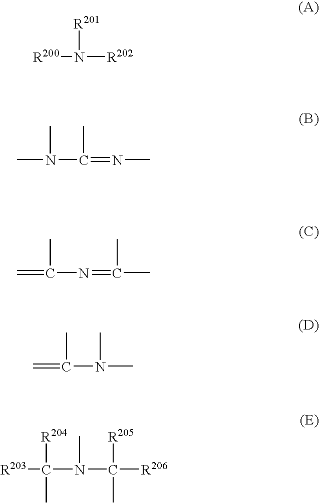

In the general formulae (A) and (E),

R₂₀₀, R₂₀₁ and R₂₀₂ may be identical to or different from each other and each represent a hydrogen atom, an alkyl group (preferably having 1 to 20 carbon atoms), a cycloalkyl group (preferably having 3 to 20 carbon atoms) or an aryl group (having 6 to 20 carbon atoms). R₂₀₁ and R₂₀₂ may be bonded with each other to thereby form a ring.

With respect to the above alkyl group, as a preferred substituted alkyl group, there can be mentioned an aminoalkyl group having 1 to 20 carbon atoms, a hydroxyalkyl group having 1 to 20 carbon atoms or a cyanoalkyl group having 1 to 20 carbon atoms.

R₂₀₃, R₂₀₄, R₂₀₅ and R₂₀₆ may be identical to or different from each other and each represent an alkyl group having 1 to 20 carbon atoms.

It is more preferred that in the general formulae (A) and (E) the alkyl group be unsubstituted.

As preferred compounds, there can be mentioned guanidine, aminopyrrolidine, pyrazole, pyrazoline, piperazine, aminomorpholine, aminoalkylmorpholine, piperidine and the like. As more preferred compounds, there can be mentioned compounds with an imidazole structure, a diazabicyclo structure, an onium hydroxide structure, an onium carboxylate structure, a trialkylamine structure, an aniline structure or a pyridine structure, alkylamine derivatives having a hydroxyl group and/or an ether bond, aniline derivatives having a hydroxyl group and/or an ether bond and the like.

As the compounds with an imidazole structure, there can be mentioned imidazole, 2,4,5-triphenylimidazole, benzimidazole, 2-phenylbenzimidazole and the like. As the compounds with a diazabicyclo structure, there can be mentioned 1,4-diazabicyclo[2,2,2]octane, 1,5-diazabicyclo[4,3,0]non-5-ene, 1,8-diazabicyclo[5,4,0]undec-7-ene and the like. As the compounds with an onium hydroxide structure, there can be mentioned tetrabutylammonium hydroxide, triarylsulfonium hydroxide, phenacylsulfonium hydroxide, and sulfonium hydroxides having a 2-oxoalkyl group such as triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide and the like. As the compounds with an onium carboxylate structure, there can be mentioned those having a carboxylate at the anion moiety of the compounds with an onium hydroxide structure, for example, acetate, adamantane-1-carboxylate, perfluoroalkyl carboxylate and the like. As the compounds with a trialkylamine structure, there can be mentioned tri(n-butyl)amine, tri(n-octyl)amine and the like. As the aniline compounds, there can be mentioned 2,6-diisopropylaniline, N,N-dimethylaniline, N,N-dibutylaniline, N,N-dihexylaniline and the like. As the alkylamine derivatives having a hydroxyl group and/or an ether bond, there can be mentioned ethanolamine, diethanolamine, triethanolamine, N-phenyldiethanolamine, tris(methoxyethoxyethyl)amine and the like. As the aniline derivatives having a hydroxyl group and/or an ether bond, there can be mentioned N,N-bis(hydroxyethyl)aniline and the like.

As preferred basic compounds, there can be further mentioned an amine compound having a phenoxy group, an ammonium salt compound having a phenoxy group, an amine compound having a sulfonic ester group and an ammonium salt compound having a sulfonic ester group.

As the amine compound, use can be made of primary, secondary and tertiary amine compounds. An amine compound having at least one alkyl group bonded to the nitrogen atom thereof is preferred. Among the amine compounds, a tertiary amine compound is more preferred. In the amine compounds, when at least one alkyl group (preferably having 1 to 20 carbon atoms) is bonded to the nitrogen atom, a cycloalkyl group (preferably having 3 to 20 carbon atoms) or an aryl group (preferably having 6 to 12 carbon atoms) besides the alkyl group may be bonded to the nitrogen atom. In the amine compounds, it is preferred that the alkyl chain contain an oxygen atom, thereby forming an oxyalkylene group. The number of oxyalkylene groups in each molecule is one or more, preferably 3 to 9 and further preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

As the ammonium salt compound, use can be made of primary, secondary, tertiary and quaternary ammonium salt compounds. An ammonium salt compound having at least one alkyl group bonded to the nitrogen atom thereof is preferred. In the ammonium salt compounds, when at least one alkyl group (preferably having 1 to 20 carbon atoms) is bonded to the nitrogen atom, a cycloalkyl group (preferably having 3 to 20 carbon atoms) or an aryl group (preferably having 6 to 12 carbon atoms) besides the alkyl group may be bonded to the nitrogen atom. In the ammonium salt compounds, it is preferred that the alkyl chain contain an oxygen atom, thereby forming an oxyalkylene group. The number of oxyalkylene groups in each molecule is one or more, preferably 3 to 9 and further preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

As the anion of the ammonium salt compounds, there can be mentioned a halogen atom, a sulfonate, a borate, a phosphate or the like. Of these, a halogen atom and sulfonate are preferred. Among halogen atoms, chloride, bromide and iodide are especially preferred. Among sulfonates, an organic sulfonate having 1 to 20 carbon atoms is especially preferred. As the organic sulfonate, there can be mentioned an aryl sulfonate and an alkyl sulfonate having 1 to 20 carbon atoms. The alkyl group of the alkyl sulfonate may have a substituent. As the substituent, there can be mentioned, for example, fluorine, chlorine, bromine, an alkoxy group, an acyl group, an aryl group or the like. As specific alkyl sulfonates, there can be mentioned methane sulfonate, ethane sulfonate, butane sulfonate, hexane sulfonate, octane sulfonate, benzyl sulfonate, trifluoromethane sulfonate, pentafluoroethane sulfonate, nonafluorobutane sulfonate and the like. As the aryl group of the aryl sulfonate, there can be mentioned a benzene ring, a naphthalene ring or an anthracene ring. The benzene ring, naphthalene ring or anthracene ring may have a substituent. As preferred substituents, there can be mentioned a linear or branched alkyl group having 1 to 6 carbon atoms and a cycloalkyl group having 3 to 6 carbon atoms. As specific linear or branched alkyl groups and cycloalkyl groups, there can be mentioned methyl, ethyl, n-propyl, isopropyl, n-butyl, i-butyl, t-butyl, n-hexyl, cyclohexyl and the like. As other substituents, there can be mentioned an alkoxy group having 1 to 6 carbon atoms, a halogen atom, cyano, nitro, an acyl group, an acyloxy group and the like.

The amine compound having a phenoxy group or ammonium salt compound having a phenoxy group is one having a phenoxy group at the end of alkyl group of amine compound or ammonium salt compound opposed to the nitrogen atom. The phenoxy group may have a substituent. As the substituent of the phenoxy group, there can be mentioned, for example, an alkyl group, an alkoxy group, a halogen atom, a cyano group, a nitro group, a carboxyl group, a carboxylic ester group, a sulfonic ester group, an aryl group, an aralkyl group, an acyloxy group, an aryloxy group or the like. The substitution position of the substituent may be any of 2- to 6-positions. The number of substituents is optional within the range of 1 to 5.

It is preferred that at least one oxyalkylene group exist between the phenoxy group and the nitrogen atom. The number of oxyalkylene groups in each molecule is one or more, preferably 3 to 9 and further preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

The sulfonic ester group of the amine compound having a sulfonic ester group or ammonium salt compound having a sulfonic ester group may be any of an alkylsulfonic ester, cycloalkylsulfonic ester and arylsulfonic ester. In the alkylsulfonic ester, the alkyl group preferably has 1 to 20 carbon atoms. In the cycloalkylsulfonic ester, the cycloalkyl group preferably has 3 to 20 carbon atoms. In the arylsulfonic ester, the aryl group preferably has 6 to 12 carbon atoms. The alkylsulfonic ester, cycloalkylsulfonic ester and arylsulfonic ester may have substituents. As preferred substituents, there can be mentioned a halogen atom, a cyano group, a nitro group, a carboxyl group, a carboxylic ester group and a sulfonic ester group.

It is preferred that at least one oxyalkylene group exist between the sulfonic ester group and the nitrogen atom. The number of oxyalkylene groups in each molecule is one or more, preferably 3 to 9 and further preferably 4 to 6. The oxyalkylene group is preferably an oxyethylene group (—CH₂CH₂O—) or an oxypropylene group (—CH(CH₃)CH₂O— or —CH₂CH₂CH₂O—), more preferably an oxyethylene group.

These basic compounds are used individually or in combination.

The amount of basic compound used is generally in the range of 0.001 to 10 mass %, preferably 0.01 to 5 mass % based on the total solid of the positive photosensitive composition.

With respect to the ratio of acid generator (B) to basic compound (C) used in the composition, preferably, the acid generator/basic compound (molar ratio)=2.5 to 300. The reason for this is that the molar ratio is preferred to be 2.5 or higher from the viewpoint of sensitivity and resolving power. The molar ratio is preferred to be 300 or below from the viewpoint of inhibition of resolving power drop due to the thickening of the resist pattern over time up to heating treatment after exposure. The acid generator/basic compound (molar ratio) is more preferably in the range of 5.0 to 200, still more preferably 7.0 to 150.

[4] Surfactant (Component (D))

The positive photosensitive composition of the present invention preferably further contains a surfactant, and more preferably contains any one, or two or more members, of fluorinated and/or siliconized surfactants (fluorinated surfactant, siliconized surfactant and surfactant containing both fluorine and silicon atoms).

The positive photosensitive composition of the present invention when containing the above surfactant would, in the use of an exposure light source of 250 nm or below, especially 220 nm or below, realize a favorable sensitivity and resolving power and produce a resist pattern of less adhesion and development defects.

As the fluorinated and/or siliconized surfactants, there can be mentioned, for example, those described in JP-A's-62-36663, 61-226746, 61-226745, 62-170950, 63-34540, 7-230165, 8-62834, 9-54432, 9-5988 and 2002-277862 and U.S. Pat. Nos. 5,405,720, 5,360,692, 5,529,881, 5,296,330, 5,436,098, 5,576,143, 5,294,511 and 5,824,451. Any of the following commercially available surfactants can be used as is.

As useful commercially available surfactants, there can be mentioned, for example, fluorinated surfactants/siliconized surfactants, such as Eftop EF301 and EF303 (produced by Shin-Akita Kasei Co., Ltd.), Florad FC 430, 431 and 4430 (produced by Sumitomo 3M Ltd.), Megafac F171, F173, F176, F189, F113, F110, F177, F120 and R08 (produced by Dainippon Ink & Chemicals, Inc.), Surflon S-382, SC101, 102, 103, 104, 105 and 106 (produced by Asahi Glass Co., Ltd.), Troy Sol S-366 (produced by Troy Chemical Co., Ltd.), GF-300 and GF-150 (produced by TOAGOSEI CO., LTD.), Sarfron S-393 (produced by SEIMI CHEMICAL CO., LTD.), Eftop EF121, EF122A, EF122B, RF122C, EFl25M, EF135M, EF351, EF352, EF801, EF802 and EF601 (produced by JEMCO INC.), PF636, PF656, PF6320 and PF6520 (produced by OMNOVA), and FTX-204G, 208G, 218G, 230G, 204D, 208D, 212D, 218D and 222D (produced by NEOS). Further, polysiloxane polymer KP-341 (produced by Shin-Etsu Chemical Co., Ltd.) can be employed as the siliconized surfactant.

As the surfactant, besides the above publicly known surfactants, use can be made of a surfactant based on a polymer having a fluorinated aliphatic group derived from a fluorinated aliphatic compound produced by a telomerization technique (also called a telomer process) or an oligomerization technique (also called an oligomer process). The fluorinated aliphatic compound can be synthesized by the process described in JP-A-2002-90991.

The polymer having a fluorinated aliphatic group is preferably a copolymer from a monomer having a fluorinated aliphatic group and poly(oxyalkylene) acrylate and/or poly(oxyalkylene) methacrylate, which copolymer may have an irregular distribution or may result from block copolymerization. As the poly(oxyalkylene) group, there can be mentioned a poly(oxyethylene) group, a poly(oxypropylene) group, a poly(oxybutylene) group or the like. Further, use can be made of a unit having alkylene groups of different chain lengths in a single chain, such as poly(oxyethylene-oxypropylene-oxyethylene block concatenation) or poly(oxyethylene-oxypropylene block concatenation). Moreover, the copolymer from a monomer having a fluorinated aliphatic group and poly(oxyalkylene) acrylate (or methacrylate) is not limited to two-monomer copolymers and may be a three or more monomer copolymer obtained by simultaneous copolymerization of two or more different monomers having a fluorinated aliphatic group, two or more different poly(oxyalkylene) acrylates (or methacrylates), etc.

For example, as a commercially available surfactant, there can be mentioned Megafac F178, F-470, F-473, F-475, F-476 or F-472 (produced by Dainippon Ink & Chemicals, Inc.). Further, there can be mentioned a copolymer from an acrylate (or methacrylate) having a C₆F₁₃ group and poly(oxyalkylene) acrylate (or methacrylate), a copolymer from an acrylate (or methacrylate) having a C₃F₇ group, poly(oxyethylene) acrylate (or methacrylate) and poly(oxypropylene) acrylate (or methacrylate), or the like.

In the present invention, surfactants other than the fluorinated and/or siliconized surfactants can also be employed. In particular, there can be mentioned, for example, nonionic surfactants consisting of a polyoxyethylene alkyl ether such as polyoxyethylene lauryl ether, polyoxyethylene stearyl ether, polyoxyethylene cetyl ether or polyoxyethylene oleyl ether, a polyoxyethylene alkylaryl ether such as polyoxyethylene octylphenol ether or polyoxyethylene nonylphenol ether, a polyoxyethylene-polyoxypropylene block copolymer, a sorbitan fatty acid ester such as sorbitan monolaurate, sorbitan monopalmitate, sorbitan monostearate, sorbitan monooleate, sorbitan trioleate or sorbitan tristearate, a polyoxyethylene sorbitan fatty acid ester such as polyoxyethylene sorbitan monolaurate, polyoxyethylene sorbitan monopalmitate, polyoxyethylene sorbitan monostearate, polyoxyethylene sorbitan trioleate or polyoxyethylene sorbitan tristearate, or the like.

These surfactants may be used either individually or in combination.

The amount of surfactant used is preferably in the range of 0.0001 to 2 mass %, further preferably 0.001 to 1 mass %.

[5] Dissolution Inhibiting Compound (Component (E))

The positive photosensitive composition of the present invention may contain a dissolution inhibiting compound of 3000 or less molecular weight that is decomposed by the action of an acid to thereby realize an increased solubility in alkali developer (hereinafter also referred to as “dissolution inhibiting compound”). From the viewpoint of preventing any drop of 220 nm or less transmission, the dissolution inhibiting compound is preferably an alicyclic or aliphatic compound having an acid-decomposable group, such as any of cholic acid derivatives having an acid-decomposable group described in Proceeding of SPIE, 2724, 355 (1996). As the acid-decomposable group and alicyclic structure, there can be mentioned those as mentioned in the section on the resin (A).

When the positive photosensitive composition of the present invention is exposed to a KrF excimer laser or irradiated with electron beams, preferred use is made of one having a structure resulting from substitution of the phenolic hydroxyl group of a phenol compound with an acid-decomposable group. The phenol compound preferably contains 1 to 9 phenol skeletons, more preferably 2 to 6 phenol skeletons.

In the present invention, the molecular weight of the dissolution inhibiting compound is preferably 3000 or less, more preferably 300 to 3000 and still more preferably 500 to 2500.

The amount of dissolution inhibiting compound added is preferably in the range of 3 to 50 mass %, more preferably 5 to 40 mass % based on the total solid of the positive photosensitive composition.

Specific examples of dissolution inhibiting compounds will be shown below, which however in no way limit the scope of the present invention.

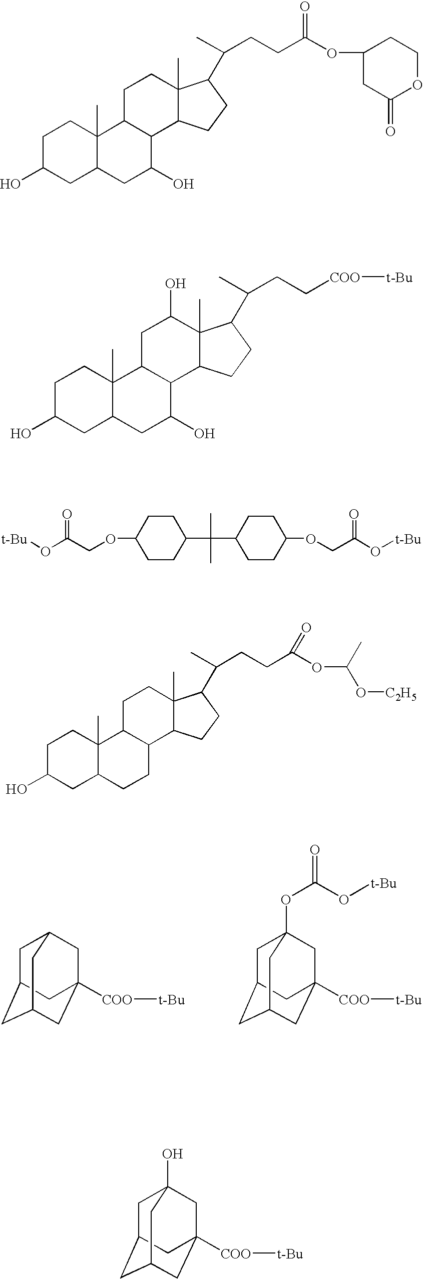

[6] Solvent (Component (F))

In the preparation of the photosensitive composition of the present invention, the above components are dissolved in given solvents before use. As solvents being useful in the preparation of the positive resist composition of the present invention, there can be mentioned, for example, organic solvents, such as an alkylene glycol monoalkyl ether carboxylate, an alkylene glycol monoalkyl ether, an alkyl lactate, an alkyl alkoxypropionate, a cyclolactone (preferably having 4 to 10 carbon atoms), an optionally cyclized monoketone compound (preferably having 4 to 10 carbon atoms), an alkylene carbonate, an alkyl alkoxyacetate and an alkyl pyruvate.

As preferred alkylene glycol monoalkyl ether carboxylates, there can be mentioned, for example, propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate and ethylene glycol monoethyl ether acetate.

As preferred alkylene glycol monoalkyl ethers, there can be mentioned, for example, propylene glycol monomethyl ether, propylene glycol monoethyl ether, propylene glycol monopropyl ether, propylene glycol monobutyl ether, ethylene glycol monomethyl ether and ethylene glycol monoethyl ether.

As preferred alkyl lactates, there can be mentioned, for example, methyl lactate, ethyl lactate, propyl lactate and butyl lactate.

As preferred alkyl alkoxypropionates, there can be mentioned, for example, ethyl 3-ethoxypropionate, methyl 3-methoxypropionate, methyl 3-ethoxypropionate and ethyl 3-methoxypropionate.

As preferred cyclolactones, there can be mentioned, for example, β-propiolactone, β-butyrolactone, γ-butyrolactone, α-methyl-γ-butyrolactone, β-methyl-γ-butyrolactone, γ-valerolactone, γ-caprolactone, γ-octanoic lactone and α-hydroxy-γ-butyrolactone.

As preferred optionally cyclized monoketone compounds, there can be mentioned, for example, 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone and 3-methylcycloheptanone.

As preferred alkylene carbonates, there can be mentioned, for example, propylene carbonate, vinylene carbonate, ethylene carbonate and butylene carbonate.

As preferred alkyl alkoxyacetates, there can be mentioned, for example, acetic acid 2-methoxyethyl ester, acetic acid 2-ethoxyethyl ester, acetic acid 2-(2-ethoxyethoxy)ethyl ester, acetic acid 3-methoxy-3-methylbutyl ester and acetic acid 1-methoxy-2-propyl ester.

As preferred alkyl pyruvates, there can be mentioned, for example, methyl pyruvate, ethyl pyruvate and propyl pyruvate.

As a preferably employable solvent, there can be mentioned a solvent having a boiling point of 130° C. or above measured at ordinary temperature under ordinary pressure. For example, there can be mentioned cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, acetic acid 2-ethoxyethyl ester, acetic acid 2-(2-ethoxyethoxy)ethyl ester or propylene carbonate.

In the present invention, the above solvents may be used either individually or in combination.

In the present invention, a mixed solvent consisting of a mixture of a solvent having a hydroxyl group in its structure and a solvent having no hydroxyl group may be used as an organic solvent.

As the solvent having a hydroxyl group, there can be mentioned, for example, ethylene glycol, ethylene glycol monomethyl ether, ethylene glycol monoethyl ether, propylene glycol, propylene glycol monomethyl ether, propylene glycol monoethyl ether, ethyl lactate or the like. Of these, propylene glycol monomethyl ether and ethyl lactate are especially preferred.

As the solvent having no hydroxyl group, there can be mentioned, for example, propylene glycol monomethyl ether acetate, ethyl ethoxypropionate, 2-heptanone, γ-butyrolactone, cyclohexanone, butyl acetate, N-methylpyrrolidone, N,N-dimethylacetamide, dimethyl sulfoxide or the like. Of these, propylene glycol monomethyl ether acetate, ethyl ethoxypropionate, 2-heptanone, γ-butyrolactone, cyclohexanone and butyl acetate are especially preferred. Propylene glycol monomethyl ether acetate, ethyl ethoxypropionate and 2-heptanone are most preferred.

The mixing ratio (mass) of a solvent having a hydroxyl group and solvent having no hydroxyl group is in the range of 1/99 to 99/1, preferably 10/90 to 90/10 and still preferably 20/80 to 60/40. The mixed solvent containing 50 mass % or more of a solvent having no hydroxyl group is especially preferred from the viewpoint of uniform applicability.

It is preferred that the solvent be a mixed solvent of two or more types of solvents containing propylene glycol monomethyl ether acetate.

[7] Other Additives

The positive photosensitive composition of the present invention may further according to necessity contain a dye, a plasticizer, a photosensitizer, a light absorber, a compound capable of promoting the solubility in developer (for example, phenolic compound of 1000 or less molecular weight, or carboxylated alicyclic or aliphatic compound), etc.

The above phenolic compound of 1000 or less molecular weight can be easily synthesized by persons of ordinary skill in the art to which the present invention pertains while consulting the processes described in, for example, JP-As 4-122938 and 2-28531, U.S. Pat. No. 4,916,210 and EP 219294.

As the carboxylated alicyclic or aliphatic compound, there can be mentioned, for example, a carboxylic acid derivative with steroid structure such as cholic acid, deoxycholic acid or lithocholic acid, an adamantanecarboxylic acid derivative, adamantanedicarboxylic acid, cyclohexanecarboxylic acid, cyclohexanedicarboxylic acid or the like. These are however nonlimiting.

[Method of Forming Pattern]

From the viewpoint of enhancement of resolving power, it is preferred that the positive photosensitive composition of the present invention be used with a coating thickness of 30 to 250 nm. More preferably, it is used with a coating thickness of 30 to 200 nm. This coating thickness can be attained by setting the solid content of the positive photosensitive composition within an appropriate range so as to cause the composition to have an appropriate viscosity, thereby improving the applicability and film forming property.

The total solid content of the positive photosensitive composition is generally in the range of 1 to 10 mass %, preferably 1 to 8.0 mass % and still preferably 1.0 to 6.0 mass %.

The positive photosensitive composition of the present invention is used in such a manner that the above components are dissolved in a given organic solvent, preferably the above mixed solvent, and filtered and applied onto a given support in the following manner. The filter medium for the filtration preferably consists of a polytetrafluoroethylene, polyethylene or nylon having a pore size of 0.1 μm or less, especially 0.05 μm or less and still more preferably 0.03 μm or less.

For example, the positive photosensitive composition is applied onto a substrate, such as one for use in the production of precision integrated circuit elements (e.g., silicon/silicon dioxide coating), by appropriate application means, such as a spinner or coater, and dried to thereby form a resist film.

The resist film is exposed through a given mask to actinic rays or radiation, preferably baked (heated), and developed and rinsed. Accordingly, a desirable pattern can be obtained.

As the actinic rays or radiation, there can be mentioned infrared rays, visible light, ultraviolet rays, far ultraviolet rays, X-rays, electron beams or the like. Among them, preferred use is made of far ultraviolet rays of especially 250 nm or less, more especially 220 nm or less and still more especially 1 to 200 nm wavelength, such as KrF excimer laser (248 nm), ArF excimer laser (193 nm) and F₂ excimer laser (157 nm), as well as X-rays, electron beams or the like. More preferred use is made of ArF excimer laser, F₂ excimer laser, EUV (13 nm) and electron beams.

Prior to the formation of a resist film, the substrate may be coated with an antireflection film.

As the antireflection film, use can be made of not only an inorganic film of titanium, titanium oxide, titanium nitride, chromium oxide, carbon, amorphous silicon or the like but also an organic film composed of a light absorber and a polymer material. Also, as the organic antireflection film, use can be made of commercially available organic antireflection films, such as the DUV30 Series and DUV40 Series produced by Brewer Science Inc. and AR-2, AR-3 and AR-5 produced by Shipley Co., Ltd.

In the development step, an alkali developer is used as follows. As the alkali developer for the positive photosensitive composition, use can be made of any of alkaline aqueous solutions of an inorganic alkali such as sodium hydroxide, potassium hydroxide, sodium carbonate, sodium silicate, sodium metasilicate or aqueous ammonia, a primary amine such as ethylamine or n-propylamine, a secondary amine such as diethylamine or di-n-butylamine, a tertiary amine such as triethylamine or methyldiethylamine, an alcoholamine such as dimethylethanolamine or triethanolamine, a quaternary ammonium salt such as tetramethylammonium hydroxide or tetraethylammonium hydroxide, a cycloamine such as pyrrole or piperidine, or the like.

Before the use of the above alkali developer, appropriate amounts of an alcohol and a surfactant may be added thereto.

The alkali concentration of the alkali developer is generally in the range of 0.1 to 20 mass %.

The pH value of the alkali developer is generally in the range of 10.0 to 15.0.

Before the use of the above alkaline aqueous solution, appropriate amounts of an alcohol and a surfactant may be added thereto.

Pure water can be used as the rinse liquid. Before the use, an appropriate amount of surfactant may be added thereto.

The development operation or rinse operation may be followed by the operation for removing any developer or rinse liquid adhering onto the pattern by the use of a supercritical fluid.

Exposure (liquid immersion exposure) may be carried out after filling the interstice between resist film and lens with a liquid (liquid immersion medium, liquid for liquid immersion) of refractive index higher than that of air at the time of irradiation with actinic rays or radiation. This would bring about an enhancement of resolving power. Any liquid with a refractive index higher than that of air can be employed as the liquid immersion medium. Preferably, pure water is employed.

The liquid for liquid immersion for use in the liquid immersion exposure will now be described.

The liquid for liquid immersion preferably consists of a liquid being transparent in exposure wavelength whose temperature coefficient of refractive index is as low as possible so as to ensure minimization of any strain of optical image projected on the resist film. Especially in the use of an ArF excimer laser (wavelength: 193 nm) as an exposure light source, however, it is more preferred to use water from not only the above viewpoints but also the viewpoints of easy procurement and easy handling.

Further, from the viewpoint of refractive index increase, use can be made of a medium of 1.5 or higher refractive index. Such a medium may be an aqueous solution or an organic solvent.

In the use of water as a liquid for liquid immersion, a slight proportion of additive (liquid) that would not dissolve the resist film on a wafer and would be negligible with respect to its influence on an optical coat for an under surface of lens element may be added in order to not only decrease the surface tension of water but also increase a surface activating power. The additive is preferably an aliphatic alcohol with a refractive index approximately equal to that of water, for example, methyl alcohol, ethyl alcohol, isopropyl alcohol or the like. The addition of an alcohol with a refractive index approximately equal to that of water is advantageous in that even when the alcohol component is evaporated from water to thereby cause a change of content concentration, the change of refractive index of the whole liquid can be minimized. On the other hand, when a substance being opaque in 193 nm rays or an impurity whose refractive index is greatly different from that of water is mixed in, the mixing would invite a strain of optical image projected on the resist film. Accordingly, it is preferred to use distilled water as the liquid immersion water. Furthermore, use may be made of pure water having been filtered through an ion exchange filter or the like.

Desirably, the electrical resistance of the water is 18.3 MQcm or higher, and the TOC (organic matter concentration) thereof is 20 ppb or below. Prior deaeration of the water is desired.

Raising the refractive index of the liquid for liquid immersion would enable an enhancement of lithography performance. From this viewpoint, an additive suitable for refractive index increase may be added to the water, or heavy water (D₂O) may be used in place of water.

In the exposure of the resist film of the positive photosensitive composition of the present invention via the liquid for liquid immersion, a hydrophobic resin (HR) may be further added according to necessity. This would bring about uneven localization of the hydrophobic resin (HR) on the surface layer of the resist film. When the liquid immersion medium is water, there would be attained an improvement of receding contact angle on the surface of the resist film with reference to water upon formation of the resist film, and accordingly an enhancement of Following Ability if Liquid Immersion Water. Although the hydrophobic resin (HR) is not particularly limited as long as an improvement of receding contact angle on the surface is realized by the addition thereof, it is preferred to employ a resin having at least either a fluorine atom or a silicon atom. The receding contact angle of the resist film is preferably in the range of 60° to 90°, more preferably 70° or higher. The amount of resin added can be appropriately regulated so that the receding contact angle of the resist film falls within the above range. However, the addition amount is preferably in the range of 0.1 to 10 mass %, more preferably 0.1 to 5 mass % based on the total solid of the positive photosensitive composition. Although the hydrophobic resin (HR) is unevenly localized on the interface as aforementioned, as different from the surfactant, the hydrophobic resin does not necessarily have to have a hydrophilic group in its molecule and does not need to contribute toward uniform mixing of polar/nonpolar substances.

The fluorine atom or silicon atom of the hydrophobic resin (HR) may be present in the principal chain of the resin or may be a substituent on the side chain thereof.

The hydrophobic resin (HR) is preferably a resin having a fluorine-atom-having alkyl group, a fluorine-atom-included cycloalkyl group or a fluorine-atom-included aryl group as a fluorine-atom partial structure.

The fluorine-atom-included alkyl group (preferably having 1 to 10 carbon atoms, more preferably 1 to 4 carbon atoms) is a linear or branched alkyl group having at least one hydrogen atom thereof substituted with a fluorine atom. Further, other substituents may be included.

The fluorine-atom-included cycloalkyl group is a cycloalkyl group of single ring or multiple rings having at least one hydrogen atom thereof substituted with a fluorine atom. Further other substituents may be had.

As the fluorine-atom-included aryl group, there can be mentioned one having at least one hydrogen atom of an aryl group, such as a phenyl or naphthyl group, substituted with a fluorine atom. Further, other substituents may be included.

As preferred fluorine-atom-included alkyl groups, fluorine-atom-included cycloalkyl groups and fluorine-atom-included aryl groups, there can be mentioned groups of the following general formulae (F2) to (F4), which however in no way limit the scope of the present invention.

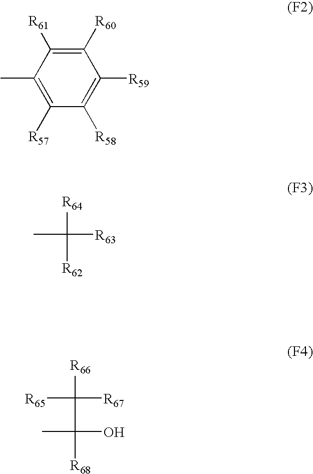

In the general formulae (F2) to (F4),

each of R₅₇ to R₆₈ independently represents a hydrogen atom, a fluorine atom or an alkyl group. At least one of each of R₅₇-R₆₁, R₆₂-R₆₄ and R₆₅-R₆₈ represents a fluorine atom or an alkyl group (preferably having 1 to 4 carbon atoms) having at least one hydrogen atom thereof substituted with a fluorine atom. It is preferred that all of R₅₇-R₆₁ and R₆₅-R₆₇ represent fluorine atoms. Each of R₆₂, R₆₃ and R₆₈ preferably represents an alkyl group (especially having 1 to 4 carbon atoms) having at least one hydrogen atom thereof substituted with a fluorine atom, more preferably a perfluoroalkyl group having 1 to 4 carbon atoms. R₆₂ and R₆₃ may be bonded with each other to thereby form a ring.

Specific examples of the groups of the general formula (F2) include a p-fluorophenyl group, a pentafluorophenyl group, a 3,5-di(trifluoromethyl)phenyl group and the like.

Specific examples of the groups of the general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. Of these, a hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred. A hexafluoroisopropyl group and a heptafluoroisopropyl group are more preferred.

Specific examples of the groups of the general formula (F4) include —C(CF₃)₂OH, —C(C₂F₅)₂OH, —C(CF₃)(CF₃)OH, —CH(CF₃)OH and the like. —C(CF₃)₂OH is preferred.

Specific examples of the repeating units having a fluorine atom will be shown below, which however in no way limit the scope of the present invention.

In the specific examples, X₁ represents a hydrogen atom, —CH₃, —F or —CF₃.

X₂ represents —F or —CF₃.

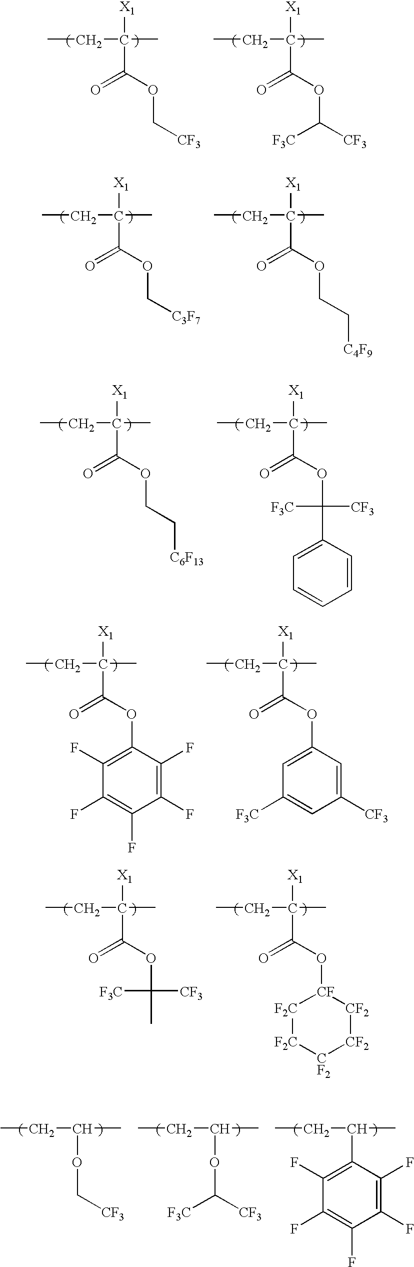

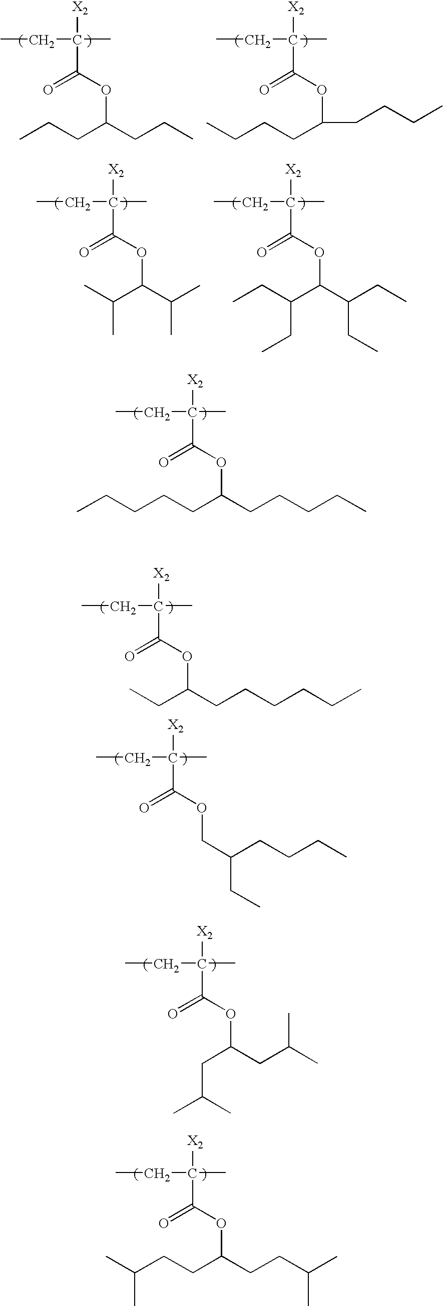

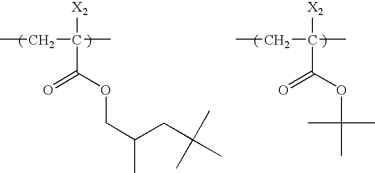

The hydrophobic resin (HR) is preferably a resin having an alkylsilyl structure (preferably a trialkylsilyl group) or a cyclosiloxane structure as a partial structure having a silicon atom.

As the alkylsilyl structure or cyclosiloxane structure, there can be mentioned, for example, any of the groups of the following general formulae (CS-1) to (CS-3) or the like.

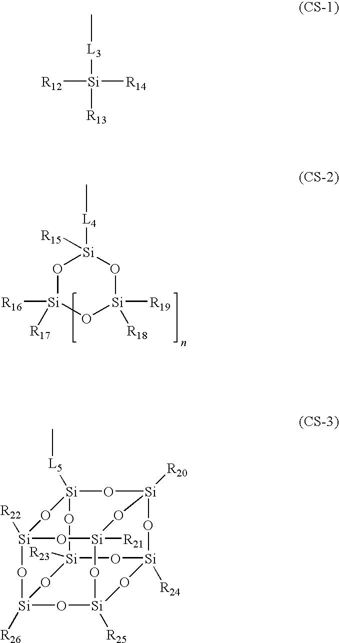

In the general formulae (CS-1) to (CS-3),

each of R₁₂ to R₂₆ independently represents a linear or branched alkyl group (preferably having 1 to 20 carbon atoms) or a cycloalkyl group (preferably having 3 to 20 carbon atoms).

Each of L₃ to L₅ represents a single bond or a bivalent linkage group. As the bivalent linkage group, there can be mentioned any one or a combination of two or more groups selected from the group consisting of an alkylene group, a phenyl group, an ether group, a thioether group, a carbonyl group, an ester group, an amido group, a urethane group and a urea group.

In the formulae, n is an integer of 1 to 5.

Specific examples of the repeating units having a silicon atom will be shown below, which however in no way limit the scope of the present invention.

In the specific examples, X₁ represents a hydrogen atom, —CH₃, —F or —CF₃.

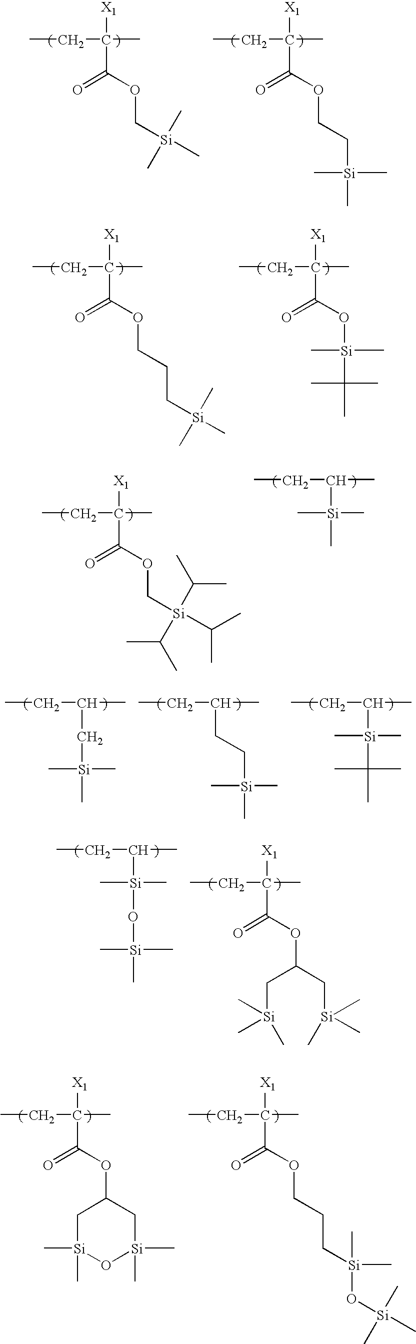

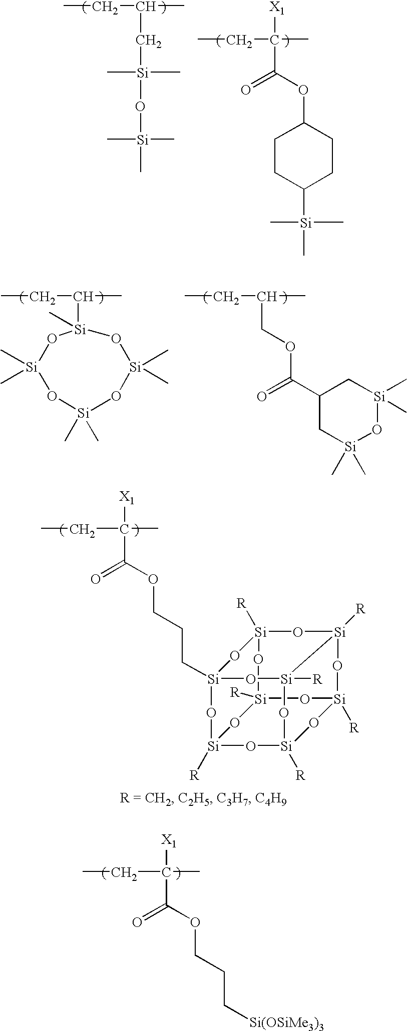

Moreover, the hydrophobic resin (HR) may have at least one group selected from among the following groups (x) to (z).

The groups are:

(x) an alkali soluble group,

(y) a group that is decomposed by the action of an alkali developer, resulting in an increase of solubility in the alkali developer, and

(z) a group that is decomposed by the action of an acid.

As the alkali soluble group (x), there can be mentioned, for example, any of groups having a phenolic hydroxyl group, a carboxylate group, a fluoroalcohol group, a sulfonate group, a sulfonamide group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group and a tris(alkylsulfonyl)methylene group.

As preferred alkali soluble groups, there can be mentioned a fluoroalcohol group (preferably hexafluoroisopropanol), a sulfonimido group and a bis(carbonyl)methylene group.

As the repeating unit having an alkali soluble group (x), preferred use is made of any of a repeating unit resulting from direct bonding of an alkali soluble group to a principal chain of resin like a repeating unit of acrylic acid or methacrylic acid, a repeating unit resulting from bonding, via a linkage group, of an alkali soluble group to a principal chain of resin and a repeating unit resulting from polymerization with the use of a chain transfer agent or polymerization initiator having an alkali soluble group to thereby attain introduction in a polymer chain terminal.

The content of repeating units having an alkali soluble group (x) is preferably in the range of 1 to 50 mol %, more preferably 3 to 35 mol % and still more preferably 5 to 20 mol % based on all the repeating units of the hydrophobic resin (HR).

Specific examples of the repeating units having an alkali soluble group (x) will be shown below, which however in no way limit the scope of the present invention.

In the formulae, Rₓ represents H, CH₃, CF₃ or CH₂OH.

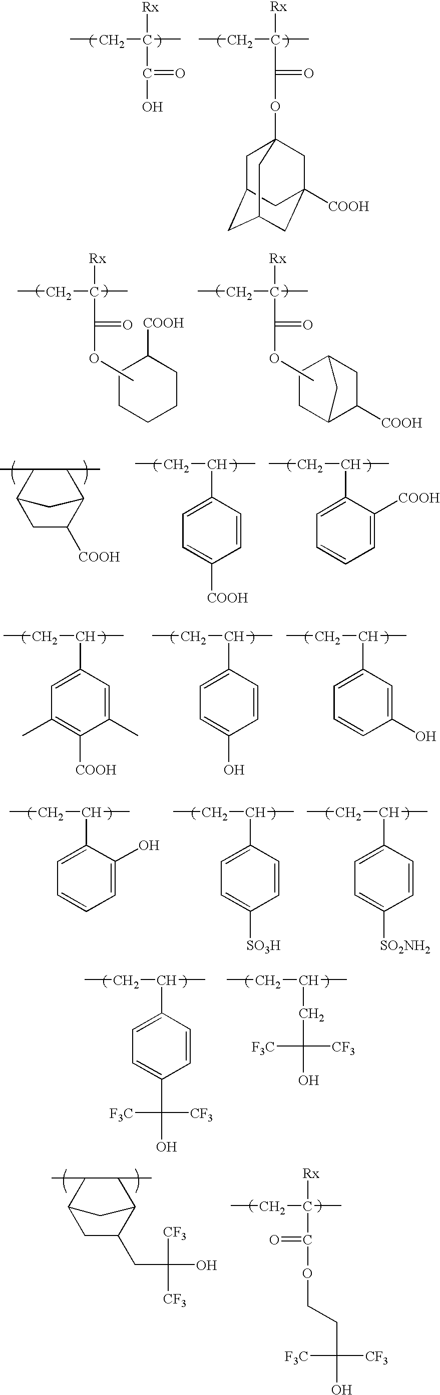

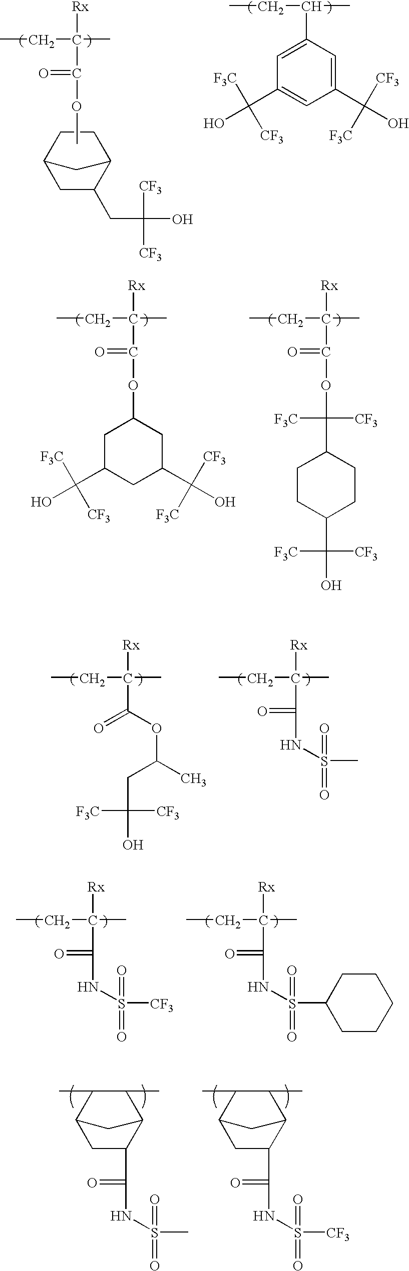

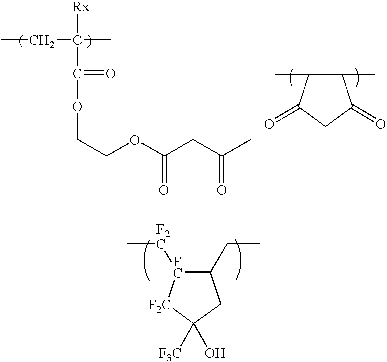

As the group (y) that is decomposed by the action of an alkali developer, resulting in an increase of solubility in the alkali developer, there can be mentioned, for example, a group having a lactone structure, an acid anhydride, an acid imide or the like. A lactone group is preferred.

As the repeating unit having a group (y) that is decomposed by the action of an alkali developer, resulting in an increase of solubility in the alkali developer, preferred use is made of both of a repeating unit resulting from bonding of a group (y) that is decomposed by the action of an alkali developer, resulting in an increase of solubility in the alkali developer, to a principal chain of resin like a repeating unit of acrylic acid or methacrylic acid and a repeating unit resulting from polymerization with the use of a chain transfer agent or polymerization initiator having a group (y) resulting in an increase of solubility in an alkali developer to thereby attain introduction in a polymer chain terminal.

The content of repeating units having a group (y) resulting in an increase of solubility in an alkali developer is preferably in the range of 1 to 40 mol %, more preferably 3 to 30 mol % and still more preferably 5 to 15 mol % based on all the repeating units of the hydrophobic resin (HR).

As specific examples of the repeating units having a group (y) resulting in an increase of solubility in an alkali developer, there can be mentioned those similar to the repeating units having a lactone structure set forth with respect to the resins as the component (B).

As the repeating unit having a group (z) that is decomposed by the action of an acid in the hydrophobic resin (HR), there can be mentioned those similar to the repeating units having an acid decomposable group set forth with respect to the resin (A). The content of repeating units having a group (z) that is decomposed by the action of an acid in the hydrophobic resin (HR) is preferably in the range of 1 to 80 mol %, more preferably 10 to 80 mol % and still more preferably 20 to 60 mol % based on all the repeating units of the hydrophobic resin (HR).

The hydrophobic resin (HR) may further have any of the repeating units of the following general formula (IV).

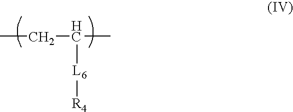

In the general formula (IV),

R₄ represents a group having any of an alkyl group, a cycloalkyl group, an alkenyl group and a cycloalkenyl group.

L₆ represents a single bond or a bivalent linkage group.

In the general formula (IV), the alkyl group represented by R₄ is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The bivalent linkage group represented by L₆ is preferably an alkenyl group (preferably having 1 to 5 carbon atoms) or an oxy group.

When the hydrophobic resin (HR) has a fluorine atom, the content of fluorine atom is preferably in the range of 5 to 80 mass %, more preferably 10 to 80 mass %, based on the molecular weight of the hydrophobic resin (HR). The repeating unit containing a fluorine atom is preferably present in the hydrophobic resin (HR) in an amount of 10 to 100 mass %, more preferably 30 to 100 mass %.

When the hydrophobic resin (HR) has a silicon atom, the content of silicon atom is preferably in the range of 2 to 50 mass %, more preferably 2 to 30 mass %, based on the molecular weight of the hydrophobic resin (HR). The repeating unit containing a silicon atom is preferably present in the hydrophobic resin (HR) in an amount of 10 to 100 mass %, more preferably 20 to 100 mass %.

The weight average molecular weight of the hydrophobic resin (HR) in terms of standard polystyrene molecular weight is preferably in the range of 1000 to 100,000, more preferably 1000 to 50,000 and still more preferably 2000 to 15,000.

Impurities, such as metals, should naturally be little in the hydrophobic resin (HR) like the resin (A). The content of residual monomers and oligomer components is preferably 0 to 10 mass %, more preferably 0 to 5 mass % and still more preferably 0 to 1 mass %. Accordingly, there can be obtained a resist being free from a change of in-liquid foreign matter, sensitivity, etc. over time. From the viewpoint of resolving power, resist profile, side wall of resist pattern, roughness, etc., the molecular weight distribution (Mw/Mn, also referred to as the degree of dispersal) thereof is preferably in the range of 1 to 5, more preferably 1 to 3 and still more preferably 1 to 2.

A variety of commercially available products can be used as the hydrophobic resin (HR), and also the resin can be synthesized in accordance with customary methods (for example, radical polymerization). As general synthetic methods, there can be mentioned, for example, a batch polymerization method in which monomer species and an initiator are dissolved in a solvent and heated to thereby carry out polymerization, a dropping polymerization method in which a solution of monomer species and initiator is dropped into a hot solvent over a period of 1 to 10 hours, and the like. The dropping polymerization method is preferred. As a reaction solvent, there can be mentioned, for example, an ether such as tetrahydrofuran, 1,4-dioxane or diisopropyl ether, a ketone such as methyl ethyl ketone or methyl isobutyl ketone, an ester solvent such as ethyl acetate, an amide solvent such as dimethylformamide or dimethylacetamide, or the aforementioned solvent capable of dissolving the composition of the present invention such as propylene glycol monomethyl ether acetate, propylene glycol monomethyl ether or cyclohexanone. It is preferred that the polymerization be carried out with the use of the same solvent as that used in the positive photosensitive composition of the present invention. This would inhibit any particle generation during storage.

The polymerization reaction is preferably carried out in an atmosphere of inert gas, such as nitrogen or argon. In the initiation of polymerization, a commercially available radical initiator (azo initiator, peroxide, etc.) is used as the polymerization initiator. An azo initiator is preferred, and an azo initiator having an ester group, a cyano group and a carboxyl group is more preferred as the radical initiator. As specific preferred initiators, there can be mentioned azobisisobutyronitrile, azobisdimethylvaleronitrile, dimethyl 2,2′-azobis(2-methylpropionate) and the like. The reaction concentration is in the range of 5 to 50 mass %, preferably 30 to 50 mass %. The reaction temperature is generally in the range of 10° to 150° C., preferably 30° to 120° C. and more preferably 60° to 100° C.

After the completion of the reaction, the mixture is allowed to stand still to cool to room temperature and purified. In the purification, use is made of customary methods, such as a liquid-liquid extraction method in which residual monomers and oligomer components are removed by water washing or by the use of a combination of appropriate solvents, a method of purification in solution form such as ultrafiltration capable of extraction removal of only components of a given molecular weight or below, a re-precipitation method in which a resin solution is dropped into a poor solvent to thereby coagulate the resin in the poor solvent and thus remove residual monomers, etc. and a method of purification in solid form such as washing of a resin slurry obtained by filtration with the use of a poor solvent. For example, the reaction solution is brought into contact with a solvent wherein the resin is poorly soluble or insoluble (poor solvent) amounting to 10 or less, preferably 10 to 5 times the volume of the reaction solution to thereby precipitate the resin as a solid.

The solvent for use in the operation of precipitation or re-precipitation from a polymer solution (precipitation or re-precipitation solvent) is not limited as long as the solvent is a poor solvent for the polymer. According to the type of polymer, use can be made of any one appropriately selected from among a hydrocarbon, a halogenated hydrocarbon, a nitro compound, an ether, a ketone, an ester, a carbonate, an alcohol, a carboxylic acid, water, a mixed solvent containing these solvents and the like. Of these, it is preferred to employ a solvent containing at least an alcohol (especially methanol or the like) or water as the precipitation or re-precipitation solvent.

The amount of precipitation or re-precipitation solvent used although can be appropriately selected taking efficiency, yield, etc. into account is generally in the range of 100 to 10,000 parts by mass, preferably 200 to 2000 parts by mass and more preferably 300 to 1000 parts by mass per 100 parts by mass of the polymer solution.

The temperature at which the precipitation or re-precipitation is carried out, which can be appropriately selected taking efficiency and operation easiness into account, is generally in the range of about 0° to 50° C., preferably about room temperature (for example, about 20° to 35° C.). The operation of precipitation or re-precipitation can be carried out by a publicly known method, such as a batch or continuous method, with the use of a customary mixing vessel, such as an agitation vessel.

The polymer obtained by precipitation or re-precipitation is generally subjected to customary solid/liquid separation, such as filtration or centrifugal separation, and dried before use. The filtration is carried out with the use of a filter medium ensuring solvent resistance, preferably under pressure. The drying is performed at about 30° to 100° C., preferably about 30° to 50° C. at ordinary pressure or reduced pressure (preferably reduced pressure).

Optionally, after the resin precipitation and separation, the resin may be once more dissolved in a solvent and brought into contact with a solvent wherein the resin is poorly soluble or insoluble. Specifically, the method may include the steps of, after the completion of the radical polymerization reaction, bringing the polymer into contact with a solvent wherein the polymer is poorly soluble or insoluble to thereby attain resin precipitation (step a), separating the resin from the solution (step b), re-dissolving the resin in a solvent to thereby obtain a resin solution (A) (step c), thereafter bringing the resin solution (A) into contact with a solvent wherein the resin is poorly soluble or insoluble amounting to less than 10 times (preferably 5 times or less) the volume of the resin solution (A) to thereby attain resin solid precipitation (step d) and separating the precipitated resin (step e).

Specific examples of the hydrophobic resins (HR) will be shown below. The following Table 3 shows the molar ratio of individual repeating units (corresponding to individual repeating units in the order from the left), weight average molecular weight and degree of dispersal with respect to each of the resins.

TABLE 3

| | |
|---|---|
| | (HR-1) |
| 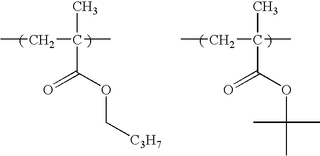 | |
| | (HR-2) |
| 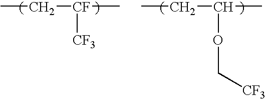 | |
| | (HR-3) |
| 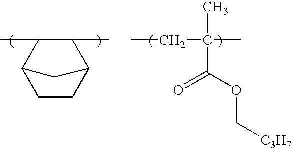 | |
| | (HR-4) |
| 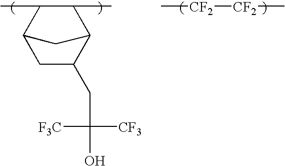 | |
| | (HR-5) |
| 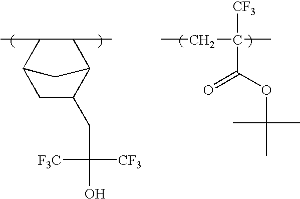 | |
| | (HR-6) |
| 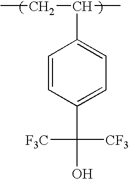 | |
| | (HR-7) |
| 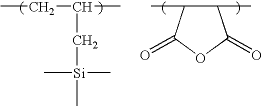 | |
| | (HR-8) |
| 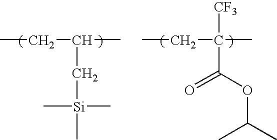 | |
| | (HR-9) |
| 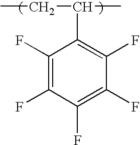 | |
| | (HR-10) |
| 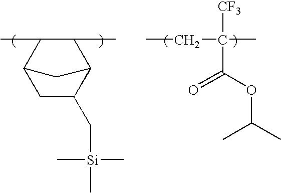 | |
| | (HR-11) |
| 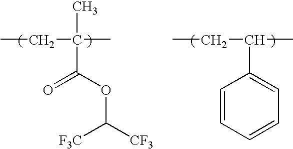 | |
| | (HR-12) |
| 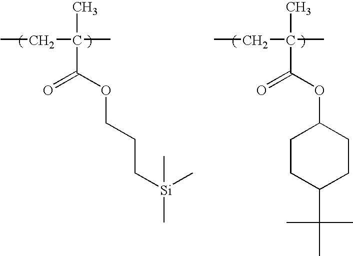 | |
| | (HR-13) |
| 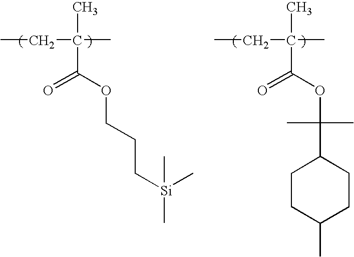 | |
| | (HR-14) |
| 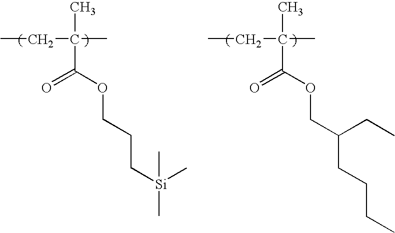 | |
| | (HR-15) |
| 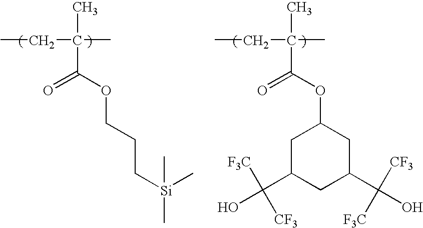 | |
| | (HR-16) |
| 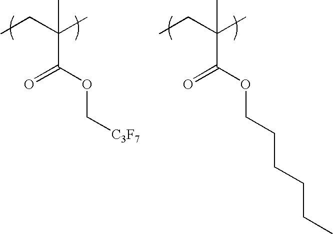 | |
| | (HR-17) |
| 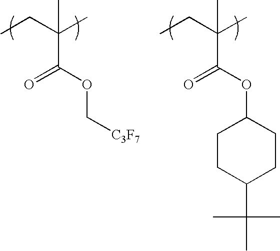 | |
| | (HR-18) |
| 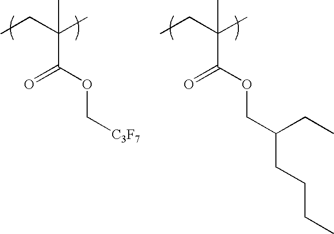 | |
| | (HR-19) |
| 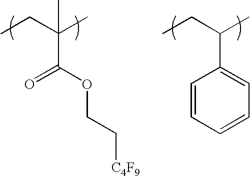 | |
| | (HR-20) |
| 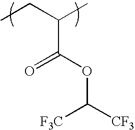 | |
| | (HR-21) |
| 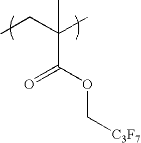 | |
| | (HR-22) |
| 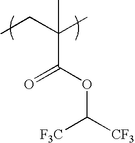 | |
| | (HR-23) |
| 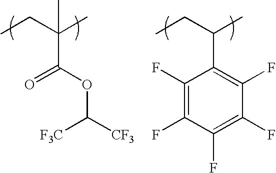 | |
| | (HR-24) |
| 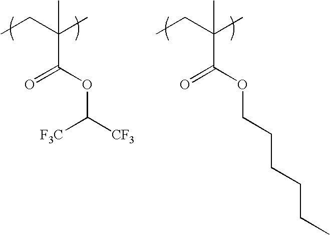 | |
| | (HR-25) |
| 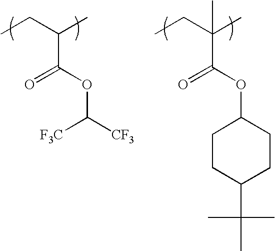 | |
| | (HR-26) |
| 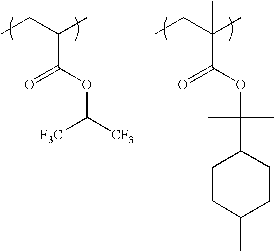 | |
| | (HR-27) |
| 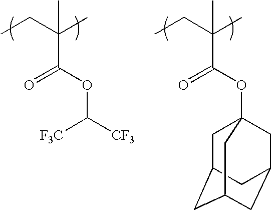 | |
| | (HR-28) |
| 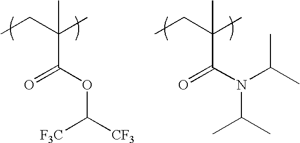 | |
| | (HR-29) |
| 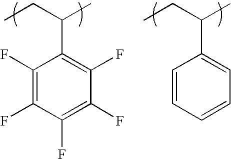 | |
| | (HR-30) |
| 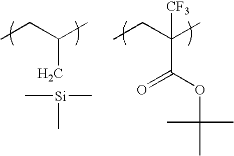 | |
| | (HR-31) |
| 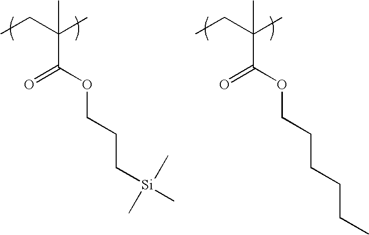 | |
| | (HR-32) |
| 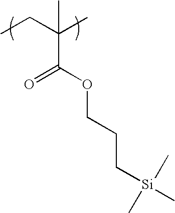 | |
| | (HR-33) |
| 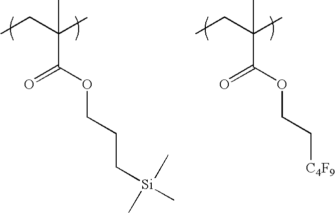 | |
| | (HR-34) |
| 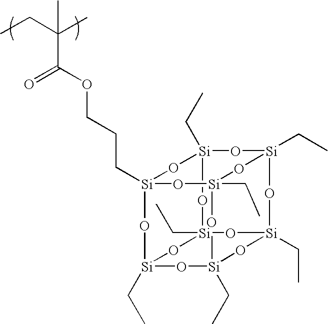 | |
| 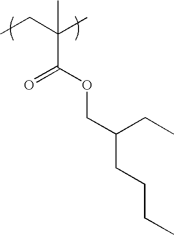 | |
| | (HR-35) |
| 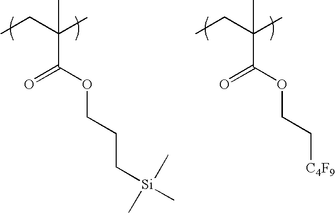 | |
| 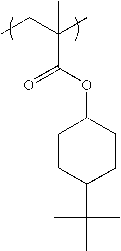 | |
| | (HR-36) |
| 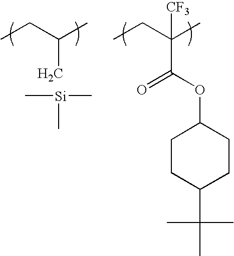 | |
| | (HR-37) |
| 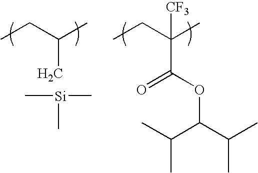 | |
| | (HR-38) |
| 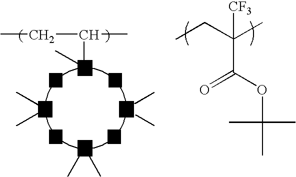 | |
| | (HR-39) |
| 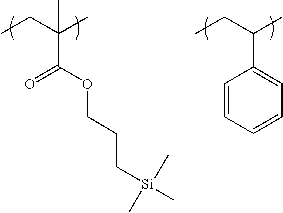 | |
| | (HR-40) |
| 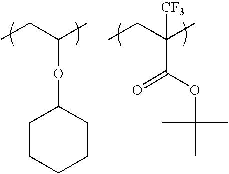 | |
| | (HR-41) |
| 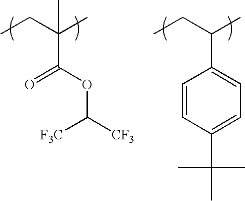 | |
| | (HR-42) |
| 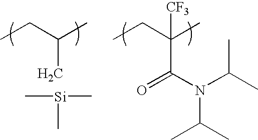 | |
| | (HR-43) |
| 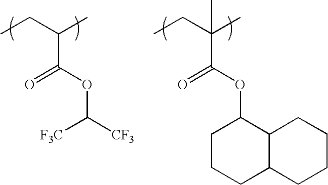 | |
| | (HR-44) |
| 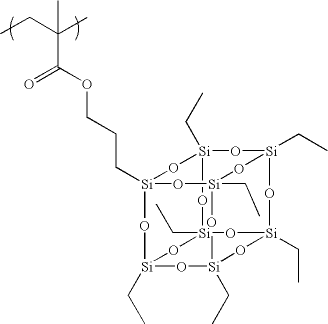 | |
| 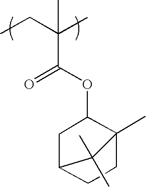 | |
| | (HR-45) |
| 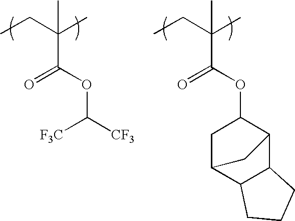 | |
| | (HR-46) |
| 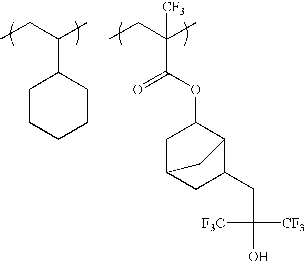 | |
| | (HR-47) |
| 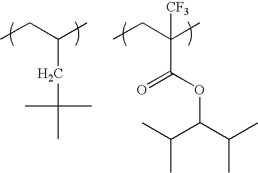 | |
| | (HR-48) |
| 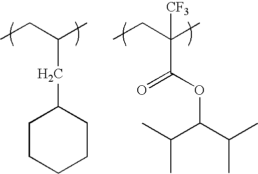 | |
| | (HR-49) |
| 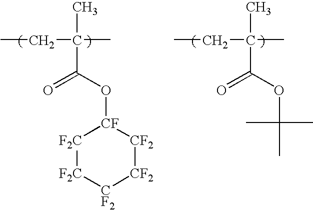 | |
| | (HR-50) |
| 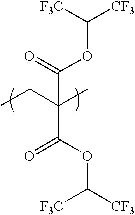 | |
| | (HR-51) |
| 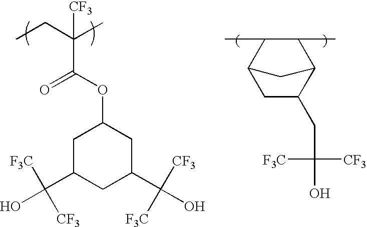 | |
| | (HR-52) |
| 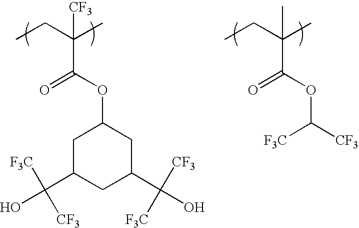 | |
| | (HR-53) |
| 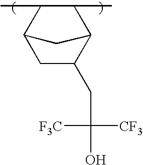 | |
| | (HR-54) |
| 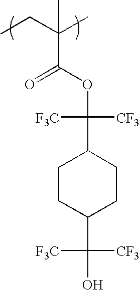 | |
| | (HR-55) |
| 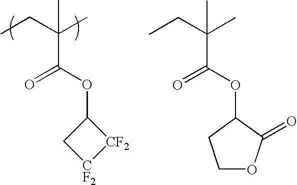 | |
| | (HR-56) |
| 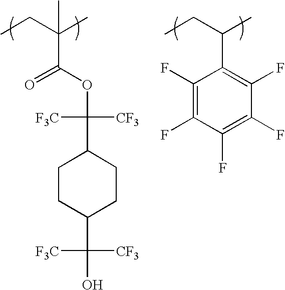 | |
| | (HR-57) |
| 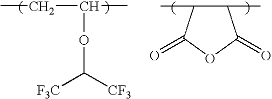 | |
| | (HR-58) |
| 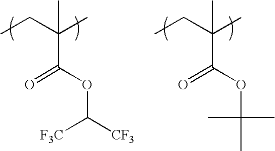 | |
| | (HR-59) |
| 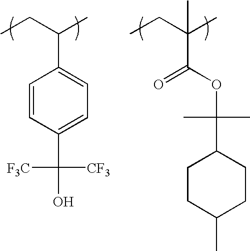 | |
| | (CP-60) |
| 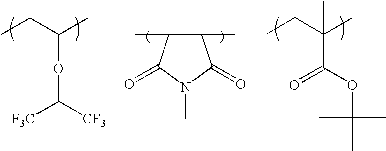 | |
| | (HR-61) |
| 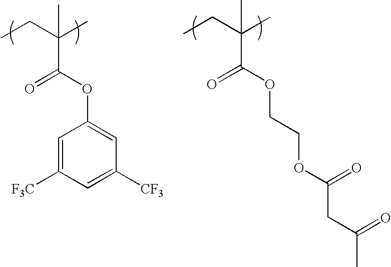 | |
| 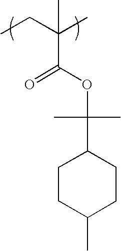 | |
| | (HR-62) |
| 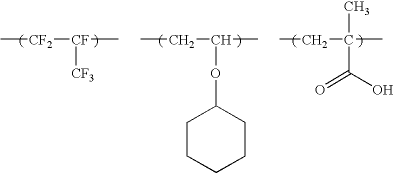 | |
| | (HR-63) |
| 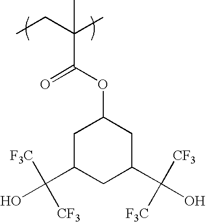 | |
| | (HR-64) |
| 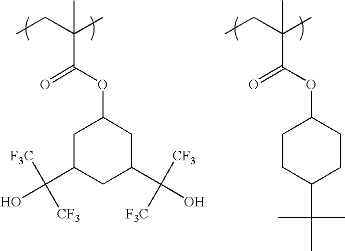 | |
| | (HR-65) |
| 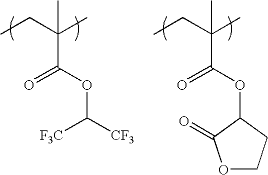 | |
| 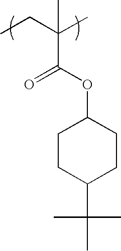 | |
| | (HR-66) |
| 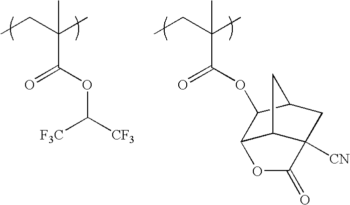 | |
| | (HR-67) |
| 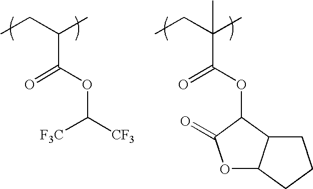 | |
| | (HR-68) |
| 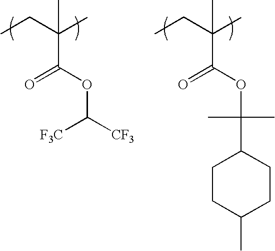 | |
| | (HR-69) |
| 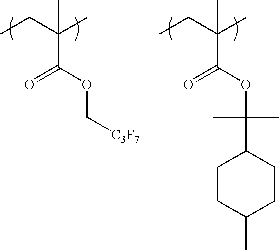 | |
| | (HR-70) |
| 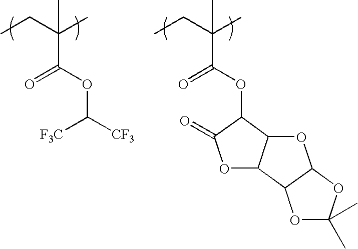 | |
| 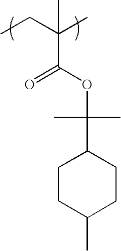 | |
| | (HR-71) |
| 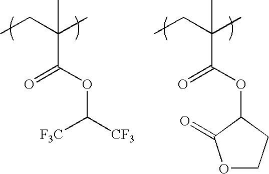 | |
| 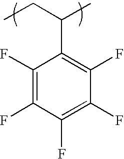 | |
| | (HR-72) |
| 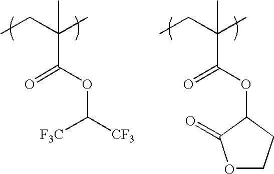 | |
| 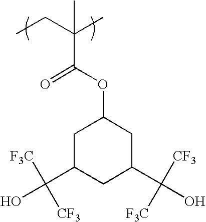 | |
| | (HR-73) |
| 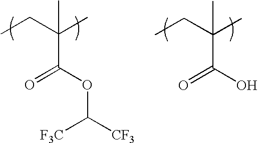 | |
| | (HR-74) |
| 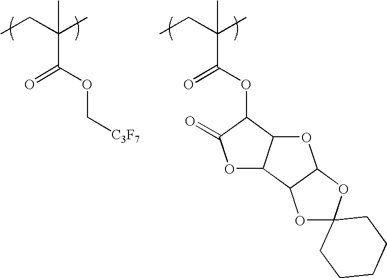 | |
| | (HR-75) |
| 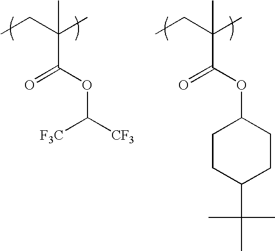 | |
| 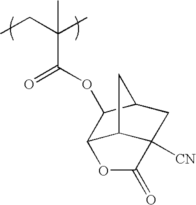 | |
| | (HR-76) |
| 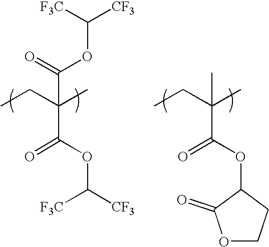 | |
| | (HR-77) |
| 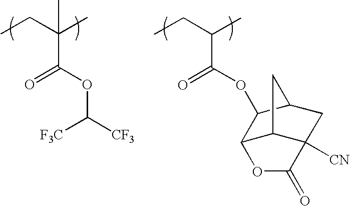 | |
| | (HR-78) |
| 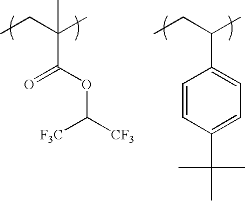 | |
| 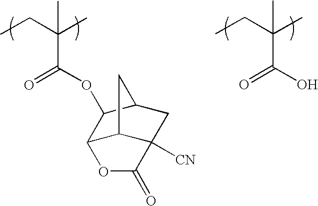 | |
| | (HR-79) |
| 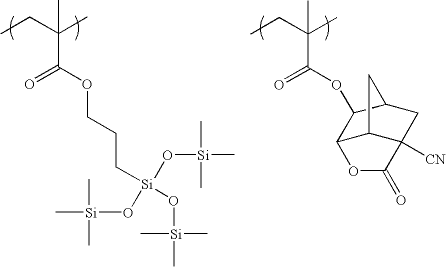 | |
| | (HR-80) |
| 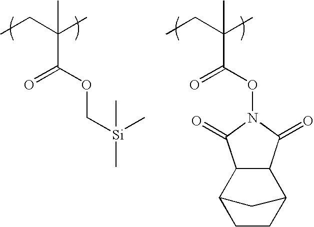 | |
| | (HR-81) |
| 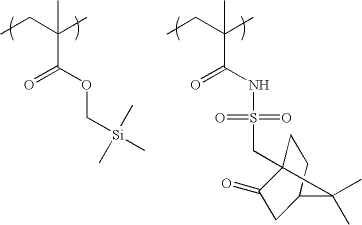 | |
| | (HR-82) |
| 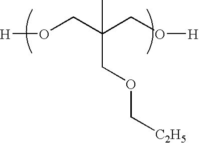 | |
| | (HR-83) |
| 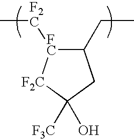 | |
| | (HR-84) |
| 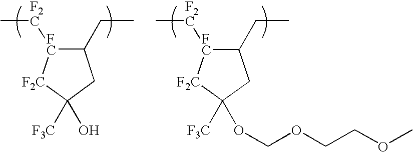 | |

| Resin | Comp. | Mw | Mw/Mn |
|---|---|---|---|
| HR-1 | 50/50 | 8800 | 2.1 |
| HR-2 | 50/50 | 5200 | 1.8 |
| HR-3 | 50/50 | 4800 | 1.9 |
| HR-4 | 50/50 | 5300 | 1.9 |
| HR-5 | 50/50 | 6200 | 1.9 |
| HR-6 | 100 | 12000 | 2.0 |
| HR-7 | 50/50 | 5800 | 1.9 |
| HR-8 | 50/50 | 6300 | 1.9 |
| HR-9 | 100 | 5500 | 2.0 |
| HR-10 | 50/50 | 7500 | 1.9 |
| HR-11 | 70/30 | 10200 | 2.2 |
| HR-12 | 40/60 | 15000 | 2.2 |
| HR-13 | 40/60 | 13000 | 2.2 |
| HR-14 | 80/20 | 11000 | 2.2 |
| HR-15 | 60/40 | 9800 | 2.2 |
| HR-16 | 50/50 | 8000 | 2.2 |
| HR-17 | 50/50 | 7600 | 2.0 |
| HR-18 | 50/50 | 12000 | 2.0 |
| HR-19 | 20/80 | 6500 | 1.8 |
| HR-20 | 100 | 6500 | 1.2 |
| HR-21 | 100 | 6000 | 1.6 |
| HR-22 | 100 | 2000 | 1.6 |
| HR-23 | 50/50 | 6000 | 1.7 |
| HR-24 | 50/50 | 8800 | 1.9 |
| HR-25 | 50/50 | 7800 | 2.0 |
| HR-26 | 50/50 | 8000 | 2.0 |
| HR-27 | 80/20 | 8000 | 1.8 |
| HR-28 | 30/70 | 7000 | 1.7 |
| HR-29 | 50/50 | 6500 | 1.6 |
| HR-30 | 50/50 | 6500 | 1.6 |
| HR-31 | 50/50 | 9000 | 1.8 |
| HR-32 | 100 | 10000 | 1.6 |
| HR-33 | 70/30 | 8000 | 2.0 |
| HR-34 | 10/90 | 8000 | 1.8 |
| HR-35 | 30/30/40 | 9000 | 2.0 |
| HR-36 | 50/50 | 6000 | 1.4 |
| HR-37 | 50/50 | 5500 | 1.5 |
| HR-38 | 50/50 | 4800 | 1.8 |
| HR-39 | 60/40 | 5200 | 1.8 |
| HR-40 | 50/50 | 8000 | 1.5 |
| HR-41 | 20/80 | 7500 | 1.8 |
| HR-42 | 50/50 | 6200 | 1.6 |
| HR-43 | 60/40 | 16000 | 1.8 |
| HR-44 | 80/20 | 10200 | 1.8 |
| HR-45 | 50/50 | 12000 | 2.6 |
| HR-46 | 50/50 | 10900 | 1.9 |
| HR-47 | 50/50 | 6000 | 1.4 |
| HR-48 | 50/50 | 4500 | 1.4 |
| HR-49 | 50/50 | 6900 | 1.9 |
| HR-50 | 100 | 2300 | 2.6 |
| HR-51 | 60/40 | 8800 | 1.5 |
| HR-52 | 68/32 | 11000 | 1.7 |
| HR-53 | 100 | 8000 | 1.4 |
| HR-54 | 100 | 8500 | 1.4 |
| HR-55 | 80/20 | 13000 | 2.1 |
| HR-56 | 70/30 | 18000 | 2.3 |
| HR-57 | 50/50 | 5200 | 1.9 |
| HR-58 | 50/50 | 10200 | 2.2 |
| HR-59 | 60/40 | 7200 | 2.2 |
| HR-60 | 32/32/36 | 5600 | 2.0 |
| HR-61 | 30/30/40 | 9600 | 1.6 |
| HR-62 | 40/40/20 | 12000 | 2.0 |
| HR-63 | 100 | 6800 | 1.6 |
| HR-64 | 50/50 | 7900 | 1.9 |
| HR-65 | 40/30/30 | 5600 | 2.1 |
| HR-66 | 50/50 | 6800 | 1.7 |
| HR-67 | 50/50 | 5900 | 1.6 |
| HR-68 | 49/51 | 6200 | 1.8 |
| HR-69 | 50/50 | 8000 | 1.9 |
| HR-70 | 30/40/30 | 9600 | 2.3 |
| HR-71 | 30/40/30 | 9200 | 2.0 |
| HR-72 | 40/29/31 | 3200 | 2.1 |
| HR-73 | 90/10 | 6500 | 2.2 |
| HR-74 | 50/50 | 7900 | 1.9 |
| HR-75 | 20/30/50 | 10800 | 1.6 |
| HR-76 | 50/50 | 2200 | 1.9 |
| HR-77 | 50/50 | 5900 | 2.1 |
| HR-78 | 40/20/30/10 | 14000 | 2.2 |
| HR-79 | 50/50 | 5500 | 1.8 |
| HR-80 | 50/50 | 10600 | 1.9 |
| HR-81 | 50/50 | 8600 | 2.3 |
| HR-82 | 100 | 15000 | 2.1 |
| HR-83 | 100 | 6900 | 2.5 |
| HR-84 | 50/50 | 9900 | 2.3 |

For the prevention of direct contact of a resist film with a liquid for liquid immersion, a film that is highly insoluble in the liquid for liquid immersion (hereinafter also referred to as a “top coat”) may be provided between the resist film from the positive photosensitive composition of the present invention and the liquid for liquid immersion. The functions to be fulfilled by the top coat are applicability to an upper layer portion of the resist, transparency in radiation of especially 193 nm and being highly insoluble in the liquid for liquid immersion. Preferably, the top coat does not mix with the resist and is uniformly applicable to an upper layer of the resist.

From the viewpoint of 193 nm transparency, the top coat preferably consists of a polymer not abundantly containing an aromatic moiety. As such, there can be mentioned, for example, a hydrocarbon polymer, an acrylic ester polymer, polymethacrylic acid, polyacrylic acid, polyvinyl ether, a siliconized polymer, a fluoropolymer or the like. The aforementioned hydrophobic resin (HR) finds appropriate application in the top coat. From the viewpoint of contamination of an optical lens by leaching of impurities from the top coat into the liquid for liquid immersion, it is preferred to reduce the amount of residual monomer components of the polymer contained in the top coat.

At the detachment of the top coat, use may be made of a developer, or a separate peeling agent may be used. The peeling agent preferably consists of a solvent having a lower permeation into the resist film. Detachability by an alkali developer is preferred from the viewpoint of simultaneous attainment of the detachment step with the development processing step for the resist film. The top coat is preferred to be acidic from the viewpoint of detachment with the use of an alkali developer. However, from the viewpoint of non-intermixability with the resist film, the top coat may be neutral or alkaline.

The less the difference in refractive index between the top coat and the liquid for liquid immersion, the higher the resolving power. In an ArF excimer laser (wavelength: 193 nm), when water is used as the liquid for liquid immersion, the top coat for ArF liquid immersion exposure preferably has a refractive index close to that of the liquid for liquid immersion. From the viewpoint of approximation of the refractive index to that of the liquid for liquid immersion, it is preferred that a fluorine atom be contained in the top coat. From the viewpoint of transparency and refractive index, it is preferred to reduce the thickness of the film.

Preferably, the top coat does not mix with the resist film and also does not mix with the liquid for liquid immersion. From this viewpoint, when the liquid for liquid immersion is water, it is preferred that the solvent used in the top coat be hardly soluble in the solvent used in the positive photosensitive composition and be a non-water-soluble medium. When the liquid for liquid immersion is an organic solvent, the top coat may be soluble or insoluble in water.

### EXAMPLES

Now, the present invention will be described in greater detail with reference to Examples, which however in no way limit the subject matter of the present invention.

### (1) Synthetic Example 1

### Synthesis of Resin (1)

In a nitrogen stream, 40 g of cyclohexanone was placed in a three-necked flask and heated at 80° C. A solution obtained by dissolving not only the following compounds amounting in sequence from the left to 9.40 g, 2.40 g, 6.93 g and 1.60 g, but also a polymerization initiator V601 (produced by Wako Pure Chemical Industries, Ltd., 1.56 g, 10 mol % based on monomers) in 75 g of cyclohexanone was dropped thereinto over a period of 6 hours. After the completion of the dropping, reaction was carried on at 80° C. for 2 hours. The reaction mixture was allowed to stand still to cool and was dropped into a liquid of 800 ml of hexane mixed with 300 ml of ethyl acetate over a period of 20 min. The thus precipitated powder was collected by filtration and dried, thereby obtaining a resin (1) (14.8 g). The weight average molecular weight of the obtained resin (1) in terms of standard polystyrene molecular weight was 9790 and the degree of dispersal (Mw/Mn) thereof was 1.61.

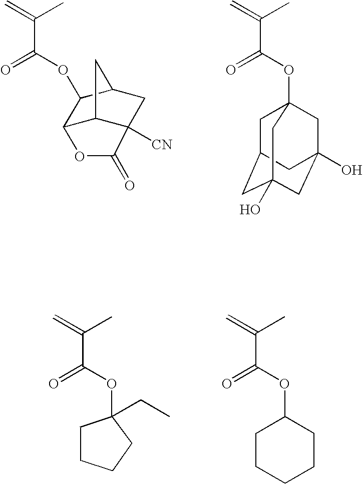

In the same manner as in the Synthetic Example 1, there were synthesized resins (2) to (18) as the resin (A) according to the present invention and comparative resins (Q1 and Q2). The structures of the individual synthesized resins are shown below. The following Table 4 shows the molar ratios of individual repeating units (corresponding to individual repeating units of each structural formula in the order from the left), weight average molecular weight Mw, degree of dispersal Pd, Onishi parameter of the repeating unit of lactone structure and van der Waals volume of acid decomposable group with respect to each of the resins.

TABLE 4

| | | | | |
|---|---|---|---|---|
| | | | | (1) |
| 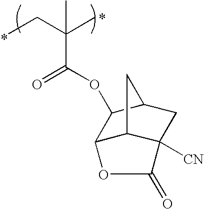 | 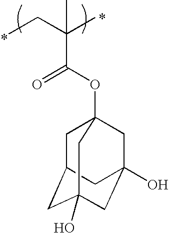 | 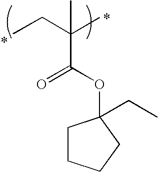 | 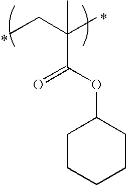 | |
| | | | | (2) |
| 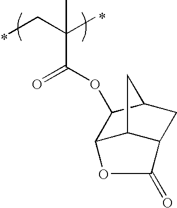 | 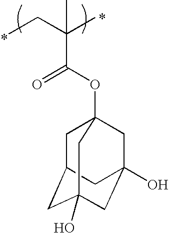 | 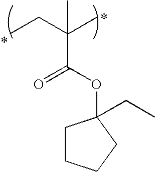 | 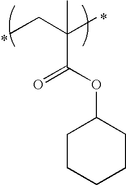 | |
| | | | | (3) |
| 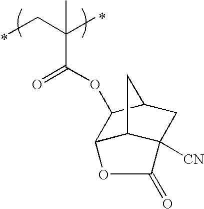 | 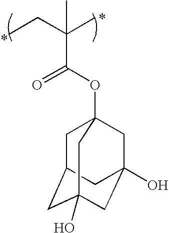 | 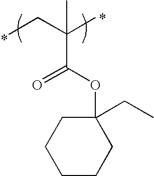 | 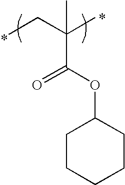 | |
| | | | | (4) |
| 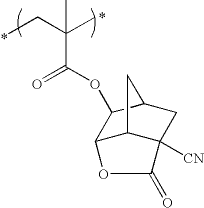 | 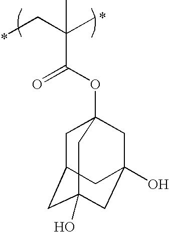 | 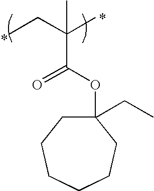 | 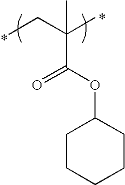 | |
| | | | | (5) |
| 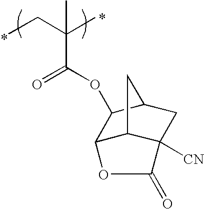 | 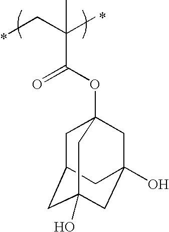 | 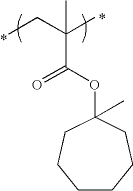 | 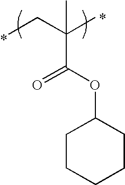 | |
| | | | | (6) |
| 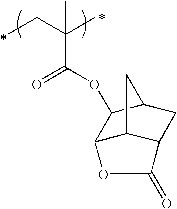 | 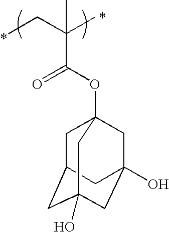 | 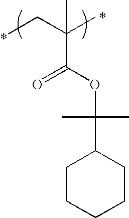 | 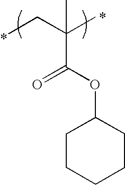 | |
| | | | | (7) |
| 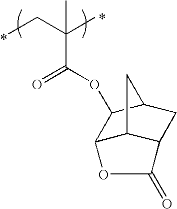 | 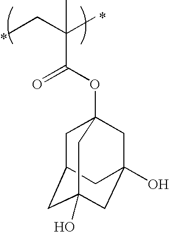 | 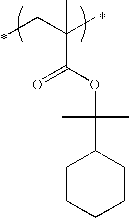 | 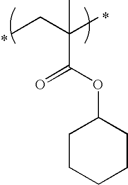 | |
| | | | | (8) |
| 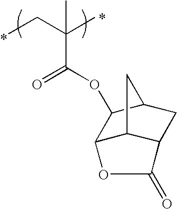 | 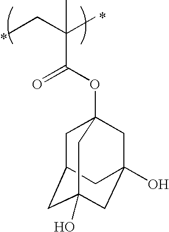 | 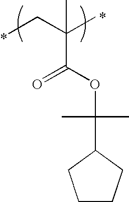 | 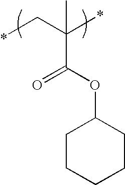 | |

| | | | |
|---|---|---|---|
| | | | (9) |
| 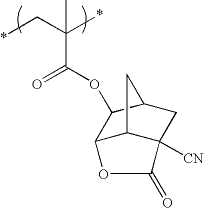 | 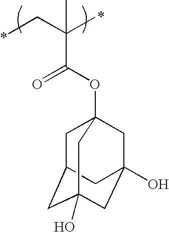 | 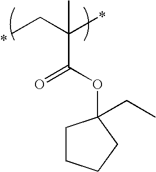 | |

| | | | | |
|---|---|---|---|---|
| | | | | (10) |
| 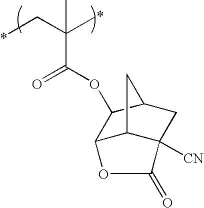 | 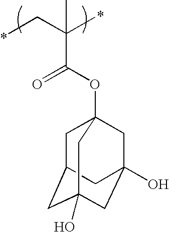 | 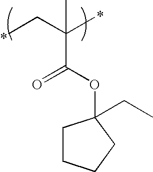 | 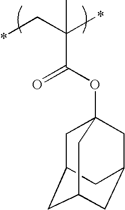 | |
| | | | | (11) |
| 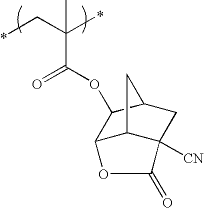 | 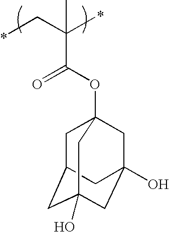 | 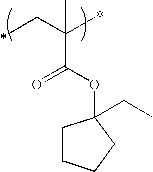 | 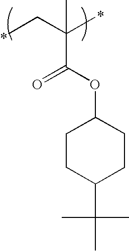 | |

| | | | |
|---|---|---|---|
| | | | (12) |
| 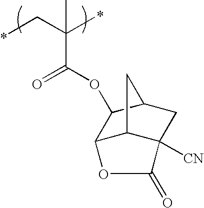 | 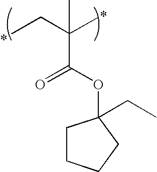 | 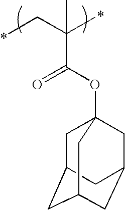 | |

| | | |
|---|---|---|
| | | (13) |
| 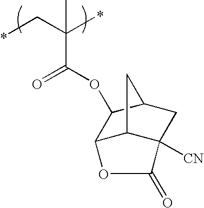 | 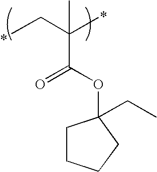 | |

| | | | | |
|---|---|---|---|---|
| | | | | (14) |
| 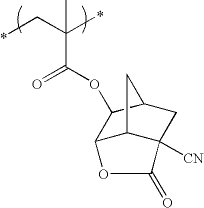 | 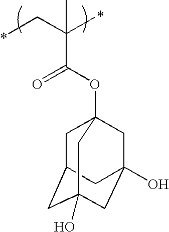 | 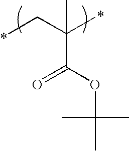 | 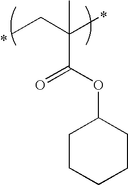 | |
| | | | | (15) |
| 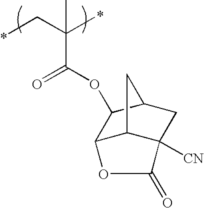 | 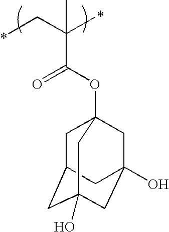 | 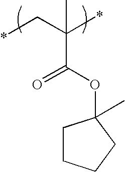 | 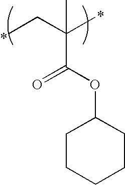 | |
| | | | | (16) |
| 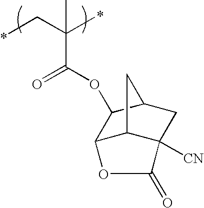 | 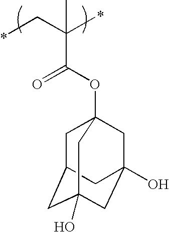 | 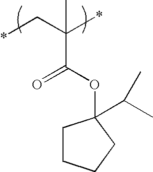 | 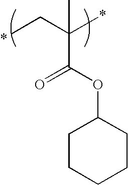 | |
| | | | | (17) |
| 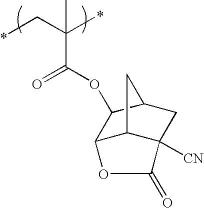 | 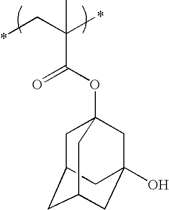 | 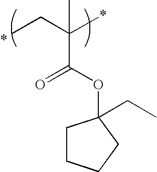 | 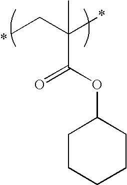 | |
| | | | | (18) |
| 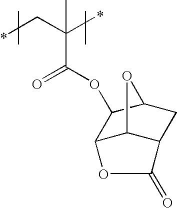 | 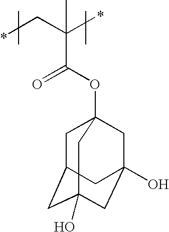 | 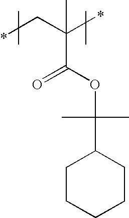 | 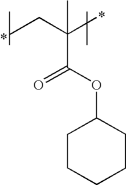 | |
| | | | | (19) |
| 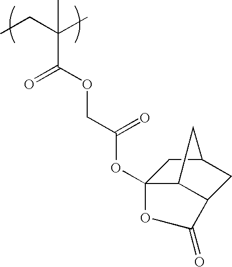 | 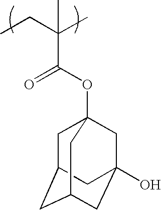 | 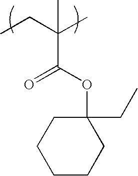 | 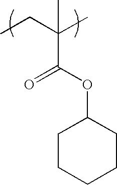 | |

| | | | |
|---|---|---|---|
| | | | (20) |
| 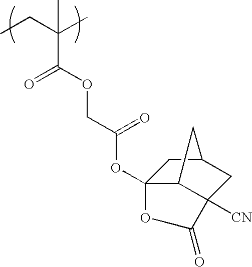 | 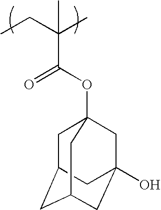 | 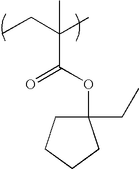 | |

| | | | | |
|---|---|---|---|---|
| | | | | (21) |
| 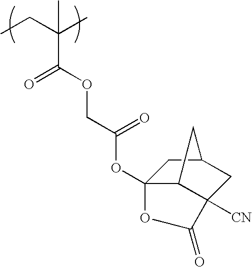 | 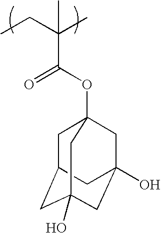 | 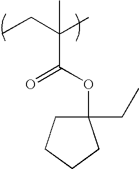 | 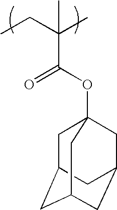 | |
| | | | | (22) |
| 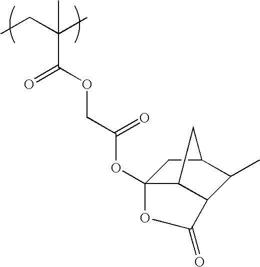 | 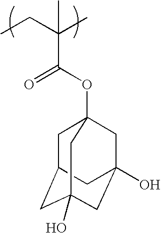 | 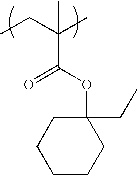 | 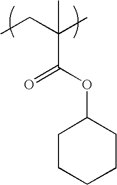 | |

| | | | |
|---|---|---|---|
| | | | Q1 |
| 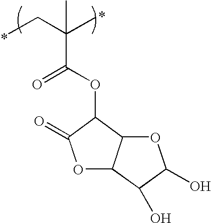 | 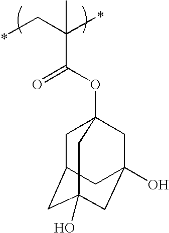 | 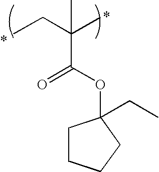 | |
| | | | Q2 |
| 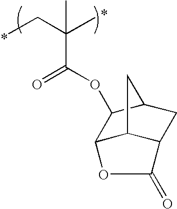 | 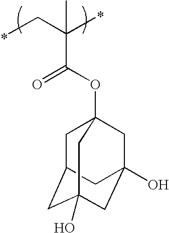 | 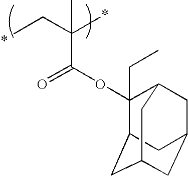 | |

| | | | | | | | | Volume of |
|---|---|---|---|---|---|---|---|---|
| | | | | | | | Onishi parameter | acid-decomposable |
| | Molar ratio (%) | | | | | | of lactone | group |
| Resin | Component 1 | Component 2 | Component 3 | Component 4 | Mw | Pd | repeating unit | (× 10⁻³⁰ m³) |
| (1) | 40 | 10 | 40 | 10 | 9790 | 1.61 | 3.45 | 264.84 |
| (2) | 40 | 10 | 40 | 10 | 9590 | 1.60 | 3.80 | 264.84 |
| (3) | 40 | 10 | 40 | 10 | 9560 | 1.59 | 3.45 | 282.77 |
| (4) | 40 | 10 | 40 | 10 | 8170 | 1.53 | 3.45 | 302.78 |
| (5) | 40 | 10 | 40 | 10 | 7400 | 1.68 | 3.45 | 284.07 |
| (6) | 40 | 10 | 40 | 10 | 6210 | 1.71 | 3.80 | 302.58 |
| (7) | 40 | 10 | 40 | 10 | 8750 | 1.65 | 3.80 | 302.58 |
| (8) | 40 | 10 | 40 | 10 | 7980 | 1.51 | 3.80 | 282.7 |
| (9) | 45 | 10 | 45 | 0 | 7440 | 1.69 | 3.45 | 264.84 |
| (10) | 40 | 10 | 40 | 10 | 8150 | 1.70 | 3.45 | 264.84 |
| (11) | 40 | 10 | 40 | 10 | 8880 | 1.64 | 3.45 | 264.84 |
| (12) | 45 | 0 | 45 | 10 | 9080 | 1.66 | 3.45 | 264.84 |
| (13) | 50 | 0 | 50 | 0 | 9920 | 1.69 | 3.45 | 264.84 |
| (14) | 40 | 10 | 40 | 10 | 10020 | 1.72 | 3.45 | 218.59 |
| (15) | 40 | 10 | 40 | 10 | 8310 | 1.60 | 3.45 | 245.69 |
| (16) | 40 | 10 | 40 | 10 | 5050 | 1.36 | 3.45 | 283.4 |
| (17) | 40 | 10 | 40 | 10 | 9105 | 1.75 | 3.45 | 264.84 |
| (18) | 40 | 10 | 40 | 10 | 9850 | 1.68 | 4.50 | 302.58 |
| (19) | 40 | 20 | 35 | 5 | 9540 | 1.61 | 4.50 | 282.77 |
| (20) | 50 | 10 | 40 | 0 | 9620 | 1.63 | 4.29 | 264.84 |
| (21) | 45 | 10 | 40 | 5 | 9210 | 1.60 | 4.29 | 264.84 |
| (22) | 40 | 15 | 40 | 5 | 8960 | 1.59 | 4.33 | 282.77 |
| Q1 | 40 | 10 | 50 | 0 | 10030 | 1.78 | 9.66 | 264.84 |
| Q2 | 40 | 10 | 50 | 0 | 9500 | 1.75 | 3.75 | 333.54 |

### Examples 1 to 24 and Comparative Examples 1 and 2

### Preparation of Resist Composition

Each of the positive resist compositions was prepared by dissolving components indicated in the following Tables 5-1 and 5-2 in a solvent to thereby obtain a solution of 5 mass % solid content with respect to each of the components and filtering the same through a polyethylene filter of 0.1 μm pore size. The thus prepared positive resist compositions were exposed under the following exposure condition (1) or exposure condition (2). The resultant resist patterns were evaluated in the following manner. The results are summarized in Table 6. With respect to the components of Table 5-1, the ratio in the use of multiple components is a mass ratio.

In Table 5-2, the addition mode is “addition” indicated when the positive resist composition contained a hydrophobic resin (HR). On the other hand, the addition mode is “TC” indicated when the positive resist composition contained no hydrophobic resin (HR) and when after formation of a resist film, a top coat protective film containing a hydrophobic resin (HR) was formed on an upper layer of the resist film.

(Exposure Condition (1) ArF Dry Exposure)

An organic antireflection film ARC29A (produced by Nissan Chemical Industries, Ltd.) was applied onto a silicon wafer and baked at 205° C. for 60 sec, thereby forming a 78 nm antireflection film. The prepared positive resist composition was applied thereonto and baked at 130° C. for 60 sec, thereby forming a 120 nm resist film. The resultant wafer was exposed through a 6% half-tone mask of 75 nm 1:1 line and space pattern with the use of ArF excimer laser scanner (manufactured by ASML, PAS5500/1100, NA0.75). Thereafter, the exposed wafer was heated at 130° C. for 60 sec, developed with an aqueous solution of tetramethylammonium hydroxide (2.38 mass %) for 30 sec, rinsed with pure water and spin dried, thereby obtaining a resist pattern.

(Exposure Condition (2) ArF Liquid Immersion Exposure)

An organic antireflection film ARC29A (produced by Nissan Chemical Industries, Ltd.) was applied onto a silicon wafer and baked at 205° C. for 60 sec, thereby forming a 98 nm antireflection film. The prepared positive resist composition was applied thereonto and baked at 130° C. for 60 sec, thereby forming a 120 nm resist film. The resultant wafer was exposed through a 6% half-tone mask of 65 nm 1:1 line and space pattern with the use of ArF excimer laser liquid immersion scanner (manufactured by ASML, XT1250i, NA0.85). Ultrapure water was used as the liquid for liquid immersion. Thereafter, the exposed wafer was heated at 130° C. for 60 sec, developed with an aqueous solution of tetramethylammonium hydroxide (2.38 mass %) for 30 sec, rinsed with pure water and spin dried, thereby obtaining a resist pattern.

When the addition mode of hydrophobic resin (HR) was “TC,” the following operation was carried out after formation of the resist film.

<Method of Forming Top Coat>

The resist film was coated with a solution obtained by dissolving a hydrophobic resin (HR) indicated in Table 5-2 in a solvent by means of a spin coater. The wafer was dried by heating at 115° C. for 60 sec, thereby forming a 0.05 μm top coat layer. At that time, the top coat was inspected with respect to any coating irregularity, thereby ascertaining a uniform coating without coating irregularity.

The code for solvent is as follows.

SL-6: perfluorobutyltetrahydrofuran

[Line Edge Roughness]

In the measurement of line edge roughness (LER), a 120 nm isolated pattern was measured with the use of a critical dimension scanning electron microscope (SEM). With respect to longitudinal edge line pattern range of 5 μm, the distance from a reference line on which edges were to be present was measured on 50 points with the use of critical dimension SEM (model S-8840, manufactured by Hitachi, Ltd.). The standard deviation of measurements was determined, and 3σ was computed. The smaller the value thereof, the higher the performance.

[Method of Evaluating Pattern Collapse]

The optimum exposure intensity was regarded as the exposure intensity capable of reproduction of an 85 nm line-and-space mask pattern. The exposure intensity was increased from the optimum exposure intensity to make the line width of the formed line pattern finer. The critical pattern collapse was defined by the line width (nm) allowing pattern resolution without collapse. The smaller the value thereof, the finer the pattern is resolved without any collapse, that is, the more effective the suppression of pattern collapse.

The codes employed in Tables 5-1 and 5-2 are as follows.

Basic compounds

N-1: trioctylamine,

N-2: 2,6-diisopropylaniline,

N-3: N-phenyldiethanolamine,

N-4: diazabicyclo[4.3.0]nonene,

N-5: dicyclohexylmethylamine, and

N-6: 2,4,5-triphenylimidazole.

Surfactants

W-1: Megafac F176 (produced by Dainippon Ink & Chemicals, Inc.) (fluorinated),

W-2: Megafac R08 (produced by Dainippon Ink & Chemicals, Inc.) (fluorinated and siliconized),

W-3: polysiloxane polymer KP-341 (produced by Shin-Etsu Chemical Co., Ltd.) (siliconized), and

W-4: PF656 (produced by OMNOVA, fluorinated). Dissolution inhibiting compound

D-1: t-butyl lithocholate. Organic solvents

A1: propylene glycol monomethyl ether acetate,

A3: cyclohexanone,

B1: propylene glycol monomethyl ether, and

B2: ethyl acetate.

TABLE 5-1

| | | (B) Acid | | | Dissolution | |
|---|---|---|---|---|---|---|
| | (A)Resin | generator | Basic compound | Surfactant | inhibiting | Organic |
| | (10 g) | (g) | (g) | (g) | compound (g) | solvent |
| Exam. 1 | Resin 1 | z-38 (0.5) | N-1 (0.05) | W-1 (0.02) | — | A3 = 1 |
| Exam. 2 | Resin 2 | z-38 (0.5) | N-1 (0.04) | W-1 (0.02) | — | A3 = 1 |
| Exam. 3 | Resin 3 | z-2 (0.55) | N-2 (0.05) | W-1 (0.02) | — | A3 = 1 |
| Exam. 4 | Resin 4 | z-38 (0.5) | N-3 (0.045) | W-2 (0.02) | — | A3 = 1 |
| Exam. 5 | Resin 5 | z-15 (0.5) | N-2 (0.05) | W-1 (0.02) | D-1 (0.1) | A3 = 1 |
| Exam. 6 | Resin 6 | z-15 (0.5) | N-1 (0.01), N-2 (0.04) | W-1 (0.02) | — | A3 = 1 |
| Exam. 7 | Resin 7 | z-38 (0.5) | N-3 (0.03) | W-1 (0.02) | — | A3 = 1 |
| Exam. 8 | Resin 8 | z-38 (0.5) | N-2 (0.04) | W-3 (0.04) | — | A3 = 1 |
| Exam. 9 | Resin 9 | z-38 (0.5) | N-1 (0.05) | W-1 (0.02) | — | A3 = 1 |
| Exam. 10 | Resin 10 | z-38 (0.5) | N-4 (0.04) | W-1 (0.02) | — | A3 = 1 |
| Exam. 11 | Resin 11 | z-15 (0.5) | N-5 (0.03) | W-1 (0.02) | — | A1/B1 = 7/3 |
| Exam. 12 | Resin 12 | z-15 (0.5) | N-6 (0.05) | W-1 (0.02) | — | A1/B1 = 6/4 |
| Exam. 13 | Resin 13 | z-38 (0.5) | N-2 (0.05) | W-1 (0.02) | D-1 (0.1) | A1/B1 = 3/7 |
| Exam. 14 | Resin 14 | z-38 (0.55) | N-2 (0.04) | W-1 (0.03) | — | A1/A3 = 3/7 |
| Exam. 15 | Resin 15 | z-15 (0.5) | N-5 (0.03) | W-1 (0.02) | — | A1/B2 = 9/1 |
| Exam. 16 | Resin 16 | z-38 (0.5) | N-2 (0.05) | W-1 (0.02) | — | A1/B1 = 7/3 |
| Exam. 17 | Resin 17 | z-38 (0.5) | N-2 (0.05) | W-1 (0.02) | — | A1/B1 = 7/3 |
| Exam. 18 | Resin 18 | z-2 (0.3) | N-1 (0.04) | W-4 (0.02) | — | A3 = 1 |
| Exam. 19 | Resin 19 | z-91 (0.5) | N-2 (0.04) | W-2 (0.02) | — | A1/B1 = 7/3 |
| Exam. 20 | Resin 20 | z-66 (0.5) | N-2 (0.04) | W-1 (0.02) | — | A1/B1 = 6/4 |
| Exam. 21 | Resin 21 | z-67 (0.5) | N-2 (0.04) | W-1 (0.02) | — | A1/B1 = 6/4 |
| Exam. 22 | Resin 22 | z-90 (0.5) | N-1 (0.04) | W-3 (0.02) | — | A1/B1 = 6/4 |
| Comp. 1 | Resin Q1 | z-2 (0.5) | N-1 (0.05) | W-1 (0.02) | — | A1/B1 = 7/3 |
| Comp. 2 | Resin Q2 | z-2 (0.5) | N-1 (0.05) | W-1 (0.02) | — | A1/B2 = 9/1 |

TABLE 5-2

| | | (B) Acid | Basic | | | Mass (g) | | Dissolution | |
|---|---|---|---|---|---|---|---|---|---|
| | (A) Resin | generator | compound | Surfactant | Hydrophobic | or | Addition | inhibiting | Organic |
| | (10 g) | (g) | (g) | (g) | resin | solvent | mode | compound (g) | solvent |
| Exam. 23 | Resin 1 | z-38 (0.5) | N-1 (0.05) | W-1 (0.02) | HR83 | SL-6 | TC | — | A3 = 1 |
| Exam. 24 | Resin 2 | z-38 (0.5) | N-1 (0.04) | W-1 (0.02) | HR25 | 0.2 | Added | — | A3 = 1 |

TABLE 6

| | | | Exposure condition (2) | |
|---|---|---|---|---|
| | Exposure condition (1) | | ArF liquid immersion | |
| | ArF dry exposure | | exposure | |
| | | Pattern | | Pattern |
| | LER(nm) | collapse (%) | LER(nm) | collapse (%) |
| Exam. 1 | 4.9 | 52.4 | — | — |
| Exam. 2 | 5.5 | 51.9 | — | — |
| Exam. 3 | 5.0 | 52.5 | — | — |
| Exam. 4 | 5.1 | 53.0 | — | — |
| Exam. 5 | 5.2 | 52.8 | — | — |
| Exam. 6 | 5.5 | 53.5 | — | — |
| Exam. 7 | 6.4 | 54.0 | — | — |
| Exam. 8 | 6.2 | 54.5 | — | — |
| Exam. 9 | 5.0 | 55.8 | — | — |
| Exam. 10 | 6.0 | 54.0 | — | — |
| Exam. 11 | 5.9 | 54.2 | — | — |
| Exam. 12 | 6.5 | 53.8 | — | — |
| Exam. 13 | 5.5 | 55.9 | — | — |
| Exam. 14 | 5.1 | 56.1 | — | — |
| Exam. 15 | 5.2 | 53.0 | — | — |
| Exam. 16 | 5.5 | 52.4 | — | — |
| Exam. 17 | 5.2 | 53.1 | — | — |
| Exam. 18 | 5.8 | 60.0 | — | — |
| Exam. 19 | 4.8 | 52.0 | — | — |
| Exam. 20 | 4.7 | 51.5 | — | — |
| Exam. 21 | 4.7 | 50.5 | — | — |
| Exam. 22 | 4.8 | 52.2 | — | — |
| Exam. 23 | — | — | 5.2 | 53 |
| Exam. 24 | — | — | 5.1 | 52 |
| Comp. 1 | 6.0 | 65.0 | — | — |
| Comp. 2 | 7.0 | 62.8 | — | — |

From the results of Table 6, it is apparent that the positive photosensitive compositions of the present invention realize favorable LER and improvement in pattern collapse in not only regular exposure (dry exposure) but also liquid immersion exposure.

What is claimed is:

1. A positive photosensitive composition comprising:
(A) a resin having a repeating unit with a lactone structure of 5.0 or below an Onishi parameter and having any of repeating units of the following general formula (I) that when acted on by an acid, generates a carboxylic acid, and
(B) a compound that when exposed to actinic rays or radiation, generates an acid, 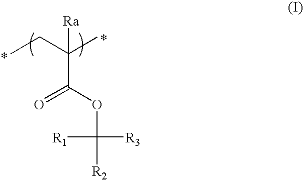
wherein each of R₁, R₂ and R₃ independently represents a substituted or unsubstituted alkyl group or a substituted or unsubstituted cycloalkyl group, provided that R₂ and R₃ may be bonded with each other to thereby form a ring structure, and
Ra represents a hydrogen atom, an alkyl group or a group of the formula —CH₂—O—Ra₂ in which Ra₂ represents a hydrogen atom, an alkyl group or an acyl group,
the structure of the general formula (I) having a van der Waals volume of 306×10⁻³⁰ m³ or less.

2. The positive photosensitive composition according to claim 1, wherein the resin (A) further has any of repeating units of the following general formula (II): 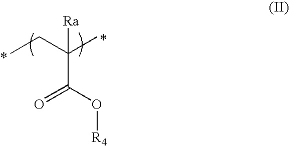
wherein R₄ represents an alicyclic hydrocarbon structure having a cyano group or a hydroxyl group, and
Ra represents a hydrogen atom, an alkyl group or a group of the formula —CH₂—O—Ra₂ in which Ra₂ represents a hydrogen atom, an alkyl group or an acyl group.

3. The positive photosensitive composition according to claim 1, wherein the resin (A) further has any of repeating units of the following general formula (III): 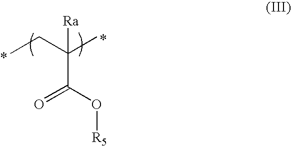
wherein R₅ represents a hydrocarbon group having at least one cyclic structure in which neither a hydroxyl group nor a cyano group is contained, and
Ra represents a hydrogen atom, an alkyl group or a group of the formula —CH₂—O—Ra₂ in which Ra₂ represents a hydrogen atom, an alkyl group or an acyl group.

4. The positive photosensitive composition according to claim 2, wherein the resin (A) further has any of repeating units of the following general formula (III): 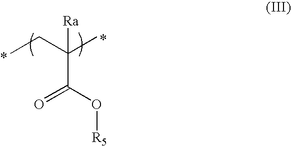
wherein R₅ represents a hydrocarbon group having at least one cyclic structure in which neither a hydroxyl group nor a cyano group is contained, and
Ra represents a hydrogen atom, an alkyl group or a group of the formula —CH₂—O—Ra₂ in which Ra₂ represents a hydrogen atom, an alkyl group or an acyl group.

5. A method of forming a pattern, comprising the steps of shaping the positive photosensitive composition according to claim 1 into a film and subjecting the film to exposure to light and development.

6. A method of forming a pattern, comprising the steps of shaping the positive photosensitive composition according to claim 2 into a film and subjecting the film to exposure to light and development.

7. A method of forming a pattern, comprising the steps of shaping the positive photosensitive composition according to claim 3 into a film and subjecting the film to exposure to light and development.

8. A method of forming a pattern, comprising the steps of shaping the positive photosensitive composition according to claim 4 into a film and subjecting the film to exposure to light and development.
